(19) United States
(12) Patent Application Publication
(10) Pub. No.: US 2015/0112064 A1
(43) Pub. Date: Apr. 23, 2015

(54) NOVEL ORGANIC ELECTROLUMINESCENT COMPOUNDS AND ORGANIC ELECTROLUMINESCENT DEVICE COMPRISING THE SAME

(71) Applicant: Rohm and Haas Electronic Materials Korea Ltd., Cheonan-Si (KR)

(72) Inventors: Bong-Ok Kim, Seoul (KR); Chi-Sik Kim, Gyeonggi-do (KR); Jong-Seok Ku, Gyeonggi-do (KR); Hyuck-Joo Kwon, Seoul (KR); Kyung-Joo Lee, Seoul (KR); Hong-Yeop Na, Seoul (KR)

(21) Appl. No.: 14/396,910

(22) PCT Filed: Apr. 24, 2013
(86) PCT No.: PCT/KR2013/003514

§ 371 Date: Oct. 24, 2014

(30) Foreign Application Priority Data
Apr. 27, 2012 (KR) 10-2012-0044711

(51) Int. Cl. H01L 51/00

(52) U.S. Cl. CPC H01L 51/0067; H01L 51/0072; H01L 51/5016
USPC 544/331

(57) ABSTRACT

The present invention relates to a novel organic electroluminescent compound and an organic electroluminescent device comprising the same. The organic electroluminescent compound according to the present invention has high green luminous efficiency and superior material lifespan characteristics, compared with conventional phosphorescent host materials, and thus can provide an organic electroluminescent device which is excellent in operational lifespan, and induces increased power efficiency and improves power consumption.

### TECHNICAL FIELD

The present invention relates to novel organic electroluminescent compounds which are useful as a phosphorescent host material and an organic electroluminescent device (hereinafter referred to as ‘OLED device’ or ‘organic EL device’) comprising the same.

### BACKGROUND ART

An electroluminescent (EL) device is a self-light-emitting device which has advantages over other types of display devices in that it provides a wider viewing angle, a greater contrast ratio, and a faster response time. Thus, the electroluminescent (EL) device receives attention as a light-emitting device of various display devices. An organic EL device was first developed by Eastman Kodak, by using small aromatic diamine molecules, and aluminum complexes as materials for forming a light-emitting layer [Appl. Phys. Lett. 51, 913, 1987]. Thereafter, since an organic electroluminescent device possesses the advantages of high visibility, excellent shock resistance, and low applied voltage, the study of its practical use as a display device of the next generation is actively conducted.

Generally, an organic electroluminescent device comprises an organic compound layer containing a light-emitting layer, a pair of electrodes supporting the organic compound layer, and a hole transport layer or an electron transport layer, and can have for example, a constitution of an anode/a hole injection layer/a hole transport layer/a light-emitting layer/an electron transport layer/an electron injection layer/a cathode. When an electric field is applied to the organic electroluminescent device having such layers, a light-emitting compound of the light-emitting layer emits light by the recombination energy of holes injected from the anode and electrons injected from the cathode.

Meanwhile, the most important factor determining luminous efficiency in an organic EL device is the light-emitting material. Until now, fluorescent materials which show fluorescent light-emission by singlet exciton have been widely used as a light-emitting material. However, phosphorescent materials have newly received attention as a light-emitting material, since the phosphorescent materials which show phosphorescent light-emission by triplet exciton can theoretically enhance luminous efficiency by four (4) times compared to fluorescent materials, in view of electroluminescent mechanisms. For example, the occurrence of the phosphorescent light-emission was reported in an organic electroluminescent device including an organic light-emitting layer comprising 4,4′-N,N′-dicarbazole-biphenyl which is a host material of a phosphorescent light-emitter (hereinafter referred to as “a phosphorescent host material”), and an iridium complex which is a phosphorescent light-emitting dopant.

In this regard, iridium(III) complexes have been widely known as phosphorescent materials, including bis(2-(2′-benzothienyl)-pyridinato-N,C3′)iridium(acetylacetonate) ((acac)Ir(btp)₂), tris(2-phenylpyridine)iridium (Ir(ppy)₃) and bis(4,6-difluorophenylpyridinato-N,C2)picolinate iridium (Firpic) as red, green and blue materials, respectively. 4,4′-N,N′-dicarbazole-biphenyl (CBP) is the most widely known phosphorescent light-emitting host material. However, when CBP is used as a host material for tris(2-phenylpyridine) iridium complex (Ir(ppy)₃) of a green phosphorescent light-emitting material, injection balance is lost due to the characteristics of CBP which make it easy to flow holes, and difficult to flow electrons. Thus, excess holes flow to the electron transport layer, and finally luminous efficiency from Ir(ppy)₃ is decreased.

In order to solve such problems, a method to achieve high light-emitting efficiency by preparing a hole blocking layer between the light-emitting layer and the electron transport layer to accumulate holes efficiently in the light-emitting layer was proposed. In this regard, an organic electroluminescent device which has high efficiency by preventing the electrons and the holes from being recombined in the electron transport layer by an hole blocking layer using materials such as 2,9-dimethyl-4,7-diphenyl-1,10-phenanthroline (hereinafter referred to as “BCP; Bathocuproine”) and BAIq (aluminum(III) bis(2-methyl-8-quinolinato)(4-phenylphenolate)) was developed. Further, Pioneer (Japan) et al. developed a high performance organic EL device employing a derivative of BAIq which has suitable electron transport ability as a host material. However, BCP has low reliability since it easily crystallizes even at room temperature, and the lifespan is very short. BAIq, of which Tg is about 100° C., is reported as having a relatively good device lifespan. However, BAIq has problems of decreasing luminous efficiency from Ir(ppy)₃ due to insufficient hole blocking ability.

Although these phosphorescent host materials have some advantages in view of light-emitting characteristics, they have the following disadvantages: (1) Due to their low glass transition temperature and poor thermal stability, they may be degraded during a high-temperature deposition process in a vacuum. (2) The power efficiency of an organic EL device is given by [(π/voltage)×current efficiency], and power efficiency is inversely proportional to voltage. An organic EL device comprising phosphorescent host materials provides a higher current efficiency (cd/A) than one comprising fluorescent materials. However, it has a higher driving voltage, and thus, there is no substantial merit in terms of power efficiency (Im/W). (3) Further, when the phosphorescent host materials are used in an OLED device, the operating lifespan of the device is unsatisfactory, and luminous efficiency still needs improvement.

Thus, considering such problems, green host materials having improved stability and performance are demanded.

Korean Patent Appln. Laying-Open No. 10-2004-0094842 discloses a device comprising a light-emitting layer using compounds in which a nitrogen-containing hetero ring is bonded to an arylcarbazolyl group, and iridium metal complex derivatives. However, the color of the emitted light is bluish-green.

Japanese Patent Appln. Laying-Open No. 2002-193952 discloses a compound in which a nitrogen-containing heteroaryl group or a diarylamino group, etc. is bonded to diaryl- or diheteroaryl triazine via an aryl group, and a device using solely said compound in a light-emitting layer. However, the color of the emitted light is blue.

Korean Patent Appln. Laying-Open No. 10-2006-0127059 discloses host materials for an organic electroluminescent device, in which two carbazole groups are bonded to each other at nitrogen atom positions via an arylene group, in order to obtain an organic electroluminescent device which emits light effectively at a triplet excited state, and which has a long light-emitting lifespan and excellent thermal resistance.

However, in the same manner as other technical fields, technologies in which the present invention is involved can be developed constantly. Further, demands for novel organic electroluminescent compounds of green emission, having better luminous efficiency and device lifespan than the conventional phosphorescent host materials, still remain.

### DISCLOSURE OF INVENTION

### Technical Problem

The objective of the present invention is to provide an organic electroluminescent compound having high luminous efficiency and superior lifespan over conventional phosphorescent host materials, and thus provide an organic electroluminescent device which is excellent in operational lifespan, and induces increased power efficiency and improves power consumption.

### Solution to Problem

As a result of efforts to solve the above problems, the present inventors found that an organic electroluminescent device having high green luminous efficiency can be obtained by using novel carbazole compounds substituted with a carbazolyl group at the 2- or 3-position, wherein a substituted or unsubstituted nitrogen-containing hetero ring is bonded to the nitrogen atom of the core carbazole structure, as phosphorescent host materials.

The organic electroluminescent compounds are represented by the following formula 1:

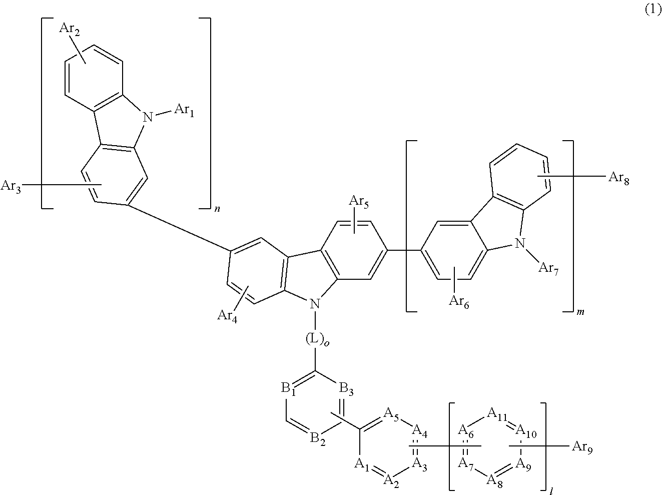

wherein

L represents a substituted or unsubstituted (C6-C30)arylene group, or a substituted or unsubstituted 3- to 30-membered heteroarylene group;

A₁ to A₁₁ each independently represent CR¹¹ or N;

B₁ to B₃ each independently represent CR₂₁ or N, provided that B₁ to B₃ are not simultaneously CR₂₁;

Ar₁ to Ar₉ each independently represent hydrogen, deuterium, a halogen, a cyano group, a nitro group, a hydroxyl group, a substituted or unsubstituted (C1-C30)alkyl group, a substituted or unsubstituted (C3-C30)cycloalkyl group, a substituted or unsubstituted (C6-C30)aryl group, a substituted or unsubstituted 3- to 30-membered heteroaryl group, —NR₁₂R₁₃, —SiR₁₄R₁₅R₁₆, —SR₁₇ or —OR₁₈;

R₁₁ to R₁₈ and R₂₁ each independently represent hydrogen, deuterium, a halogen, a substituted or unsubstituted (C1-C30)alkyl group, a substituted or unsubstituted (C3-C30)cycloalkyl group, a substituted or unsubstituted (C6-C30)aryl group, or a substituted or unsubstituted 3- to 30-membered heteroaryl group; or are linked to an adjacent substituent(s) to form a substituted or unsubstituted mono- or polycyclic 3- to 30-membered alicyclic or aromatic ring whose carbon atom(s) may be replaced by at least one heteroatom selected from nitrogen, oxygen and sulfur;

o represents an integer of 0 to 2; where o is 2, each of L is the same or different;

m and n each independently represent 0 or 1, and m+n=1;

l represents an integer of 1 to 4; where l is an integer of 2 or more, each of A₆ to A₁₁ is the same or different; and

the heteraryl(ene) group contains at least one hetero atom selected from B, N, O, S, P(═O), Si and P.

### Advantageous Effects of Invention

The organic electroluminescent compound according to the present invention has high green luminous efficiency and superior material lifespan characteristics, compared with conventional phosphorescent host materials, and thus can provide an organic electroluminescent device which is excellent in operational lifespan, and induces increased power efficiency and improves power consumption.

### MODE FOR THE INVENTION

Hereinafter, the present invention will be described in detail. However, the following description is intended to explain the invention, and is not meant in any way to restrict the scope of the invention.

The present invention relates to an organic electroluminescent compound represented by formula 1, above, an organic electroluminescent material comprising the compound, and an organic electroluminescent device comprising the material.

Hereinafter, the organic electroluminescent compound represented by the above formula 1 will be described in detail.

Herein, “(C1-C30)alkyl” is meant to be a linear or branched alkyl having 1 to 30 carbon atoms, in which the number of carbon atoms is preferably 1 to 10; more preferably 1 to 6; and includes methyl, ethyl, n-propyl, isopropyl, n-butyl, isobutyl and tert-butyl, etc.; “(C2-C30)alkenyl” is meant to be a linear or branched alkenyl having 2 to 30 carbon atoms, in which the number of carbon atoms is preferably 2 to 20; more preferably 2 to 10; and includes vinyl, 1-propenyl, 2-propenyl, 1-butenyl, 2-butenyl, 3-butenyl and 2-methylbut-2-enyl, etc.; “(C2-C30)alkynyl” is a linear or branched alkynyl having 2 to 30 carbon atoms, in which the number of carbon atoms is preferably 2 to 20; more preferably 2 to 10; and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 10; more preferably 3 to 7; and includes cyclopropyl, cyclobutyl, cyclopentyl, cyclohexyl, etc.; “3- to 30-membered heterocycloalkyl” is a cycloalkyl having at least one heteroatom selected from B, N, O, S, P(═O), Si and P; preferably O, S and N, and 3 to 30 ring backbone atoms, in which the number of ring backbone atoms is preferably 3 to 7; more preferably 5 to 7; and includes tetrahydrofurane, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20; more preferably 6 to 15; and includes phenyl, biphenyl, terphenyl, naphthyl, binaphtyl, phenylnaphtyl, naphtylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; has preferably 3 to 20; more preferably 3 to 15 ring backbone atoms; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, CI, Br and I.

The present invention provides an organic electroluminescent compound represented by the following formula 2, as one embodiment.

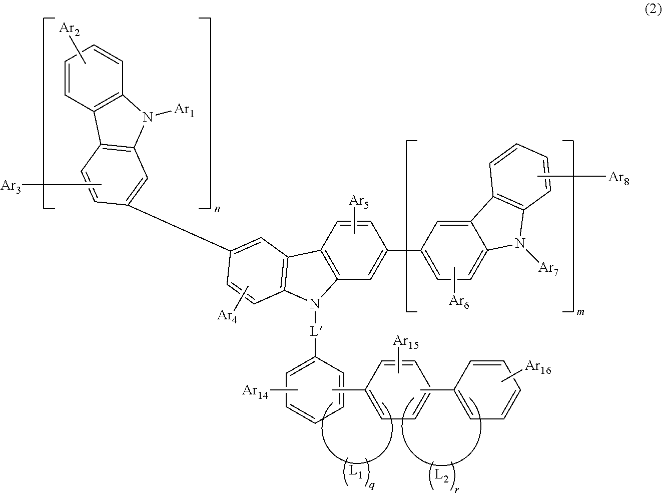

Wherein

L′ represents a substituted or unsubstituted, nitrogen-containing 3- to 30-membered heteroarylene;

m, n and Ar₁ to Ar₈ are as defined in formula 1;

Ar₁₄ to Arₘ are as defined in R₁₁ of formula 1;

L₁ and L₂ each independently are selected from the group consisting of —CR₅₁ R₅₂—, —O—, —NR₅₃— and —S—, wherein R₅₁ to R₅₃ are as defined in R₁₁ of formula 1;

q and r each independently represent 0 or 1, and q+r=1.

Herein, “substituted” in the expression “substituted or unsubstituted” means that a hydrogen atom in a certain functional group is replaced with another atom or group, i.e., a substituent.

Substituents of the substituted alkyl group, the substituted cycloalkyl group, the substituted aryl(ene) group, and the substituted heteroaryl(ene) group in L, L′, Ar₁ to Ar₉, R₁₁ to R₁₈ and R₂₁ of formula 1 and formula 2, each independently are at least one selected from the group consisting of deuterium; a halogen; a (C1-C30)alkyl group; a (C1-C30)alkyl group substituted with a halogen; a (C6-C30)aryl group; a (C6-C30)aryloxy group; a 3- to 30-membered heteroaryl group unsubstituted or substituted with a (C6-C30)aryl; a (C3-C30)cycloalkyl group; a 3- to 30-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; a carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group, specifically each independently are at least one selected from the group consisting of deuterium, chlorine, a methyl group, an ethyl group, an n-propyl group, an i-propyl group, an n-butyl group, an i-butyl group, a t-butyl group, an n-pentyl group, an i-pentyl group, an n-hexyl group, an n-heptyl group, an n-octyl group, a 2-ethylhexyl group, an n-nonyl group, a decyl group, a dodecyl group, a hexadecyl group, a trifluoromethyl group, a perfluoroethyl group, a trifluoroethyl group, a perfluoropropyl group, a perfluorobutyl group, a phenyl group, a naphthyl group, a biphenyl group, a fluorenyl group, a phenanthryl group, an anthryl group, a fluoranthenyl group, a triphenylenyl group, a pyrenyl group, a chrysenyl group, a naphthacenyl group, a perylenyl group, a trimethylsilyl group, a triethylsilyl group, a tripropylsilyl group, a tri(t-butyl)silyl group, a t-butyldimethylsilyl group, a dimethylphenylsilyl group and a triphenylsilyl group, preferably each independently are at least one selected from the group consisting of deuterium, a halogen, a (C1-C6)alkyl group, a (C6-C15)aryl group, a (C6-C15)aryloxy group, and 3- to 15-membered heteroaryl group.

In formula 1, above, L represents a substituted or unsubstituted (C6-C30)arylene group, or a substituted or unsubstituted 3- to 30-membered heteroarylene group; preferably a substituted or unsubstituted (C6-C20)arylene group; more preferably a (C6-C15)arylene group unsubstituted or substituted with a (C1-C6)alkyl group.

A₁ to A₁₁ each independently represent CR₁₁ or N.

B₁ to B₃ each independently represent CR₂₁ or N, provided that B₁ to B₃ are not simultaneously CR₂₁.

Ar₁ to Ar_{g} each independently represent hydrogen, deuterium, a halogen, a cyano group, a nitro group, a hydroxyl group, a substituted or unsubstituted (C1-C30)alkyl group, a substituted or unsubstituted (C3-C30)cycloalkyl group, a substituted or unsubstituted (C6-C30)aryl group, a substituted or unsubstituted 3- to 30-membered heteroaryl group, —NR₁₂R₁₃, —SiR₁₄R₁₅R₁₆, —SR₁₇ or —OR₁₈; preferably hydrogen, a halogen, an unsubstituted (C1-C10)alkyl group, an unsubstituted (C3-C10)cycloalkyl group, a substituted or unsubstituted (C6-C20)aryl group, a substituted or unsubstituted 3- to 20-membered heteroaryl group, or —SiR₁₄R₁₅R₁₆; more preferably hydrogen, a halogen, an unsubstituted (C1-C6)alkyl group, an unsubstituted (C3-C7)cycloalkyl group; a (C6-C15)aryl group unsubstituted or substituted with deuterium, a halogen, a (C1-C6)alkyl group, a (C6-C15)aryl group, a (C6-C15)aryloxy group, or a 3- to 15-membered heteroaryl group; a 3- to 15-membered heteroaryl group unsubstituted or substituted with a (C6-C15)aryl group; or —SiR₁₄R₁₅R₁₆.

R₁₁ to R₁₈ and R₂₁ each independently represent hydrogen, deuterium, a halogen, a substituted or unsubstituted (C1-C30)alkyl group, a substituted or unsubstituted (C3-C30)cycloalkyl group, a substituted or unsubstituted (C6-C30)aryl group, or a substituted or unsubstituted 3- to 30-membered heteroaryl group; or are linked to an adjacent substituent(s) to form a substituted or unsubstituted mono- or polycyclic 3- to 30-membered alicyclic or aromatic ring whose carbon atom(s) may be replaced by at least one heteroatom selected from nitrogen, oxygen and sulfur; preferably hydrogen, a halogen, an unsubstituted (C1-C10)alkyl group, an unsubstituted (C3-C10)cycloalkyl group, a substituted or unsubstituted (C6-C20)aryl group, or an unsubstituted 3- to 20-membered heteroaryl group; or are linked to an adjacent substituent(s) to form a substituted or unsubstituted mono- or polycyclic 3- to 20-membered aromatic ring whose carbon atom(s) may be replaced by at least one heteroatom selected from nitrogen, oxygen and sulfur; more preferably hydrogen, a halogen, an unsubstituted (C1-C6)alkyl group, an unsubstituted (C3-C7)cycloalkyl group; a (C6-C15)aryl group unsubstituted or substituted with deuterium, a halogen, or a (C1-C6)alkyl group; or an unsubstituted 3- to 15-membered heteroaryl group; or are linked to an adjacent substituent(s) to form a mono- or polycyclic 3- to 15-membered aromatic ring unsubstituted or substituted with a (C1-C6)alkyl group or a (C6-C15)aryl group, whose carbon atom(s) may be replaced by at least one heteroatom selected from nitrogen, oxygen and sulfur.

o represents an integer of 0 to 2; where o is 2, each of L is the same or different.

m and n each independently represent 0 or 1, and m+n=1.

l represents an integer of 1 to 4; where l is an integer of 2 or more, each of A₆ to A₁₁ is the same or different; preferably 1 or 2; where l is 2, each of A₆ to A₁₁ is the same or different.

According to an embodiment of the present invention in formula 1, above, L represents a substituted or unsubstituted (C6-C20)arylene group; A₁ to A₁₁ each independently represent CR₁₁ or N; B₁ to B₃ each independently represent CR₂₁ or N, provided that B₁ to B₃ are not simultaneously CR₂₁; Ar₁ to Ar₉ each independently represent hydrogen, a halogen, an unsubstituted (C1-C10)alkyl group, an unsubstituted (C3-C10)cycloalkyl group, a substituted or unsubstituted (C6-C20)aryl group, a substituted or unsubstituted 3- to 20-membered heteroaryl group, or —SiR₁₄R₁₅R₁₆; R₁₁ to R₁₈ and R₂₁ each independently represent hydrogen, a halogen, an unsubstituted (C1-C10)alkyl group, an unsubstituted (C3-C10)cycloalkyl group, a substituted or unsubstituted (C6-C20)aryl group, or an unsubstituted 3- to 20-membered heteroaryl group; or are linked to an adjacent substituent(s) to form a substituted or unsubstituted mono- or polycyclic 3- to 20-membered aromatic ring whose carbon atom(s) may be replaced by at least one heteroatom selected from nitrogen, oxygen and sulfur; o represents an integer of 0 to 2; where o is 2, each of L is the same or different; m and n each independently represent 0 or 1, and m+n=1; and I represents 1 or 2; where I is 2, each of A₆ to A₁₁ is the same or different According to another embodiment of the present invention in formula 1 above, L represents a (C6-C15)arylene group unsubstituted or substituted with a (C1-C6)alkyl group; A₁ to A₁₁ each independently represent CR₁₁ or N; B₁ to B₃ each independently represent CR₂₁ or N, provided that B₁ to B₃ are not simultaneously CR₂₁; Ar₁ to Ar₉ each independently represent hydrogen, a halogen, an unsubstituted (C1-C6)alkyl group, an unsubstituted (C3-C7)cycloalkyl group; a (C6-C15)aryl group unsubstituted or substituted with deuterium, a halogen, a (C1-C6)alkyl group, a (C6-C15)aryl group, a (C6-C15)aryloxy group, or a 3- to 15-membered heteroaryl group; a 3- to 15-membered heteroaryl group unsubstituted or substituted with a (C6-C15)aryl group; or —SiR₁₄R₁₅R₁₆; R₁₁ to R₁₈ and R₂₁ each independently represent hydrogen, a halogen, an unsubstituted (C1-C6)alkyl group, an unsubstituted (C3-C7)cycloalkyl group; a (C6-C15)aryl group unsubstituted or substituted with deuterium, a halogen, or a (C1-C6)alkyl group; or an unsubstituted 3- to 15-membered heteroaryl group; or are linked to an adjacent substituent(s) to form a mono- or polycyclic 3- to 15-membered aromatic ring unsubstituted or substituted with a (C1-C6)alkyl group or a (C6-C15)aryl group, whose carbon atom(s) may be replaced by at least one heteroatom selected from nitrogen, oxygen and sulfur; o represents an integer of 0 to 2; where o is 2, each of L is the same or different; m and n each independently represent 0 or 1, and m+n=1; and I represents 1 or 2; where I is 2, each of A₆ to A₁₁ is the same or different.

Specifically, L represents a phenylene, naphthylene, biphenylene, fluorenylene, phenanthrenylene, anthracenylene, pyridinylene, pyrimidinylene, triazinylene, furanylene, thiophenylene, dibenzothiophenylene, dibenzofuranylene or phenylene-dibenzothiophenylene group;

Ar₁ to Ar₉ each independently represent hydrogen, deuterium, chlorine, fluorine, a phenyl group, a naphthyl group, a biphenyl group, a fluorenyl group, a phenanthryl group, an anthryl group, a fluoranthenyl group, a triphenylenyl group, a pyrenyl group, a chrysenyl group, a naphthacenyl group, a pherylenyl group, a pyridyl group, a pyrrolyl group, a furanyl group, a thiophenyl group, an imidazolyl group, a benzoimidazolyl group, a pyrazinyl group, a pyrimidinyl group, a pyridazinyl group, a quinolyl group, a triazinyl group, a benzofuranyl group, a dibenzofuranyl group, a benzothiophenyl group, a dibenzothiophenyl group, a pyrazolyl group, an indolyl group, a carbazolyl group, a thiazolyl group, an oxazolyl group, a benzothiazolyl group, a benzoxazolyl group, a phenanthrolinyl group or an N-carbazolyl group;

R₁₁ to R₁₈ and R₂₁ each independently represent hydrogen, deuterium, a phenyl group, a naphthyl group, a biphenyl group, a fluorenyl group, a phenanthryl group, an anthryl group, a fluoranthenyl group, a triphenylenyl group, a pyrenyl group, a chrysenyl group, a naphthacenyl group, a pherylenyl group, a pyridyl group, a pyrrolyl group, a furanyl group, a thiophenyl group, an imidazolyl group, a benzoimidazolyl group, a pyrazinyl group, a pyrimidinyl group, a pyridazinyl group, a quinolyl group, a triazinyl group, a benzofuranyl group, a dibenzofuranyl group, a dibenzothiophenyl group, a benzothiophenyl group, a pyrazolyl group, an indolyl group, a carbazolyl group, a thiazolyl group, an oxazolyl group, a benzothiazolyl group, a benzoxazolyl group, a phenanthrolinyl group or an N-carbazolyl group.

The representative organic electroluminescent compounds of the present invention include the following compounds, but not limited thereto:

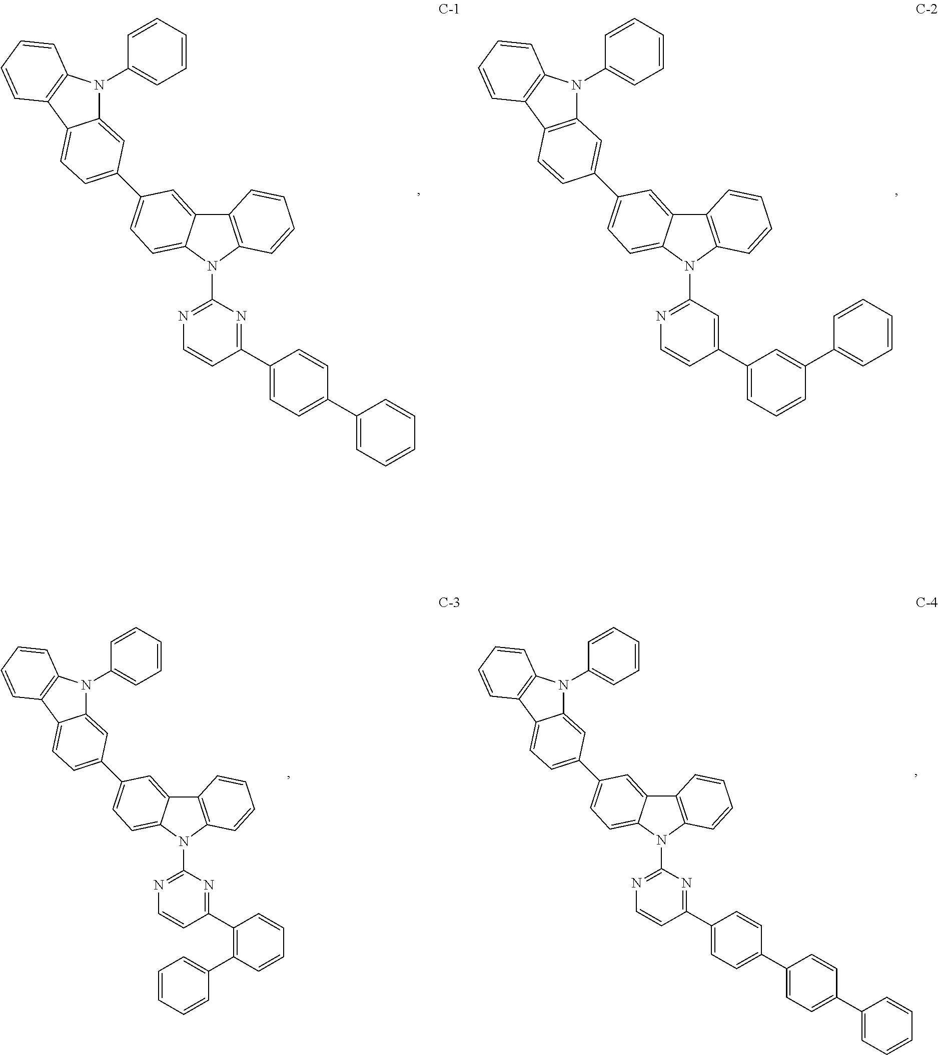 [SMILES: c1ccc(-c2ccc(-c3ccnc(-n4c5ccccc5c5cc(-c6ccc7c8ccccc8n(-c8ccccc8)c7c6)ccc54)n3)cc2)cc1 ; c1ccc(-c2cccc(-c3ccnc(-n4c5ccccc5c5cc(-c6ccc7c8ccccc8n(-c8ccccc8)c7c6)ccc54)c3)c2)cc1 ; c1ccc(-c2ccccc2-c2ccnc(-n3c4ccccc4c4cc(-c5ccc6c7ccccc7n(-c7ccccc7)c6c5)ccc43)n2)cc1 ; c1ccc(-c2ccc(-c3ccc(-c4ccnc(-n5c6ccccc6c6cc(-c7ccc8c9ccccc9n(-c9ccccc9)c8c7)ccc65)n4)cc3)cc2)cc1]

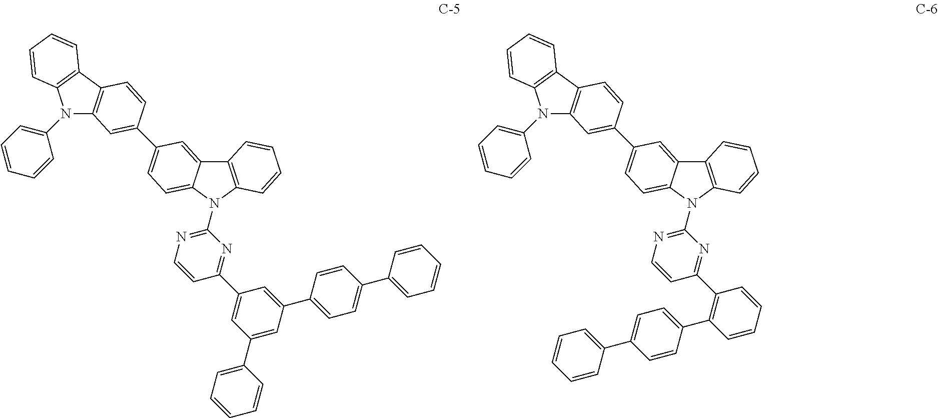 [SMILES: c1ccc(-c2ccc(-c3cc(-c4ccccc4)cc(-c4ccnc(-n5c6ccccc6c6cc(-c7ccc8c9ccccc9n(-c9ccccc9)c8c7)ccc65)n4)c3)cc2)cc1 ; c1ccc(-c2ccc(-c3ccccc3-c3ccnc(-n4c5ccccc5c5cc(-c6ccc7c8ccccc8n(-c8ccccc8)c7c6)ccc54)n3)cc2)cc1]

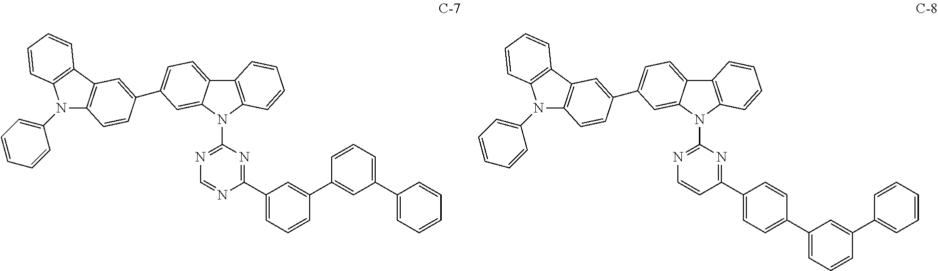 [SMILES: c1ccc(-c2cccc(-c3cccc(-c4ncnc(-n5c6ccccc6c6ccc(-c7ccc8c(c7)c7ccccc7n8-c7ccccc7)cc65)n4)c3)c2)cc1 ; c1ccc(-c2cccc(-c3ccc(-c4ccnc(-n5c6ccccc6c6ccc(-c7ccc8c(c7)c7ccccc7n8-c7ccccc7)cc65)n4)cc3)c2)cc1]

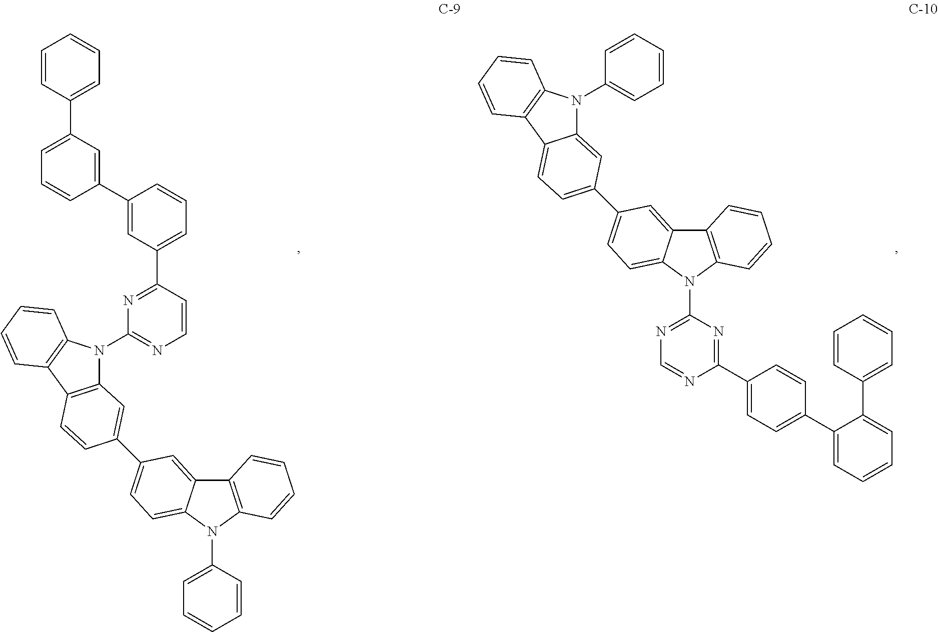 [SMILES: c1ccc(-c2cccc(-c3cccc(-c4ccnc(-n5c6ccccc6c6ccc(-c7ccc8c(c7)c7ccccc7n8-c7ccccc7)cc65)n4)c3)c2)cc1 ; c1ccc(-c2ccccc2-c2ccc(-c3ncnc(-n4c5ccccc5c5cc(-c6ccc7c8ccccc8n(-c8ccccc8)c7c6)ccc54)n3)cc2)cc1]

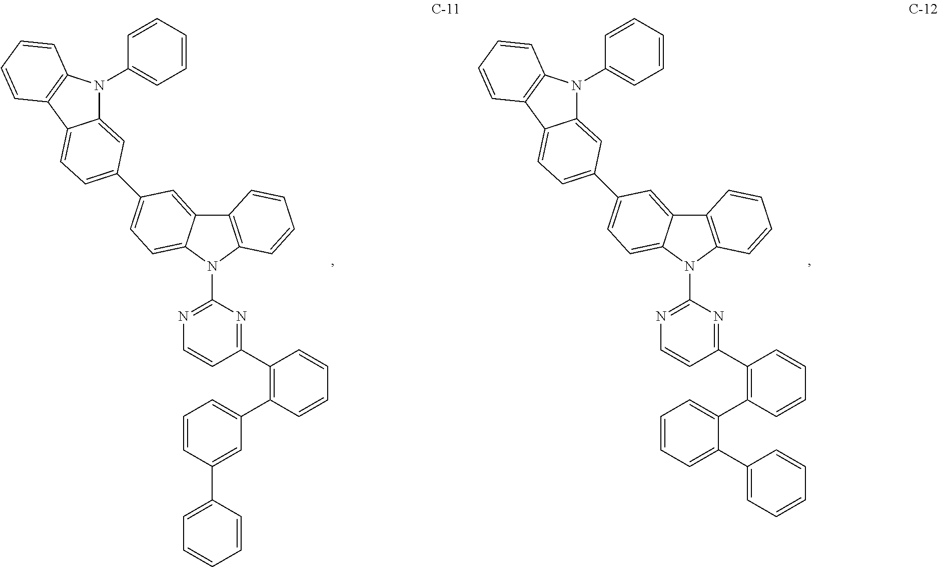 [SMILES: c1ccc(-c2cccc(-c3ccccc3-c3ccnc(-n4c5ccccc5c5cc(-c6ccc7c8ccccc8n(-c8ccccc8)c7c6)ccc54)n3)c2)cc1 ; c1ccc(-c2ccccc2-c2ccccc2-c2ccnc(-n3c4ccccc4c4cc(-c5ccc6c7ccccc7n(-c7ccccc7)c6c5)ccc43)n2)cc1]

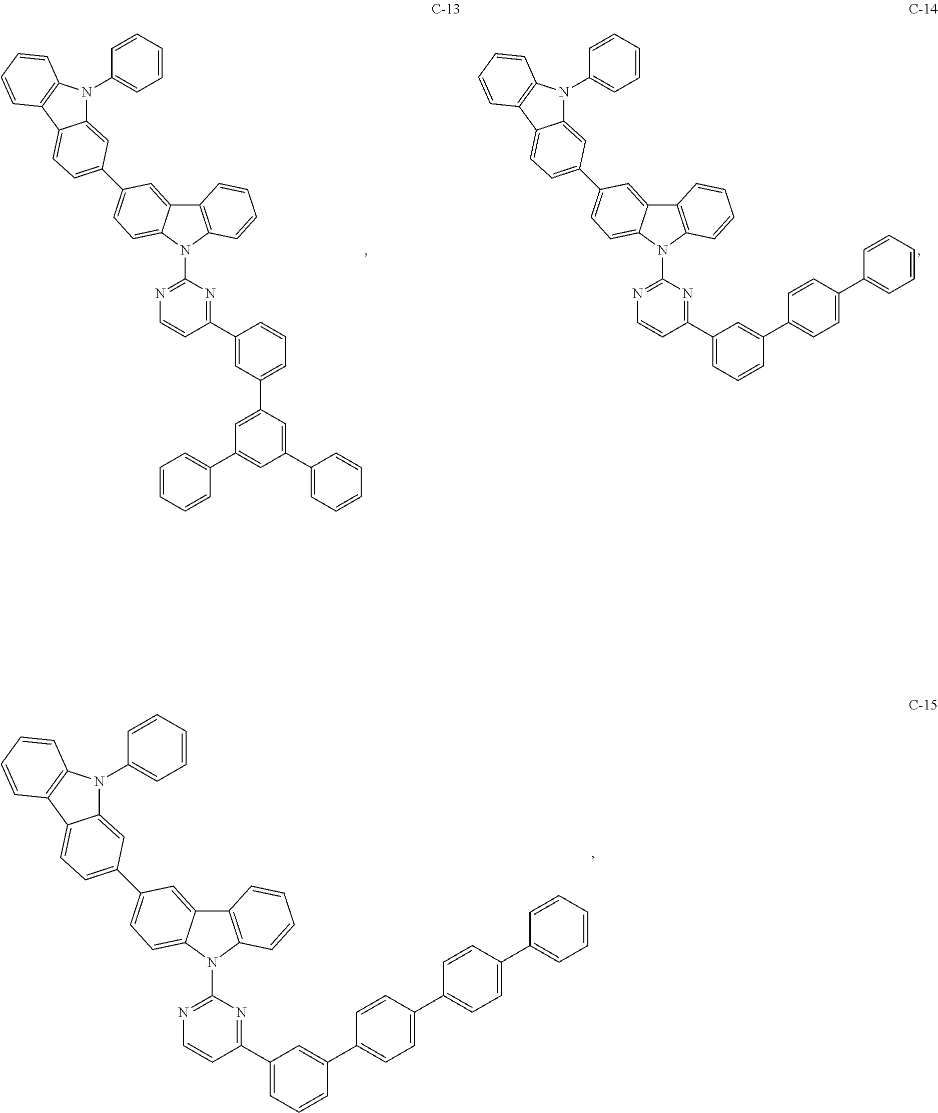 [SMILES: c1ccc(-c2cc(-c3ccccc3)cc(-c3cccc(-c4ccnc(-n5c6ccccc6c6cc(-c7ccc8c9ccccc9n(-c9ccccc9)c8c7)ccc65)n4)c3)c2)cc1 ; c1ccc(-c2ccc(-c3cccc(-c4ccnc(-n5c6ccccc6c6cc(-c7ccc8c9ccccc9n(-c9ccccc9)c8c7)ccc65)n4)c3)cc2)cc1 ; c1ccc(-c2ccc(-c3ccc(-c4cccc(-c5ccnc(-n6c7ccccc7c7cc(-c8ccc9c%10ccccc%10n(-c%10ccccc%10)c9c8)ccc76)n5)c4)cc3)cc2)cc1]

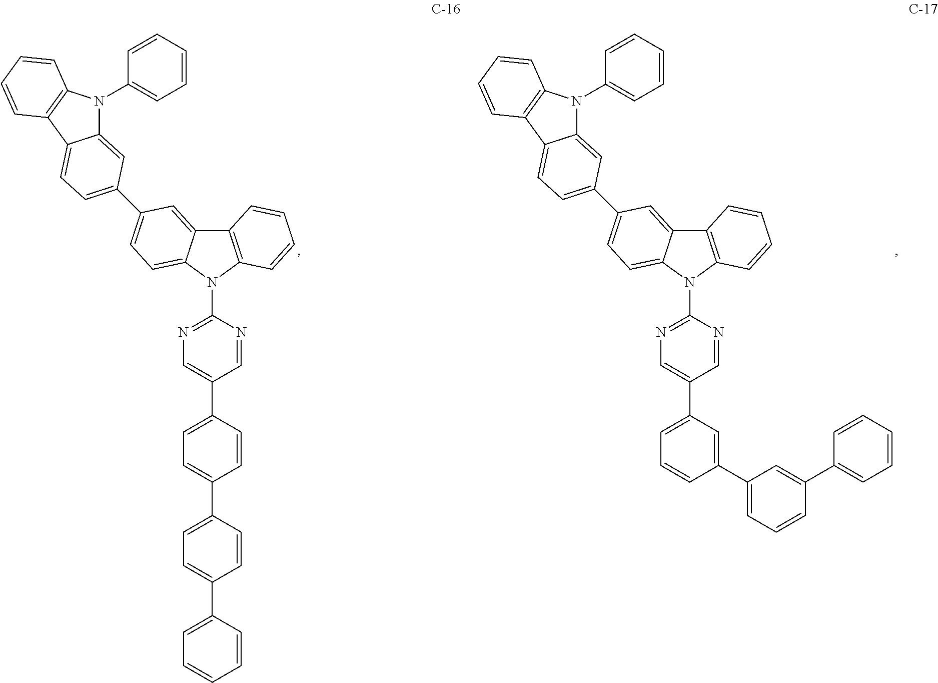 [SMILES: c1ccc(-c2ccc(-c3ccc(-c4cnc(-n5c6ccccc6c6cc(-c7ccc8c9ccccc9n(-c9ccccc9)c8c7)ccc65)nc4)cc3)cc2)cc1 ; c1ccc(-c2cccc(-c3cccc(-c4cnc(-n5c6ccccc6c6cc(-c7ccc8c9ccccc9n(-c9ccccc9)c8c7)ccc65)nc4)c3)c2)cc1]

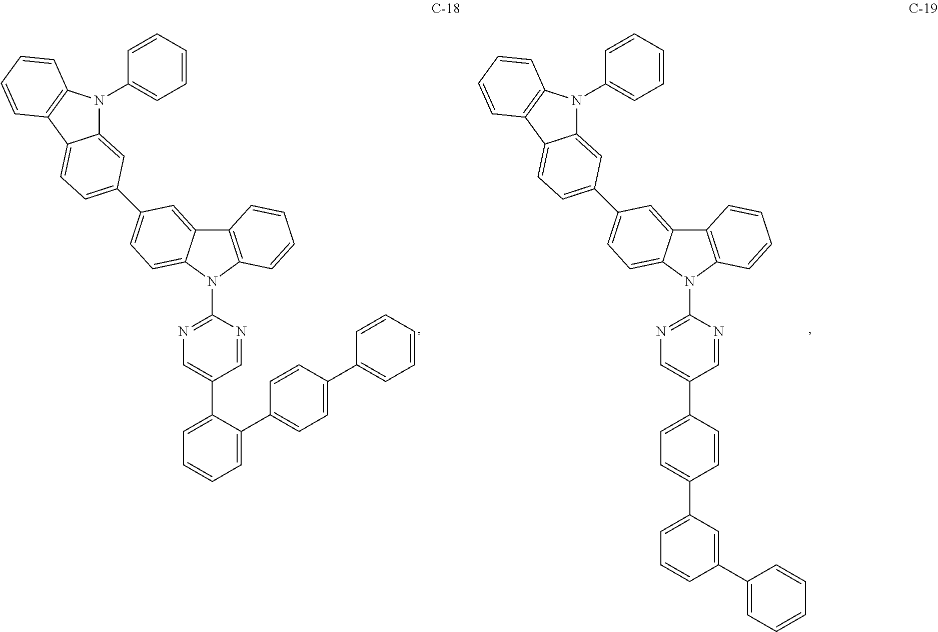 [SMILES: c1ccc(-c2ccc(-c3ccccc3-c3cnc(-n4c5ccccc5c5cc(-c6ccc7c8ccccc8n(-c8ccccc8)c7c6)ccc54)nc3)cc2)cc1 ; c1ccc(-c2cccc(-c3ccc(-c4cnc(-n5c6ccccc6c6cc(-c7ccc8c9ccccc9n(-c9ccccc9)c8c7)ccc65)nc4)cc3)c2)cc1]

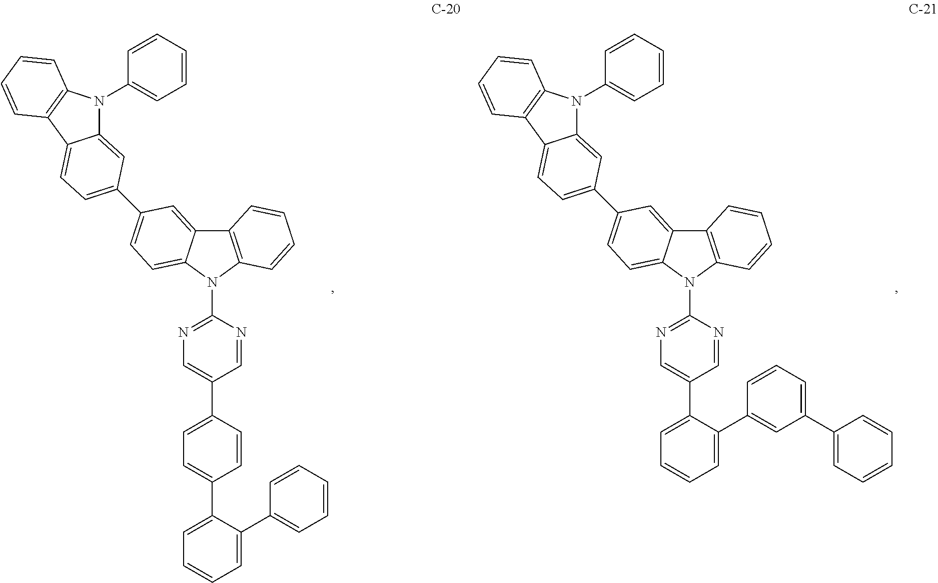 [SMILES: c1ccc(-c2ccccc2-c2ccc(-c3cnc(-n4c5ccccc5c5cc(-c6ccc7c8ccccc8n(-c8ccccc8)c7c6)ccc54)nc3)cc2)cc1 ; c1ccc(-c2cccc(-c3ccccc3-c3cnc(-n4c5ccccc5c5cc(-c6ccc7c8ccccc8n(-c8ccccc8)c7c6)ccc54)nc3)c2)cc1]

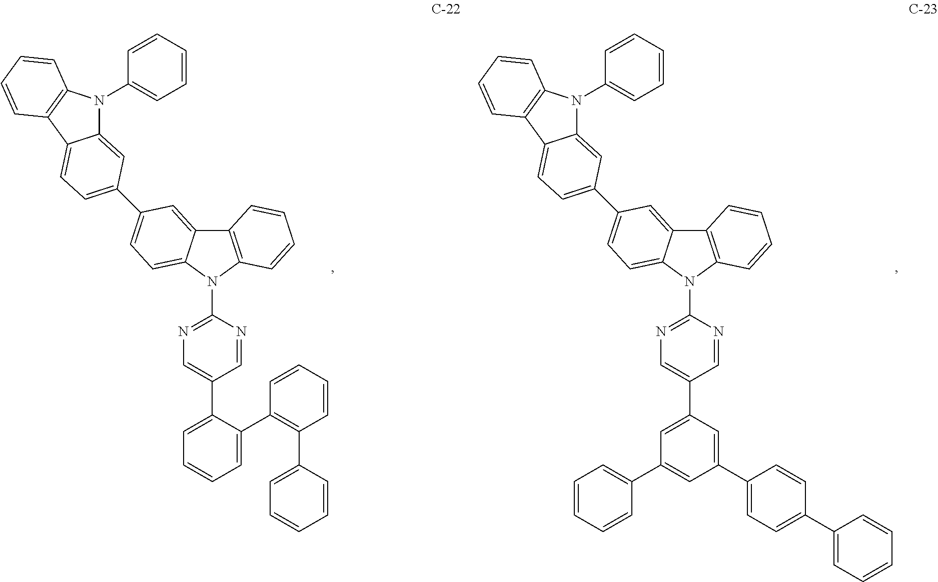 [SMILES: c1ccc(-c2ccccc2-c2ccccc2-c2cnc(-n3c4ccccc4c4cc(-c5ccc6c7ccccc7n(-c7ccccc7)c6c5)ccc43)nc2)cc1 ; c1ccc(-c2ccc(-c3cc(-c4ccccc4)cc(-c4cnc(-n5c6ccccc6c6cc(-c7ccc8c9ccccc9n(-c9ccccc9)c8c7)ccc65)nc4)c3)cc2)cc1]

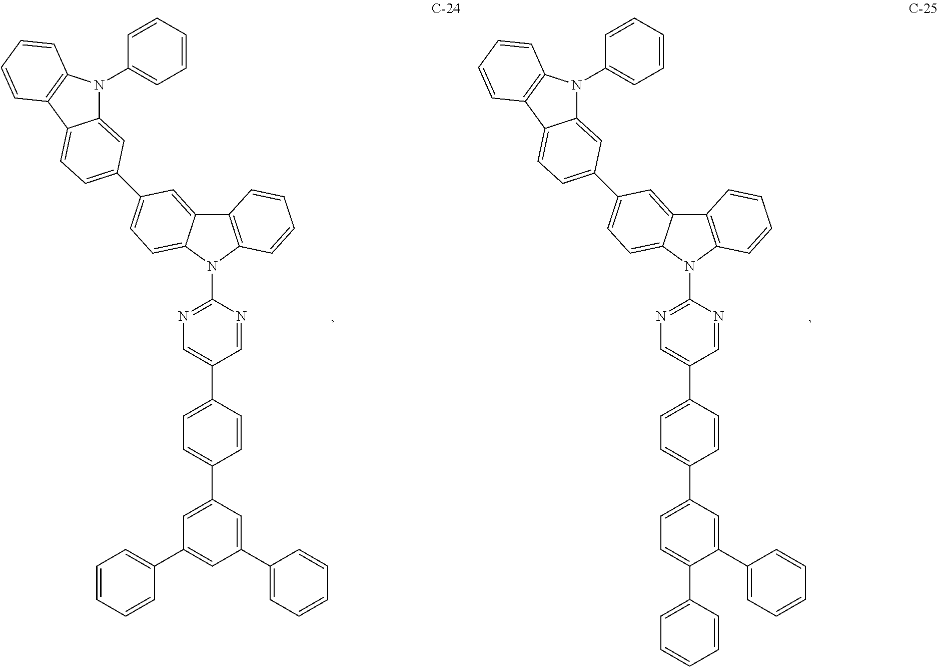 [SMILES: c1ccc(-c2cc(-c3ccccc3)cc(-c3ccc(-c4cnc(-n5c6ccccc6c6cc(-c7ccc8c9ccccc9n(-c9ccccc9)c8c7)ccc65)nc4)cc3)c2)cc1 ; c1ccc(-c2ccc(-c3ccc(-c4cnc(-n5c6ccccc6c6cc(-c7ccc8c9ccccc9n(-c9ccccc9)c8c7)ccc65)nc4)cc3)cc2-c2ccccc2)cc1]

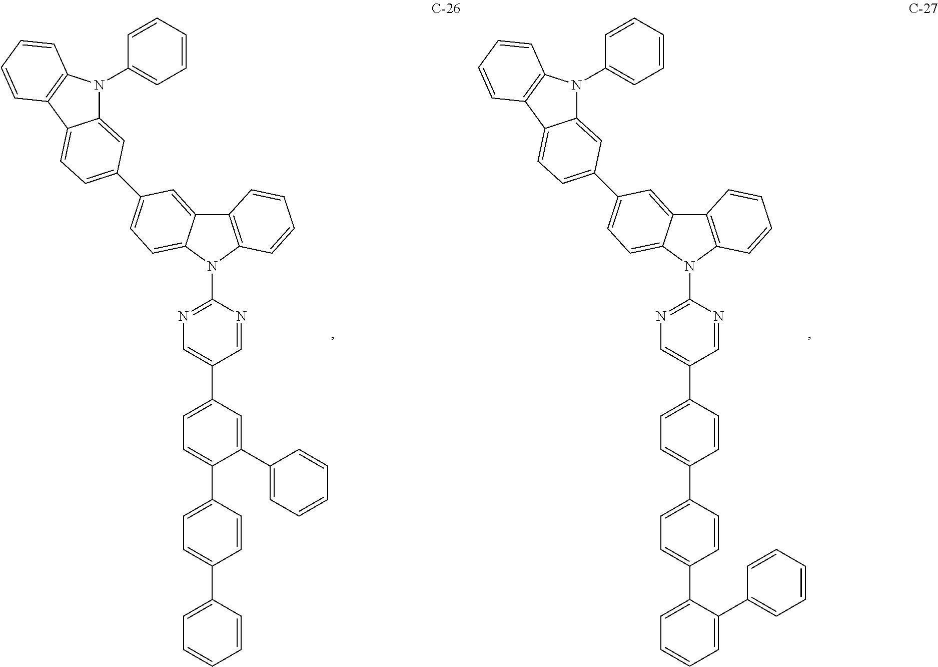 [SMILES: c1ccc(-c2ccc(-c3ccc(-c4cnc(-n5c6ccccc6c6cc(-c7ccc8c9ccccc9n(-c9ccccc9)c8c7)ccc65)nc4)cc3-c3ccccc3)cc2)cc1 ; c1ccc(-c2ccccc2-c2ccc(-c3ccc(-c4cnc(-n5c6ccccc6c6cc(-c7ccc8c9ccccc9n(-c9ccccc9)c8c7)ccc65)nc4)cc3)cc2)cc1]

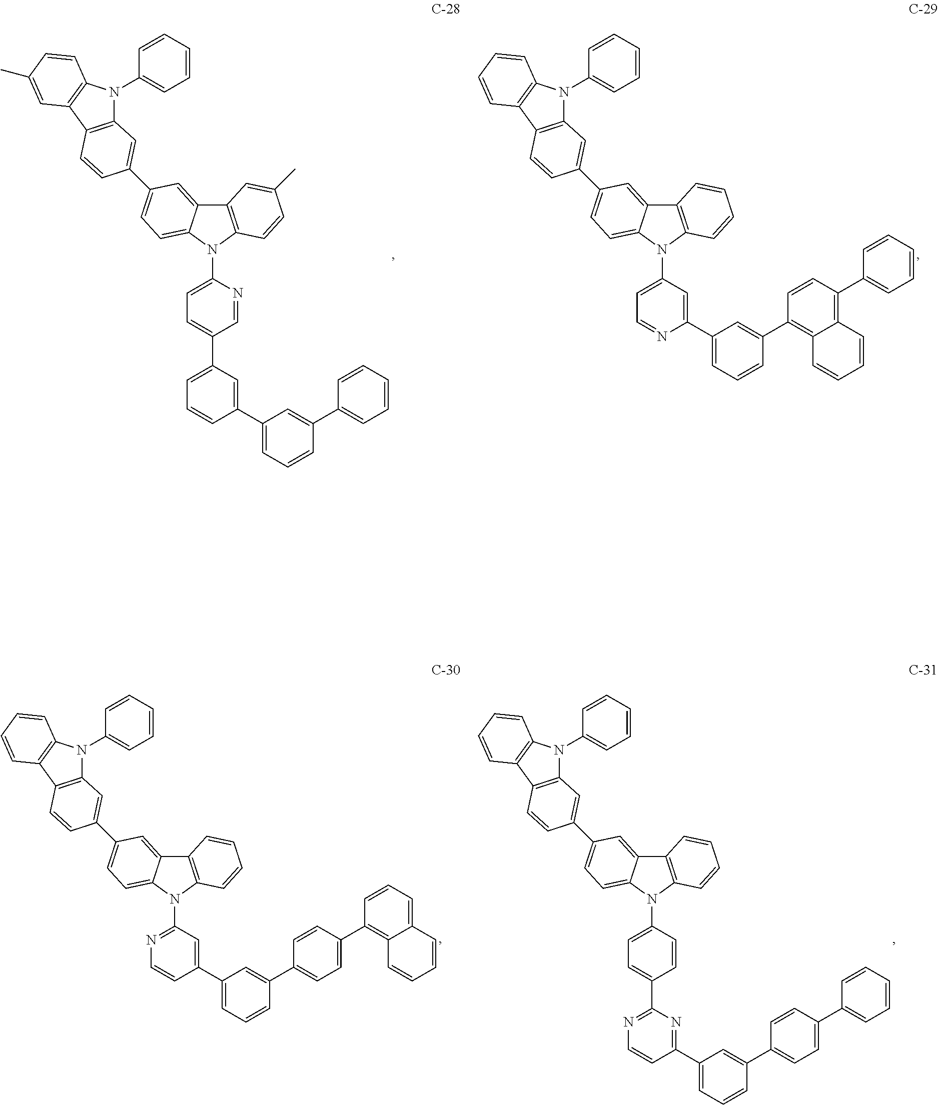 [SMILES: Cc1ccc2c(c1)c1ccc(-c3ccc4c(c3)c3cc(C)ccc3n4-c3ccc(-c4cccc(-c5cccc(-c6ccccc6)c5)c4)cn3)cc1n2-c1ccccc1 ; c1ccc(-c2ccc(-c3cccc(-c4cc(-n5c6ccccc6c6cc(-c7ccc8c9ccccc9n(-c9ccccc9)c8c7)ccc65)ccn4)c3)c3ccccc23)cc1 ; c1ccc(-n2c3ccccc3c3ccc(-c4ccc5c(c4)c4ccccc4n5-c4cc(-c5cccc(-c6ccc(-c7cccc8ccccc78)cc6)c5)ccn4)cc32)cc1 ; c1ccc(-c2ccc(-c3cccc(-c4ccnc(-c5ccc(-n6c7ccccc7c7cc(-c8ccc9c%10ccccc%10n(-c%10ccccc%10)c9c8)ccc76)cc5)n4)c3)cc2)cc1]

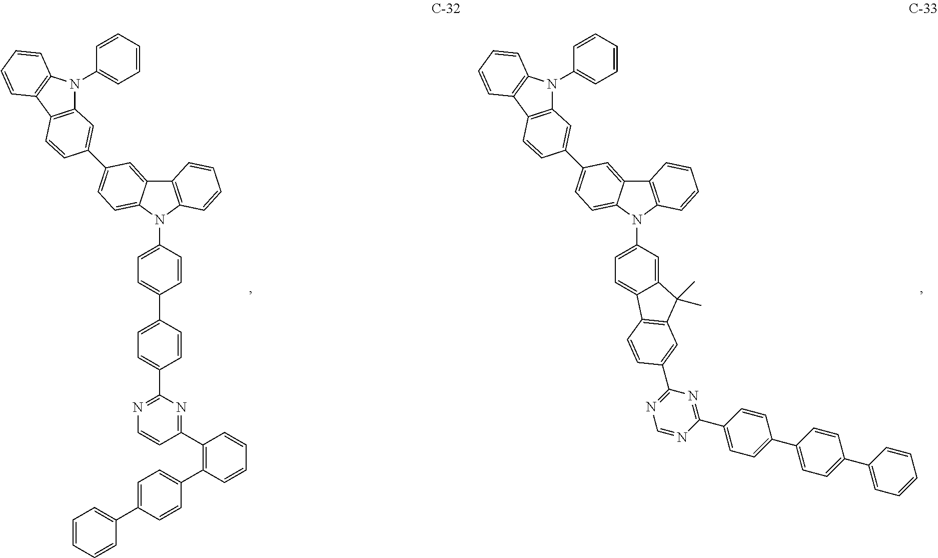 [SMILES: c1ccc(-c2ccc(-c3ccccc3-c3ccnc(-c4ccc(-c5ccc(-n6c7ccccc7c7cc(-c8ccc9c%10ccccc%10n(-c%10ccccc%10)c9c8)ccc76)cc5)cc4)n3)cc2)cc1 ; CC1(C)c2cc(-c3ncnc(-c4ccc(-c5ccc(-c6ccccc6)cc5)cc4)n3)ccc2-c2ccc(-n3c4ccccc4c4cc(-c5ccc6c7ccccc7n(-c7ccccc7)c6c5)ccc43)cc21]

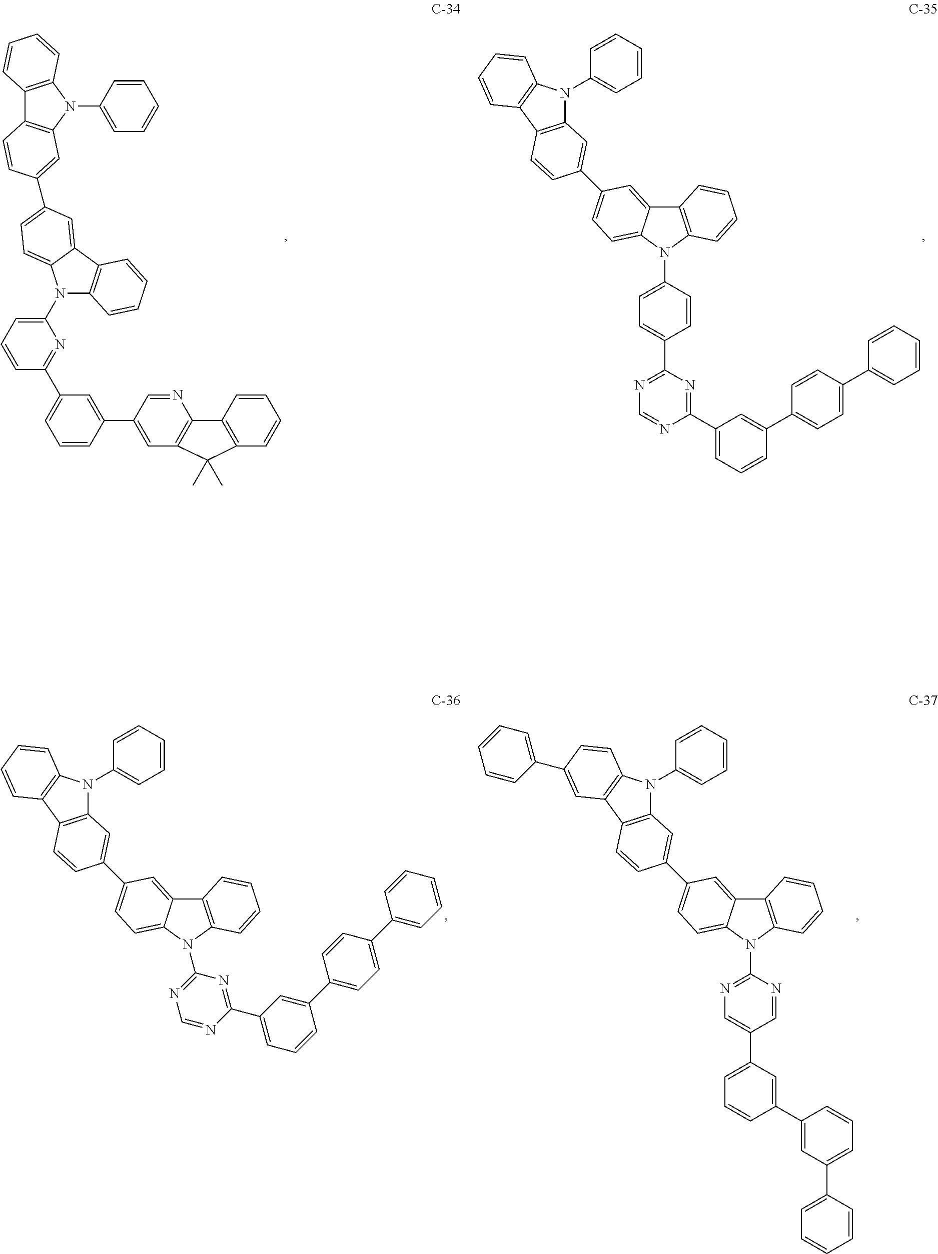 [SMILES: CC1(C)c2ccccc2-c2ncc(-c3cccc(-c4cccc(-n5c6ccccc6c6cc(-c7ccc8c9ccccc9n(-c9ccccc9)c8c7)ccc65)n4)c3)cc21 ; c1ccc(-c2ccc(-c3cccc(-c4ncnc(-c5ccc(-n6c7ccccc7c7cc(-c8ccc9c%10ccccc%10n(-c%10ccccc%10)c9c8)ccc76)cc5)n4)c3)cc2)cc1 ; c1ccc(-c2ccc(-c3cccc(-c4ncnc(-n5c6ccccc6c6cc(-c7ccc8c9ccccc9n(-c9ccccc9)c8c7)ccc65)n4)c3)cc2)cc1 ; c1ccc(-c2cccc(-c3cccc(-c4cnc(-n5c6ccccc6c6cc(-c7ccc8c9cc(-c%10ccccc%10)ccc9n(-c9ccccc9)c8c7)ccc65)nc4)c3)c2)cc1]

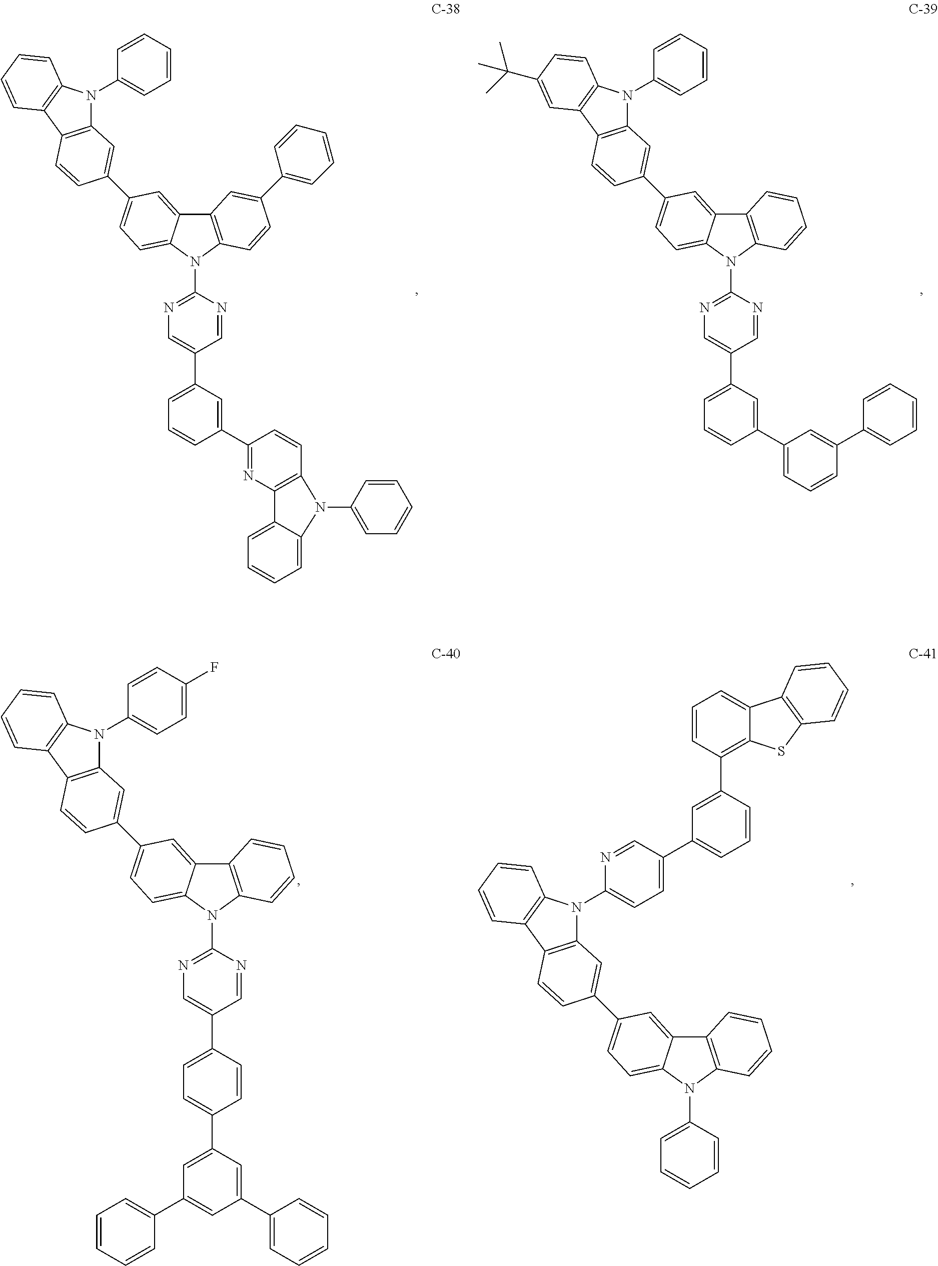 [SMILES: c1ccc(-c2ccc3c(c2)c2cc(-c4ccc5c6ccccc6n(-c6ccccc6)c5c4)ccc2n3-c2ncc(-c3cccc(-c4ccc5c(n4)c4ccccc4n5-c4ccccc4)c3)cn2)cc1 ; CC(C)(C)c1ccc2c(c1)c1ccc(-c3ccc4c(c3)c3ccccc3n4-c3ncc(-c4cccc(-c5cccc(-c6ccccc6)c5)c4)cn3)cc1n2-c1ccccc1 ; Fc1ccc(-n2c3ccccc3c3ccc(-c4ccc5c(c4)c4ccccc4n5-c4ncc(-c5ccc(-c6cc(-c7ccccc7)cc(-c7ccccc7)c6)cc5)cn4)cc32)cc1 ; c1ccc(-n2c3ccccc3c3cc(-c4ccc5c6ccccc6n(-c6ccc(-c7cccc(-c8cccc9c8sc8ccccc89)c7)cn6)c5c4)ccc32)cc1]

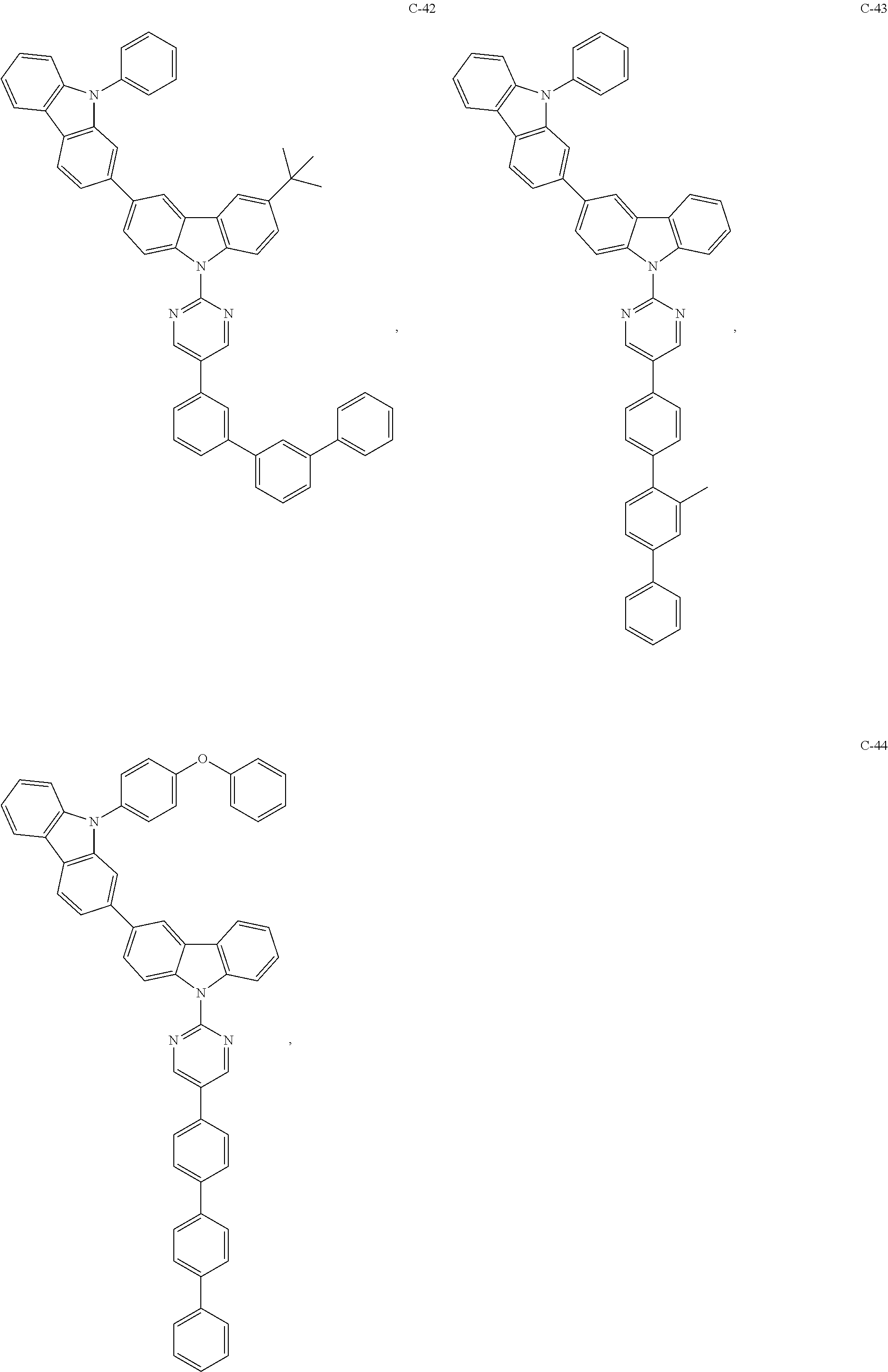 [SMILES: CC(C)(C)c1ccc2c(c1)c1cc(-c3ccc4c5ccccc5n(-c5ccccc5)c4c3)ccc1n2-c1ncc(-c2cccc(-c3cccc(-c4ccccc4)c3)c2)cn1 ; Cc1cc(-c2ccccc2)ccc1-c1ccc(-c2cnc(-n3c4ccccc4c4cc(-c5ccc6c7ccccc7n(-c7ccccc7)c6c5)ccc43)nc2)cc1 ; c1ccc(Oc2ccc(-n3c4ccccc4c4ccc(-c5ccc6c(c5)c5ccccc5n6-c5ncc(-c6ccc(-c7ccc(-c8ccccc8)cc7)cc6)cn5)cc43)cc2)cc1]

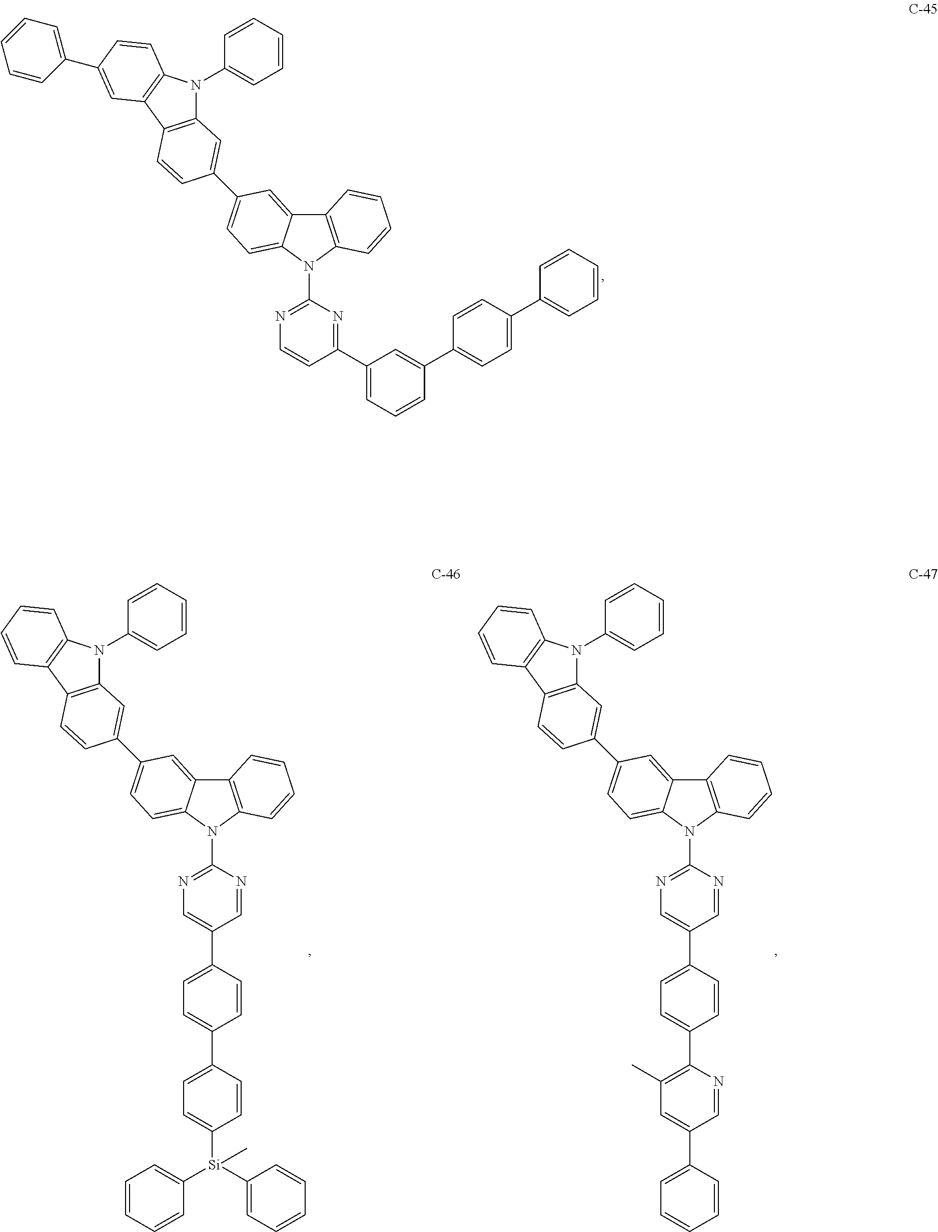 [SMILES: c1ccc(-c2ccc(-c3cccc(-c4ccnc(-n5c6ccccc6c6cc(-c7ccc8c9cc(-c%10ccccc%10)ccc9n(-c9ccccc9)c8c7)ccc65)n4)c3)cc2)cc1 ; C[Si](c1ccccc1)(c1ccccc1)c1ccc(-c2ccc(-c3cnc(-n4c5ccccc5c5cc(-c6ccc7c8ccccc8n(-c8ccccc8)c7c6)ccc54)nc3)cc2)cc1 ; Cc1cc(-c2ccccc2)cnc1-c1ccc(-c2cnc(-n3c4ccccc4c4cc(-c5ccc6c7ccccc7n(-c7ccccc7)c6c5)ccc43)nc2)cc1]

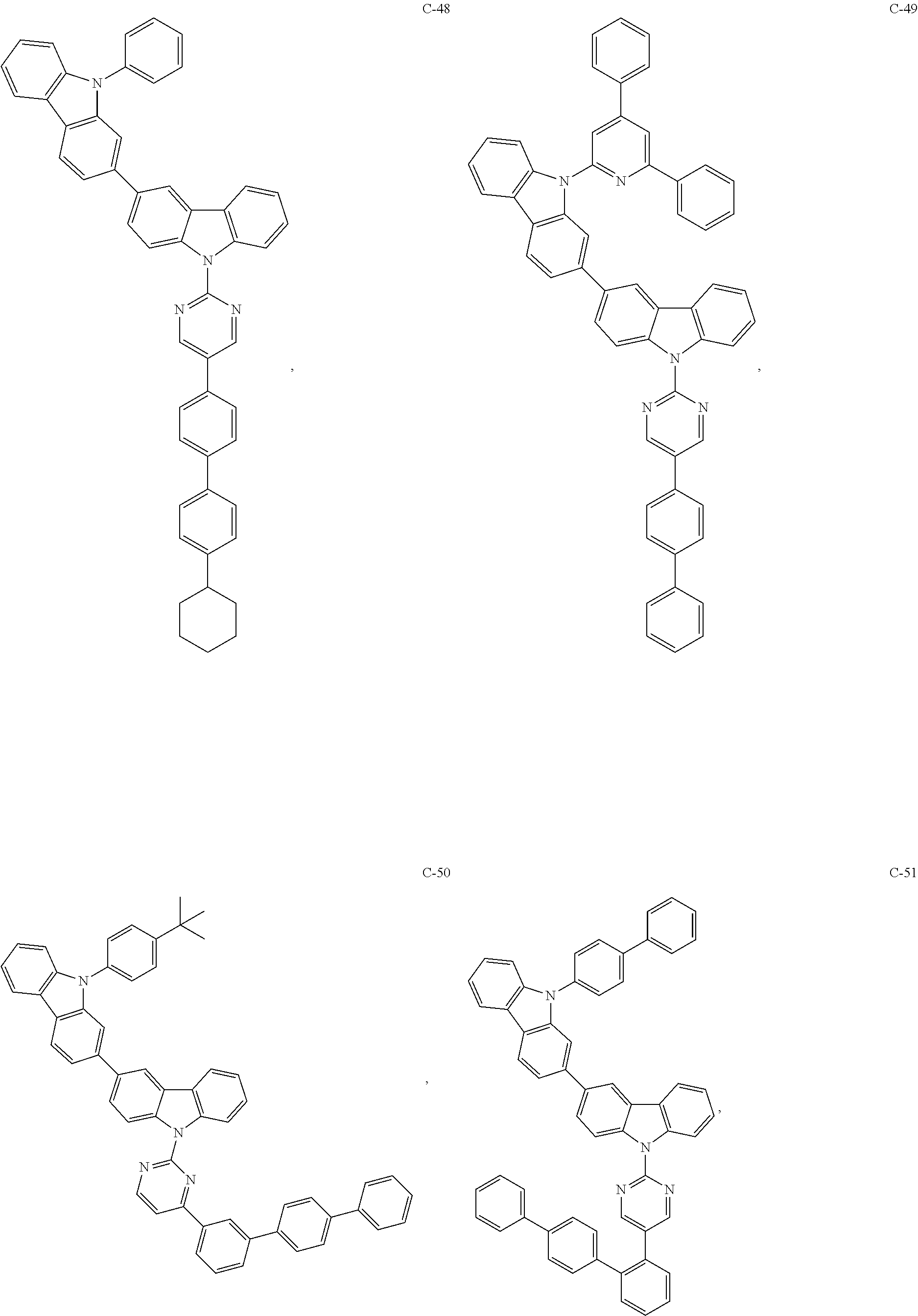 [SMILES: c1ccc(-n2c3ccccc3c3ccc(-c4ccc5c(c4)c4ccccc4n5-c4ncc(-c5ccc(-c6ccc(C7CCCCC7)cc6)cc5)cn4)cc32)cc1 ; c1ccc(-c2ccc(-c3cnc(-n4c5ccccc5c5cc(-c6ccc7c8ccccc8n(-c8cc(-c9ccccc9)cc(-c9ccccc9)n8)c7c6)ccc54)nc3)cc2)cc1 ; CC(C)(C)c1ccc(-n2c3ccccc3c3ccc(-c4ccc5c(c4)c4ccccc4n5-c4nccc(-c5cccc(-c6ccc(-c7ccccc7)cc6)c5)n4)cc32)cc1 ; c1ccc(-c2ccc(-c3ccccc3-c3cnc(-n4c5ccccc5c5cc(-c6ccc7c8ccccc8n(-c8ccc(-c9ccccc9)cc8)c7c6)ccc54)nc3)cc2)cc1]

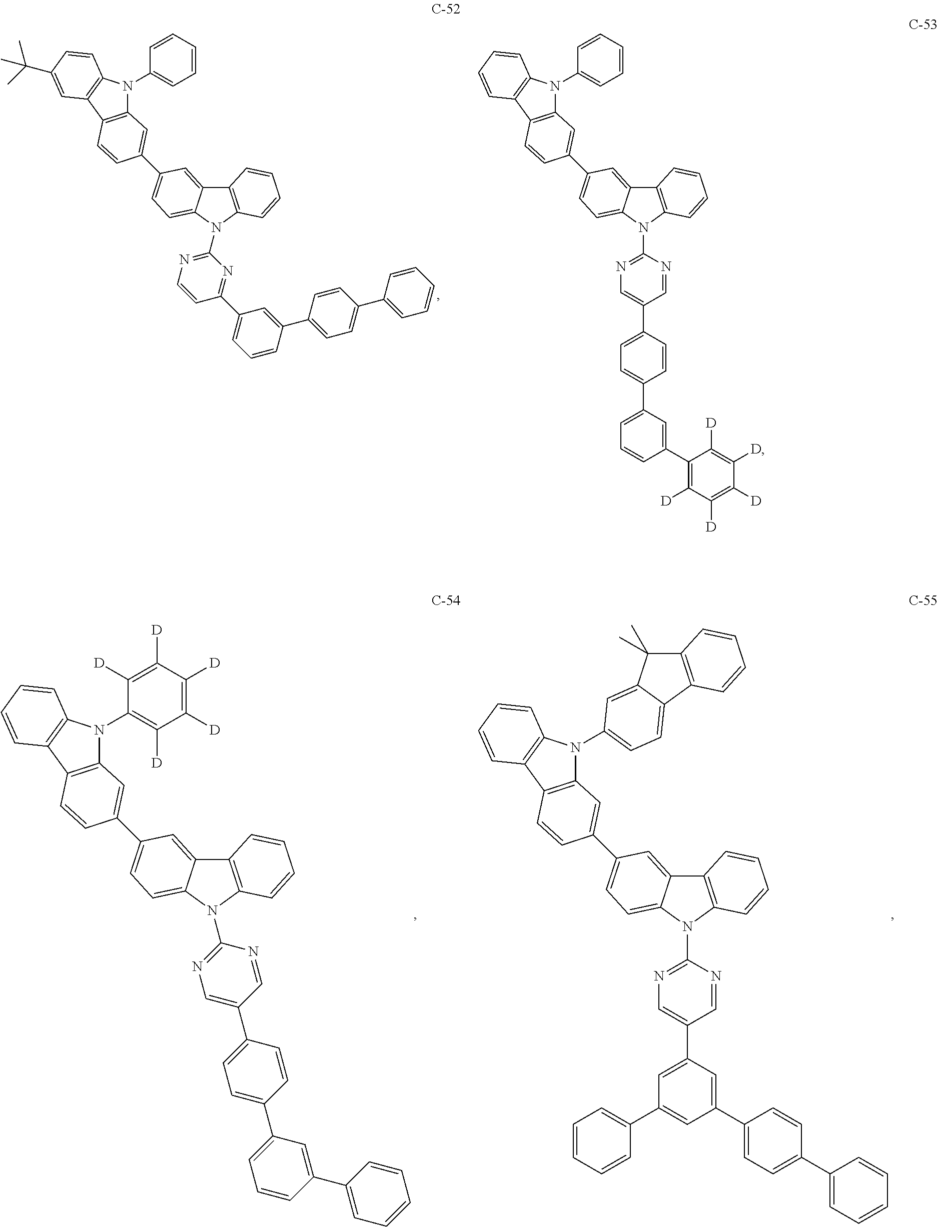

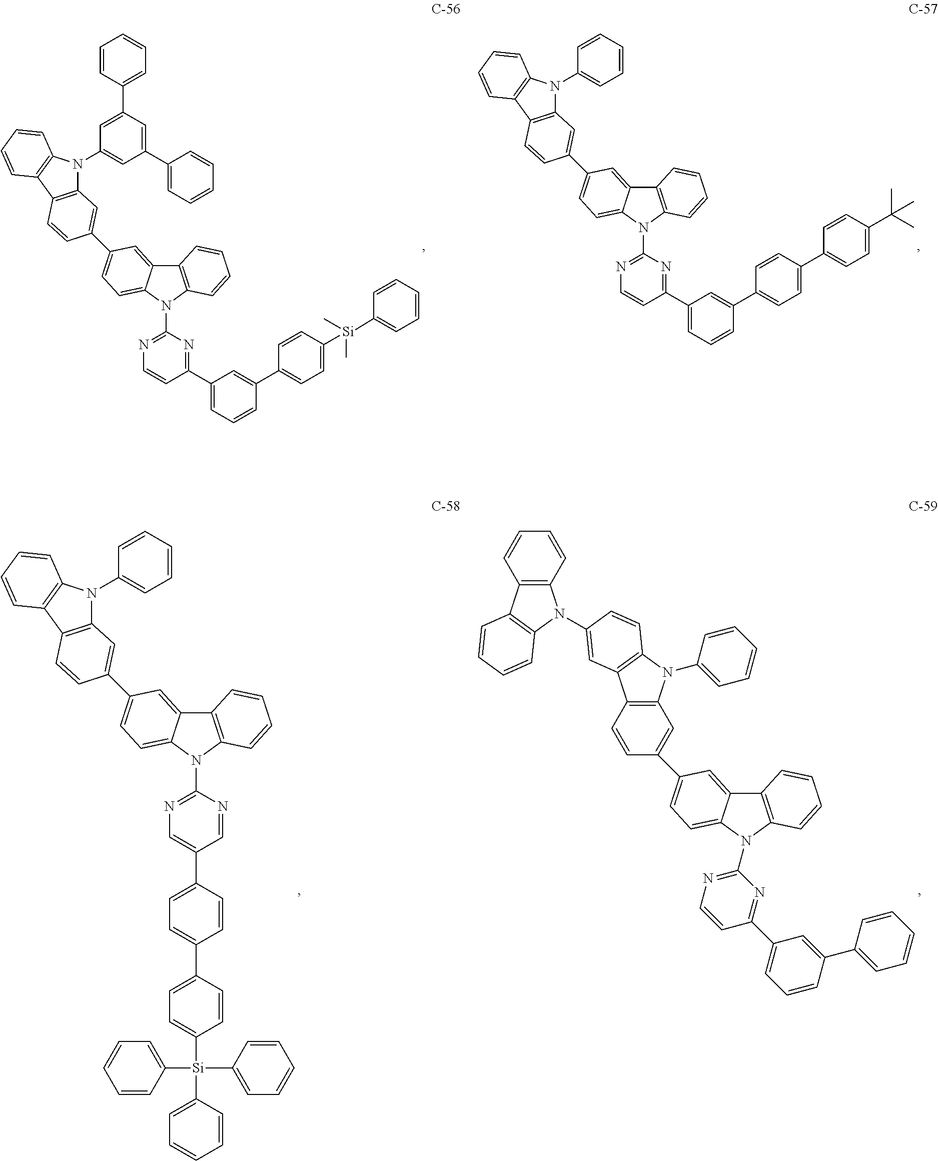 [SMILES: C[Si](C)(c1ccccc1)c1ccc(-c2cccc(-c3ccnc(-n4c5ccccc5c5cc(-c6ccc7c8ccccc8n(-c8cc(-c9ccccc9)cc(-c9ccccc9)c8)c7c6)ccc54)n3)c2)cc1 ; CC(C)(C)c1ccc(-c2ccc(-c3cccc(-c4ccnc(-n5c6ccccc6c6cc(-c7ccc8c9ccccc9n(-c9ccccc9)c8c7)ccc65)n4)c3)cc2)cc1 ; c1ccc(-n2c3ccccc3c3ccc(-c4ccc5c(c4)c4ccccc4n5-c4ncc(-c5ccc(-c6ccc([Si](c7ccccc7)(c7ccccc7)c7ccccc7)cc6)cc5)cn4)cc32)cc1 ; c1ccc(-c2cccc(-c3ccnc(-n4c5ccccc5c5cc(-c6ccc7c8cc(-n9c%10ccccc%10c%10ccccc%109)ccc8n(-c8ccccc8)c7c6)ccc54)n3)c2)cc1]

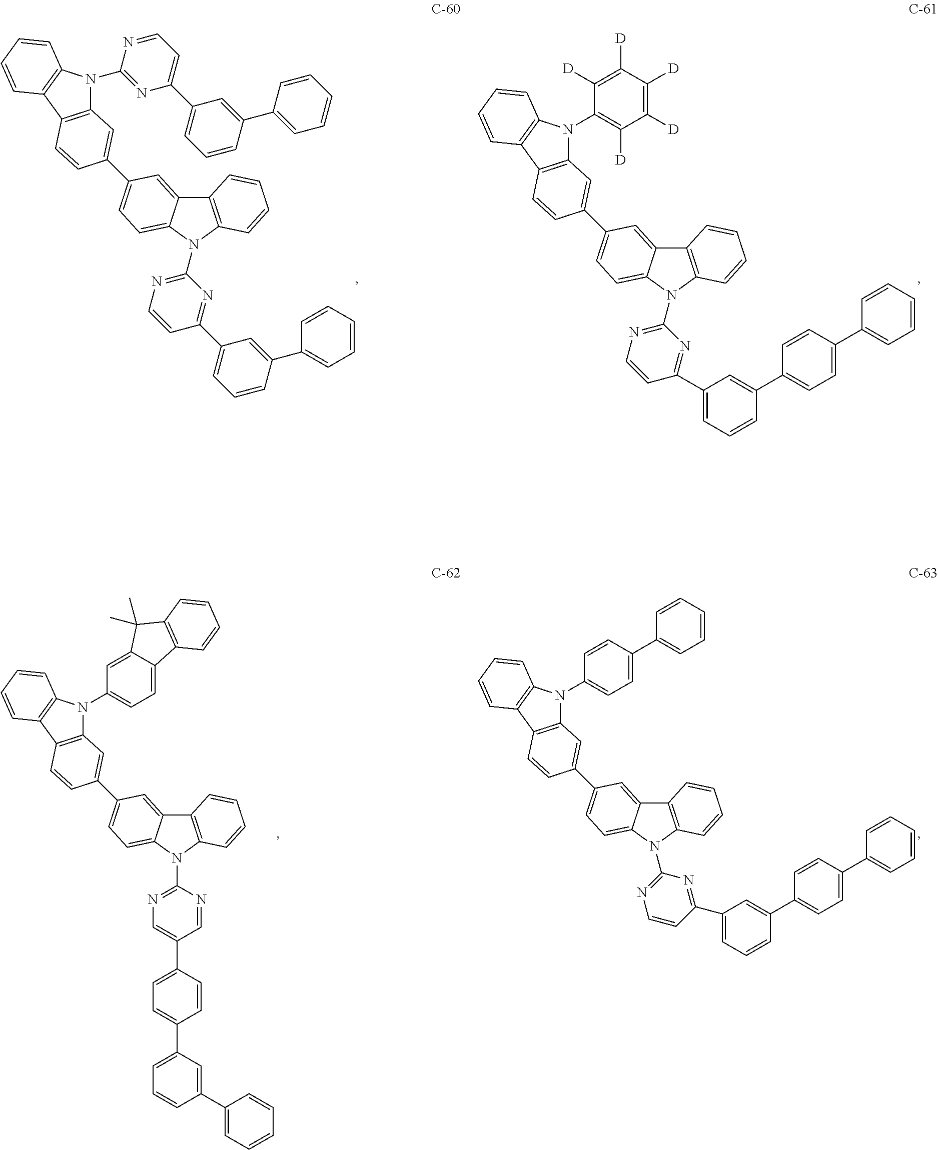 [SMILES: c1ccc(-c2cccc(-c3ccnc(-n4c5ccccc5c5cc(-c6ccc7c8ccccc8n(-c8nccc(-c9cccc(-c%10ccccc%10)c9)n8)c7c6)ccc54)n3)c2)cc1 ; [2H]c1c([2H])c([2H])c(-n2c3ccccc3c3ccc(-c4ccc5c(c4)c4ccccc4n5-c4nccc(-c5cccc(-c6ccc(-c7ccccc7)cc6)c5)n4)cc32)c([2H])c1[2H] ; CC1(C)c2ccccc2-c2ccc(-n3c4ccccc4c4ccc(-c5ccc6c(c5)c5ccccc5n6-c5ncc(-c6ccc(-c7cccc(-c8ccccc8)c7)cc6)cn5)cc43)cc21 ; c1ccc(-c2ccc(-c3cccc(-c4ccnc(-n5c6ccccc6c6cc(-c7ccc8c9ccccc9n(-c9ccc(-c%10ccccc%10)cc9)c8c7)ccc65)n4)c3)cc2)cc1]

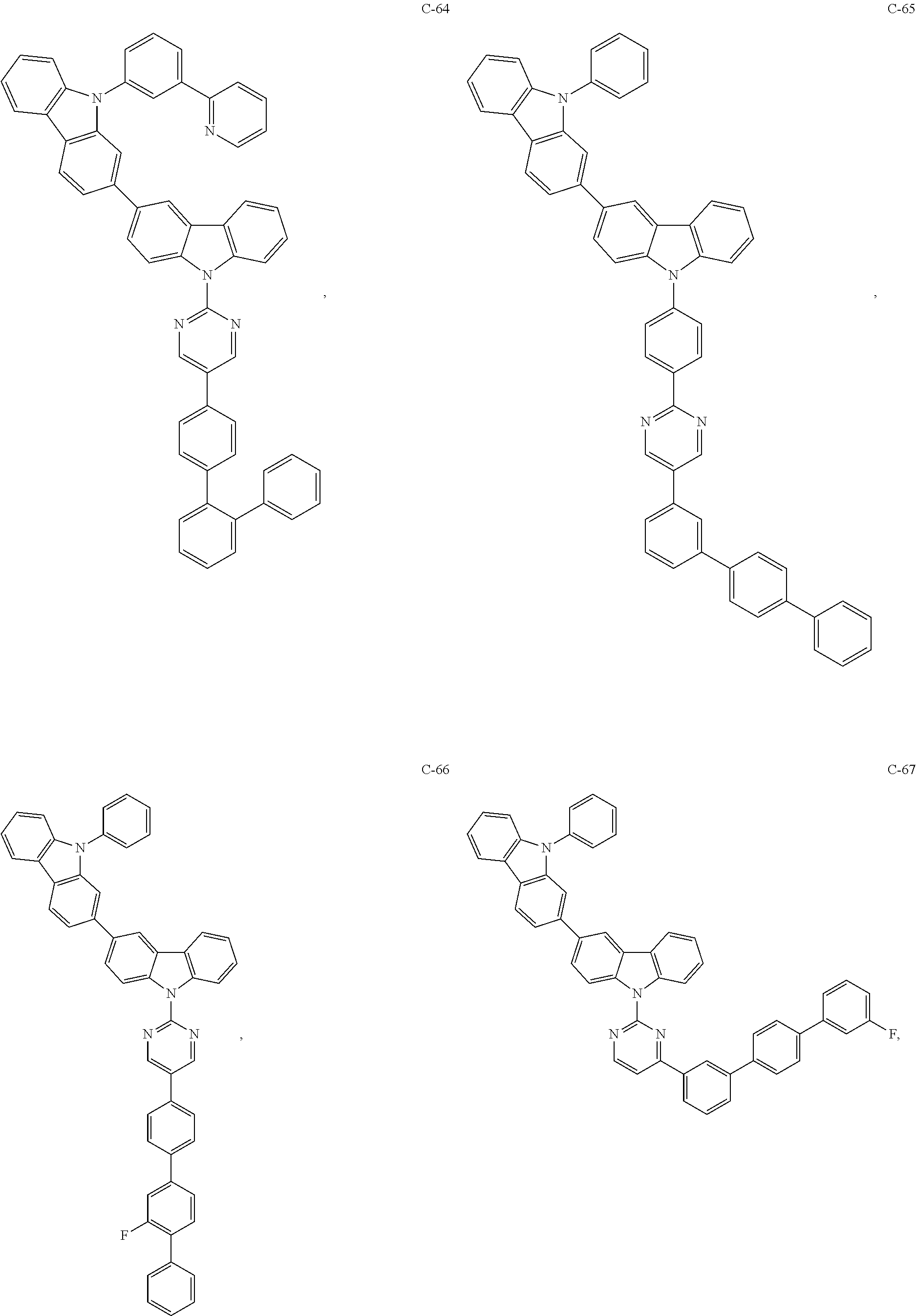 [SMILES: c1ccc(-c2ccccc2-c2ccc(-c3cnc(-n4c5ccccc5c5cc(-c6ccc7c8ccccc8n(-c8cccc(-c9ccccn9)c8)c7c6)ccc54)nc3)cc2)cc1 ; c1ccc(-c2ccc(-c3cccc(-c4cnc(-c5ccc(-n6c7ccccc7c7cc(-c8ccc9c%10ccccc%10n(-c%10ccccc%10)c9c8)ccc76)cc5)nc4)c3)cc2)cc1 ; Fc1cc(-c2ccc(-c3cnc(-n4c5ccccc5c5cc(-c6ccc7c8ccccc8n(-c8ccccc8)c7c6)ccc54)nc3)cc2)ccc1-c1ccccc1 ; Fc1cccc(-c2ccc(-c3cccc(-c4ccnc(-n5c6ccccc6c6cc(-c7ccc8c9ccccc9n(-c9ccccc9)c8c7)ccc65)n4)c3)cc2)c1]

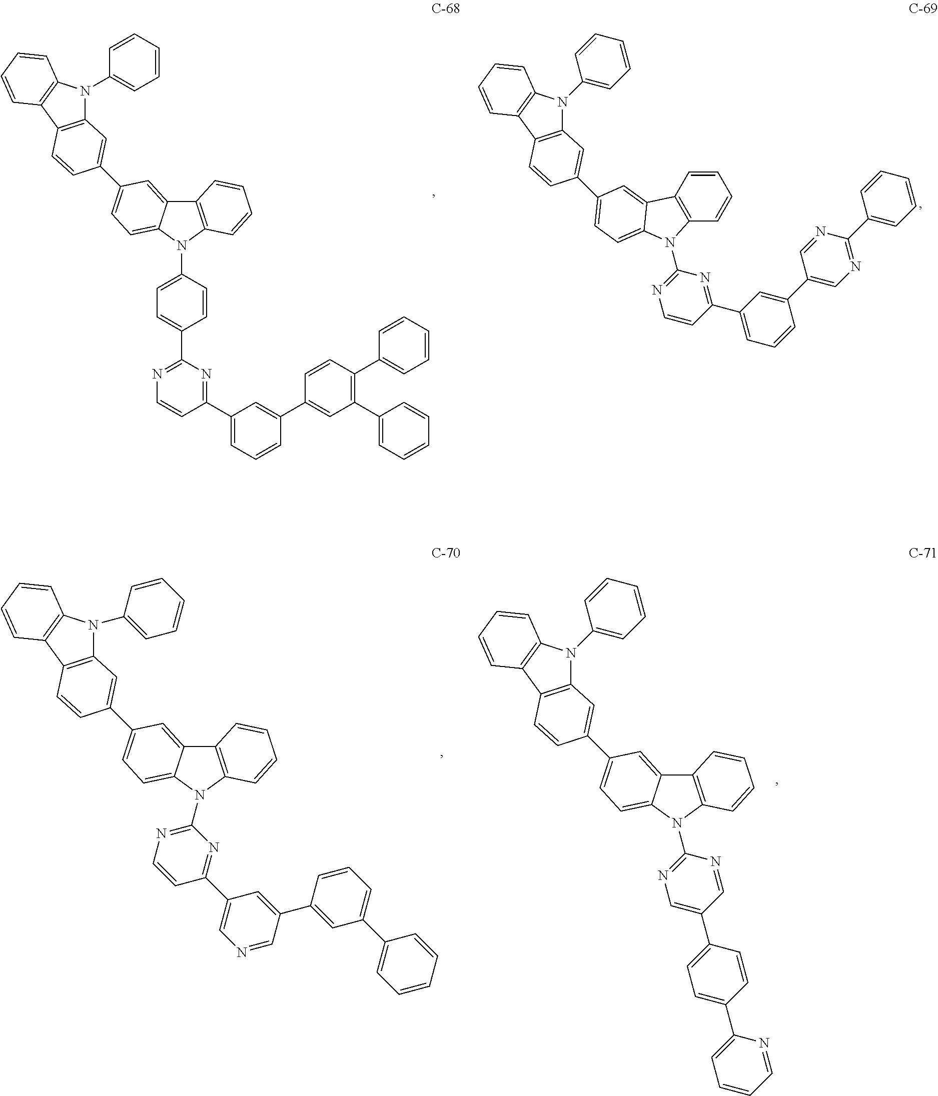 [SMILES: c1ccc(-c2ccc(-c3cccc(-c4ccnc(-c5ccc(-n6c7ccccc7c7cc(-c8ccc9c%10ccccc%10n(-c%10ccccc%10)c9c8)ccc76)cc5)n4)c3)cc2-c2ccccc2)cc1 ; c1ccc(-c2ncc(-c3cccc(-c4ccnc(-n5c6ccccc6c6cc(-c7ccc8c9ccccc9n(-c9ccccc9)c8c7)ccc65)n4)c3)cn2)cc1 ; c1ccc(-c2cccc(-c3cncc(-c4ccnc(-n5c6ccccc6c6cc(-c7ccc8c9ccccc9n(-c9ccccc9)c8c7)ccc65)n4)c3)c2)cc1 ; c1ccc(-n2c3ccccc3c3ccc(-c4ccc5c(c4)c4ccccc4n5-c4ncc(-c5ccc(-c6ccccn6)cc5)cn4)cc32)cc1]

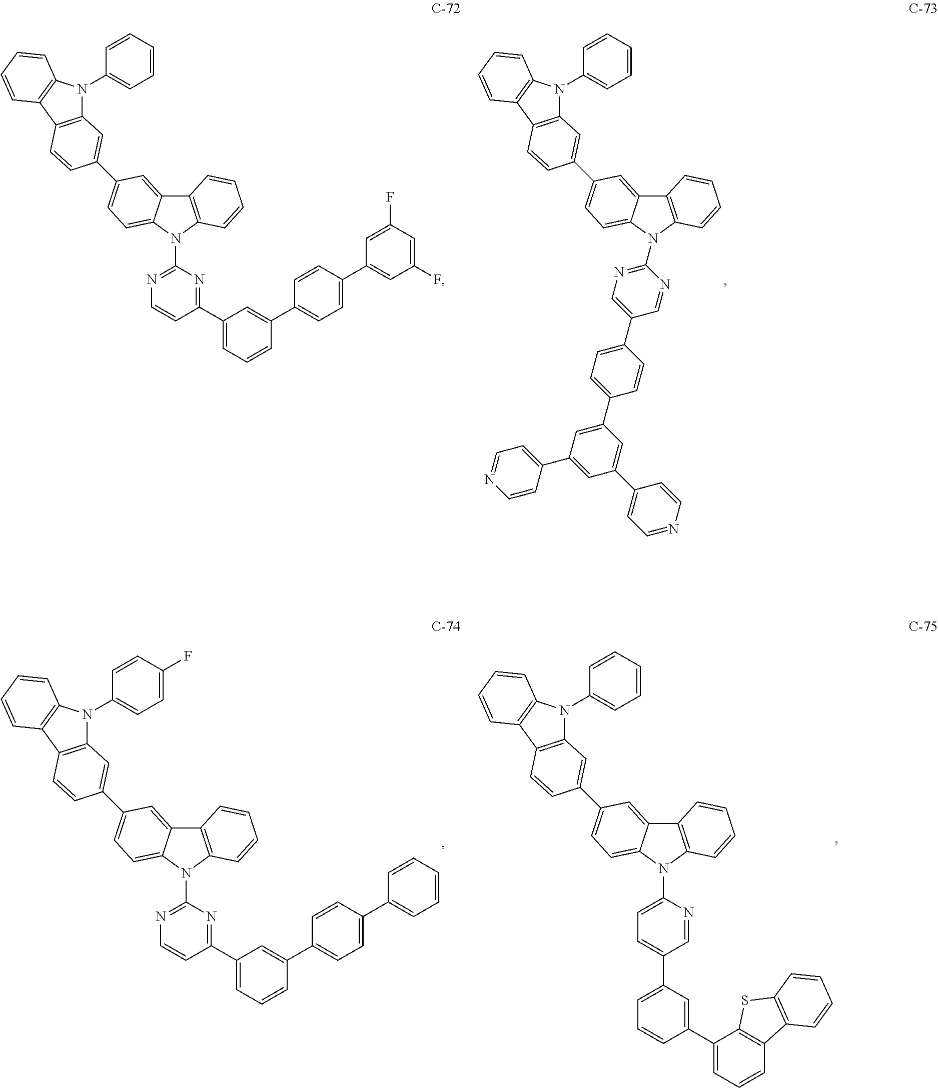 [SMILES: Fc1cc(F)cc(-c2ccc(-c3cccc(-c4ccnc(-n5c6ccccc6c6cc(-c7ccc8c9ccccc9n(-c9ccccc9)c8c7)ccc65)n4)c3)cc2)c1 ; c1ccc(-n2c3ccccc3c3ccc(-c4ccc5c(c4)c4ccccc4n5-c4ncc(-c5ccc(-c6cc(-c7ccncc7)cc(-c7ccncc7)c6)cc5)cn4)cc32)cc1 ; Fc1ccc(-n2c3ccccc3c3ccc(-c4ccc5c(c4)c4ccccc4n5-c4nccc(-c5cccc(-c6ccc(-c7ccccc7)cc6)c5)n4)cc32)cc1 ; c1ccc(-n2c3ccccc3c3ccc(-c4ccc5c(c4)c4ccccc4n5-c4ccc(-c5cccc(-c6cccc7c6sc6ccccc67)c5)cn4)cc32)cc1]

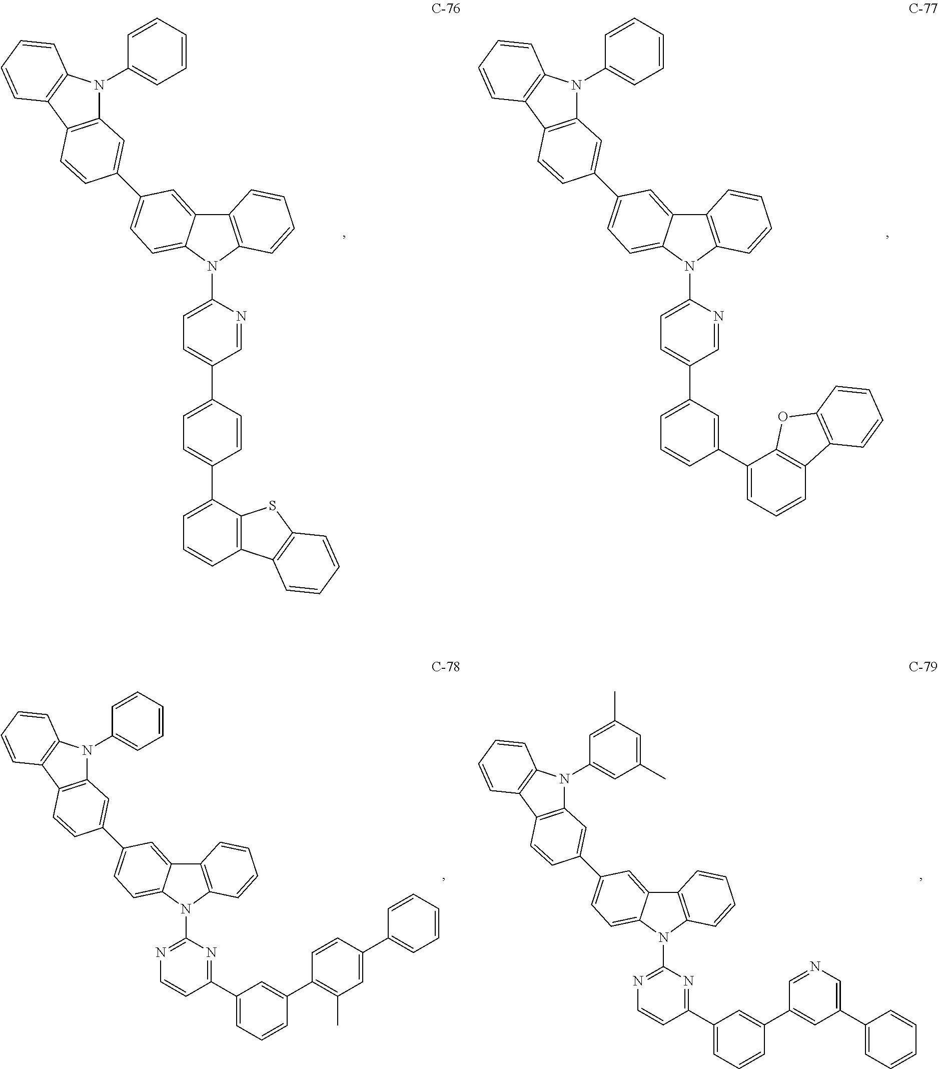 [SMILES: c1ccc(-n2c3ccccc3c3ccc(-c4ccc5c(c4)c4ccccc4n5-c4ccc(-c5ccc(-c6cccc7c6sc6ccccc67)cc5)cn4)cc32)cc1 ; c1ccc(-n2c3ccccc3c3ccc(-c4ccc5c(c4)c4ccccc4n5-c4ccc(-c5cccc(-c6cccc7c6oc6ccccc67)c5)cn4)cc32)cc1 ; Cc1cc(-c2ccccc2)ccc1-c1cccc(-c2ccnc(-n3c4ccccc4c4cc(-c5ccc6c7ccccc7n(-c7ccccc7)c6c5)ccc43)n2)c1 ; Cc1cc(C)cc(-n2c3ccccc3c3ccc(-c4ccc5c(c4)c4ccccc4n5-c4nccc(-c5cccc(-c6cncc(-c7ccccc7)c6)c5)n4)cc32)c1]

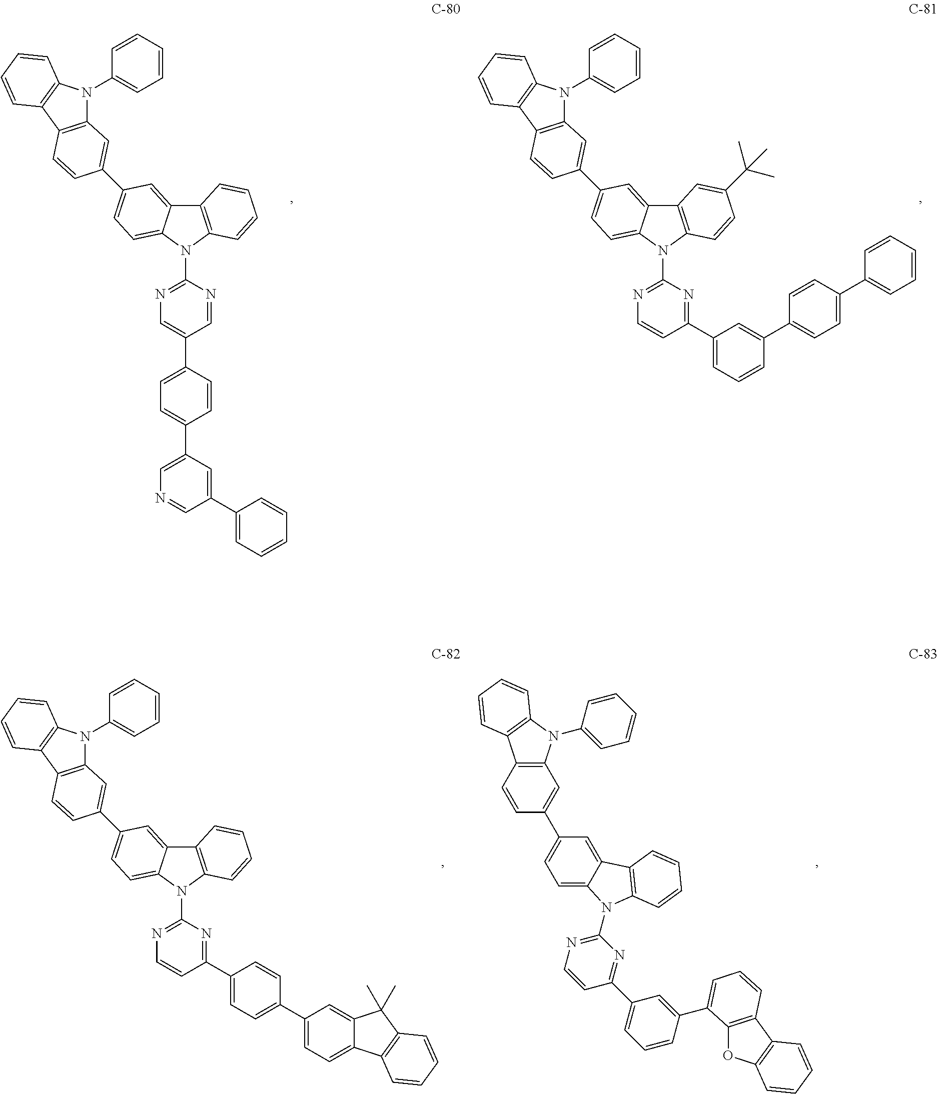 [SMILES: c1ccc(-c2cncc(-c3ccc(-c4cnc(-n5c6ccccc6c6cc(-c7ccc8c9ccccc9n(-c9ccccc9)c8c7)ccc65)nc4)cc3)c2)cc1 ; CC(C)(C)c1ccc2c(c1)c1cc(-c3ccc4c5ccccc5n(-c5ccccc5)c4c3)ccc1n2-c1nccc(-c2cccc(-c3ccc(-c4ccccc4)cc3)c2)n1 ; CC1(C)c2ccccc2-c2ccc(-c3ccc(-c4ccnc(-n5c6ccccc6c6cc(-c7ccc8c9ccccc9n(-c9ccccc9)c8c7)ccc65)n4)cc3)cc21 ; c1ccc(-n2c3ccccc3c3ccc(-c4ccc5c(c4)c4ccccc4n5-c4nccc(-c5cccc(-c6cccc7c6oc6ccccc67)c5)n4)cc32)cc1]

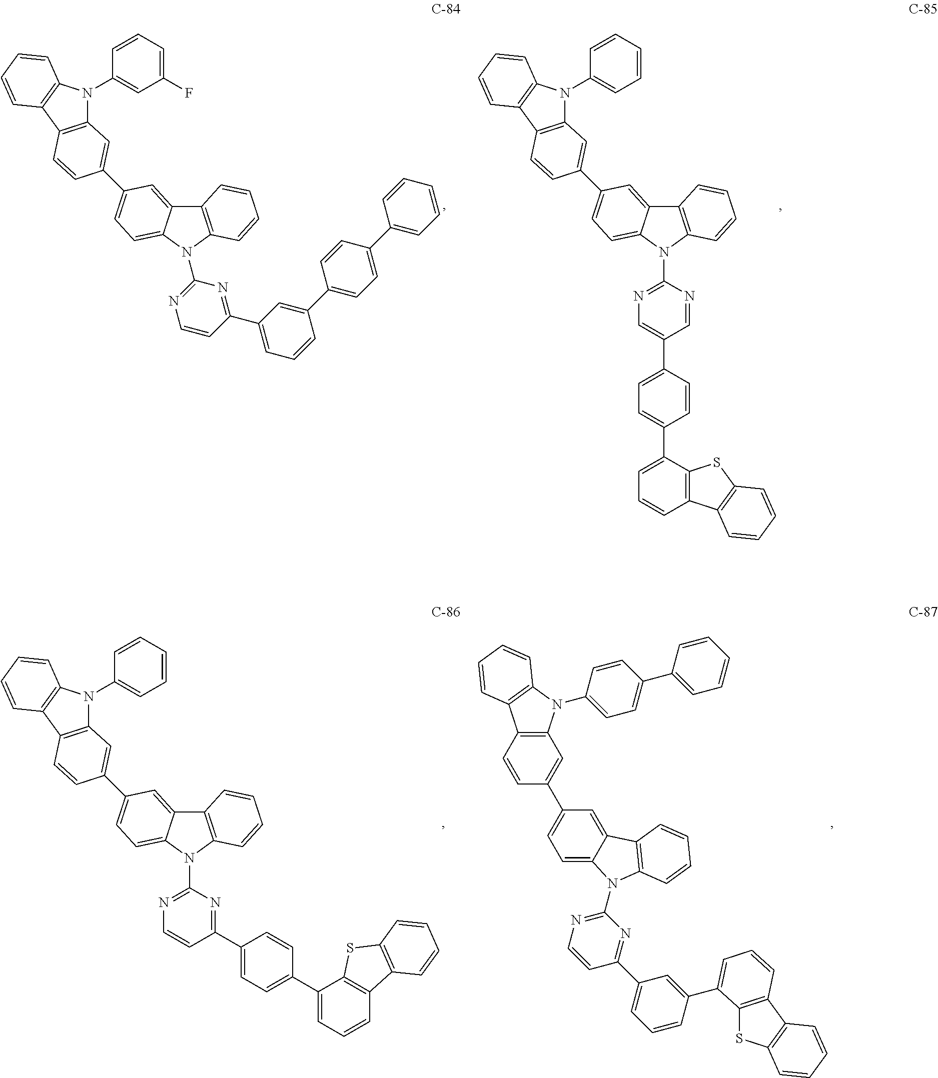 [SMILES: Fc1cccc(-n2c3ccccc3c3ccc(-c4ccc5c(c4)c4ccccc4n5-c4nccc(-c5cccc(-c6ccc(-c7ccccc7)cc6)c5)n4)cc32)c1 ; c1ccc(-n2c3ccccc3c3ccc(-c4ccc5c(c4)c4ccccc4n5-c4ncc(-c5ccc(-c6cccc7c6sc6ccccc67)cc5)cn4)cc32)cc1 ; c1ccc(-n2c3ccccc3c3ccc(-c4ccc5c(c4)c4ccccc4n5-c4nccc(-c5ccc(-c6cccc7c6sc6ccccc67)cc5)n4)cc32)cc1 ; c1ccc(-c2ccc(-n3c4ccccc4c4ccc(-c5ccc6c(c5)c5ccccc5n6-c5nccc(-c6cccc(-c7cccc8c7sc7ccccc78)c6)n5)cc43)cc2)cc1]

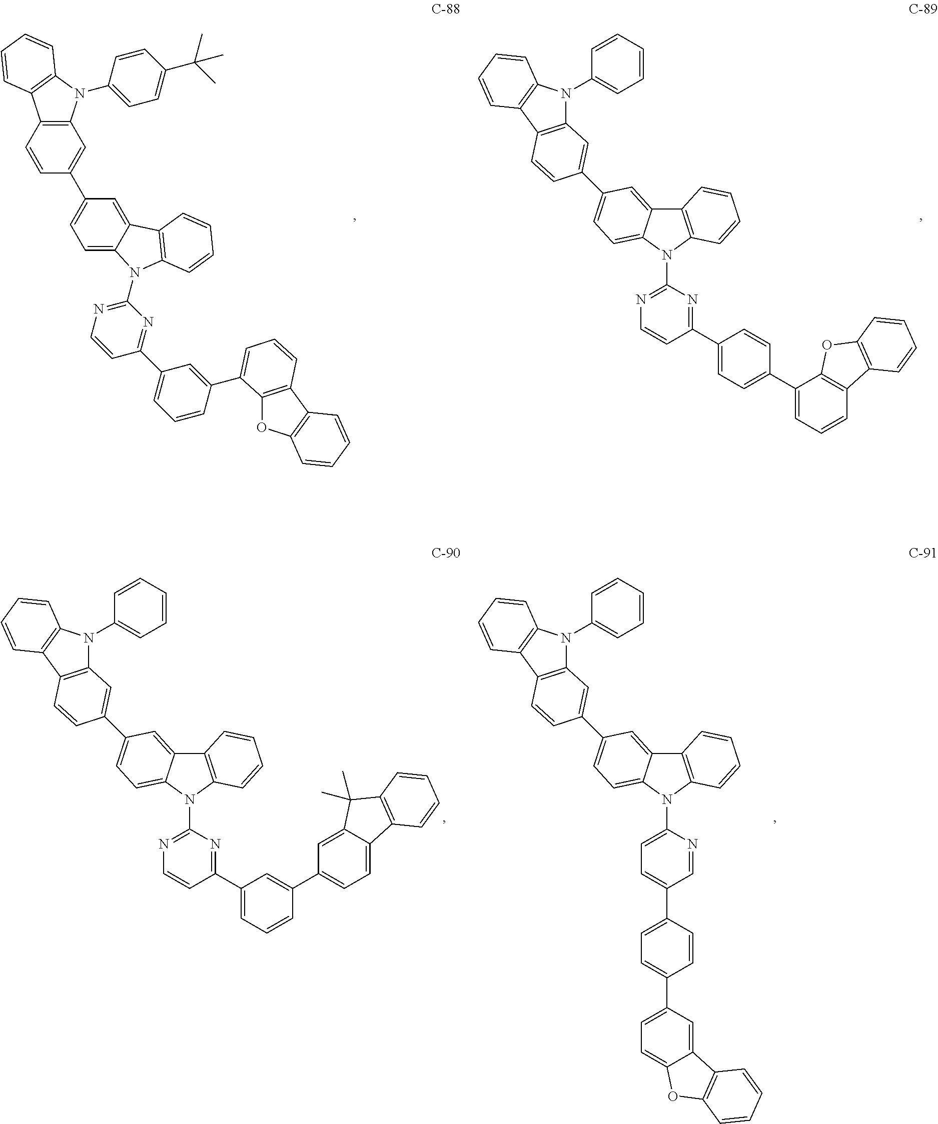 [SMILES: CC(C)(C)c1ccc(-n2c3ccccc3c3ccc(-c4ccc5c(c4)c4ccccc4n5-c4nccc(-c5cccc(-c6cccc7c6oc6ccccc67)c5)n4)cc32)cc1 ; c1ccc(-n2c3ccccc3c3ccc(-c4ccc5c(c4)c4ccccc4n5-c4nccc(-c5ccc(-c6cccc7c6oc6ccccc67)cc5)n4)cc32)cc1 ; CC1(C)c2ccccc2-c2ccc(-c3cccc(-c4ccnc(-n5c6ccccc6c6cc(-c7ccc8c9ccccc9n(-c9ccccc9)c8c7)ccc65)n4)c3)cc21 ; c1ccc(-n2c3ccccc3c3ccc(-c4ccc5c(c4)c4ccccc4n5-c4ccc(-c5ccc(-c6ccc7oc8ccccc8c7c6)cc5)cn4)cc32)cc1]

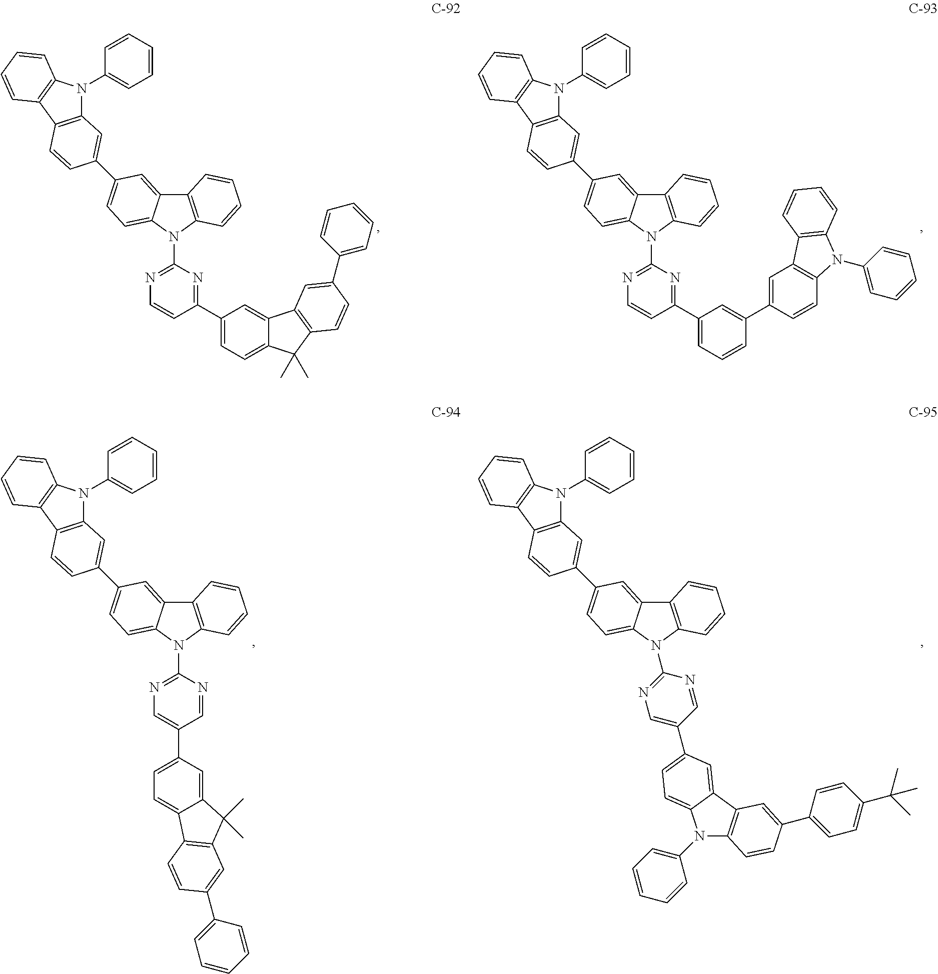 [SMILES: CC1(C)c2ccc(-c3ccccc3)cc2-c2cc(-c3ccnc(-n4c5ccccc5c5cc(-c6ccc7c8ccccc8n(-c8ccccc8)c7c6)ccc54)n3)ccc21 ; c1ccc(-n2c3ccccc3c3cc(-c4cccc(-c5ccnc(-n6c7ccccc7c7cc(-c8ccc9c%10ccccc%10n(-c%10ccccc%10)c9c8)ccc76)n5)c4)ccc32)cc1 ; CC1(C)c2cc(-c3ccccc3)ccc2-c2ccc(-c3cnc(-n4c5ccccc5c5cc(-c6ccc7c8ccccc8n(-c8ccccc8)c7c6)ccc54)nc3)cc21 ; CC(C)(C)c1ccc(-c2ccc3c(c2)c2cc(-c4cnc(-n5c6ccccc6c6cc(-c7ccc8c9ccccc9n(-c9ccccc9)c8c7)ccc65)nc4)ccc2n3-c2ccccc2)cc1]

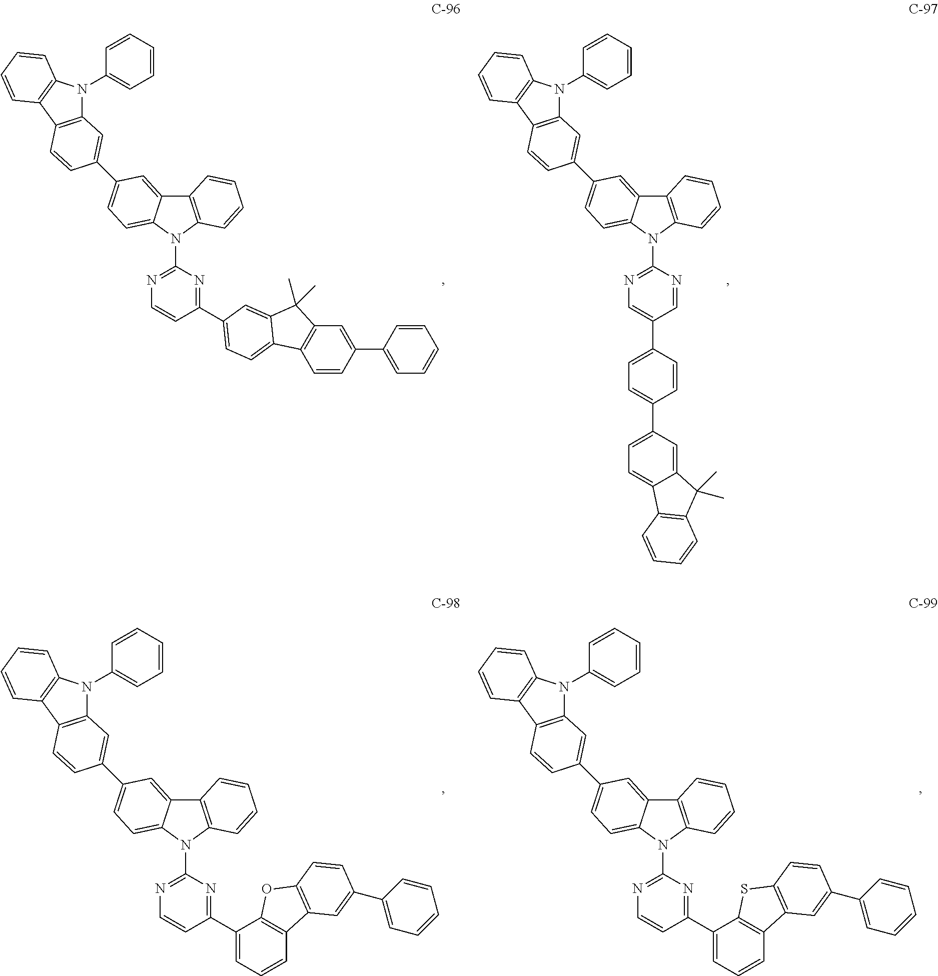 [SMILES: CC1(C)c2cc(-c3ccccc3)ccc2-c2ccc(-c3ccnc(-n4c5ccccc5c5cc(-c6ccc7c8ccccc8n(-c8ccccc8)c7c6)ccc54)n3)cc21 ; CC1(C)c2ccccc2-c2ccc(-c3ccc(-c4cnc(-n5c6ccccc6c6cc(-c7ccc8c9ccccc9n(-c9ccccc9)c8c7)ccc65)nc4)cc3)cc21 ; c1ccc(-c2ccc3oc4c(-c5ccnc(-n6c7ccccc7c7cc(-c8ccc9c%10ccccc%10n(-c%10ccccc%10)c9c8)ccc76)n5)cccc4c3c2)cc1 ; c1ccc(-c2ccc3sc4c(-c5ccnc(-n6c7ccccc7c7cc(-c8ccc9c%10ccccc%10n(-c%10ccccc%10)c9c8)ccc76)n5)cccc4c3c2)cc1]

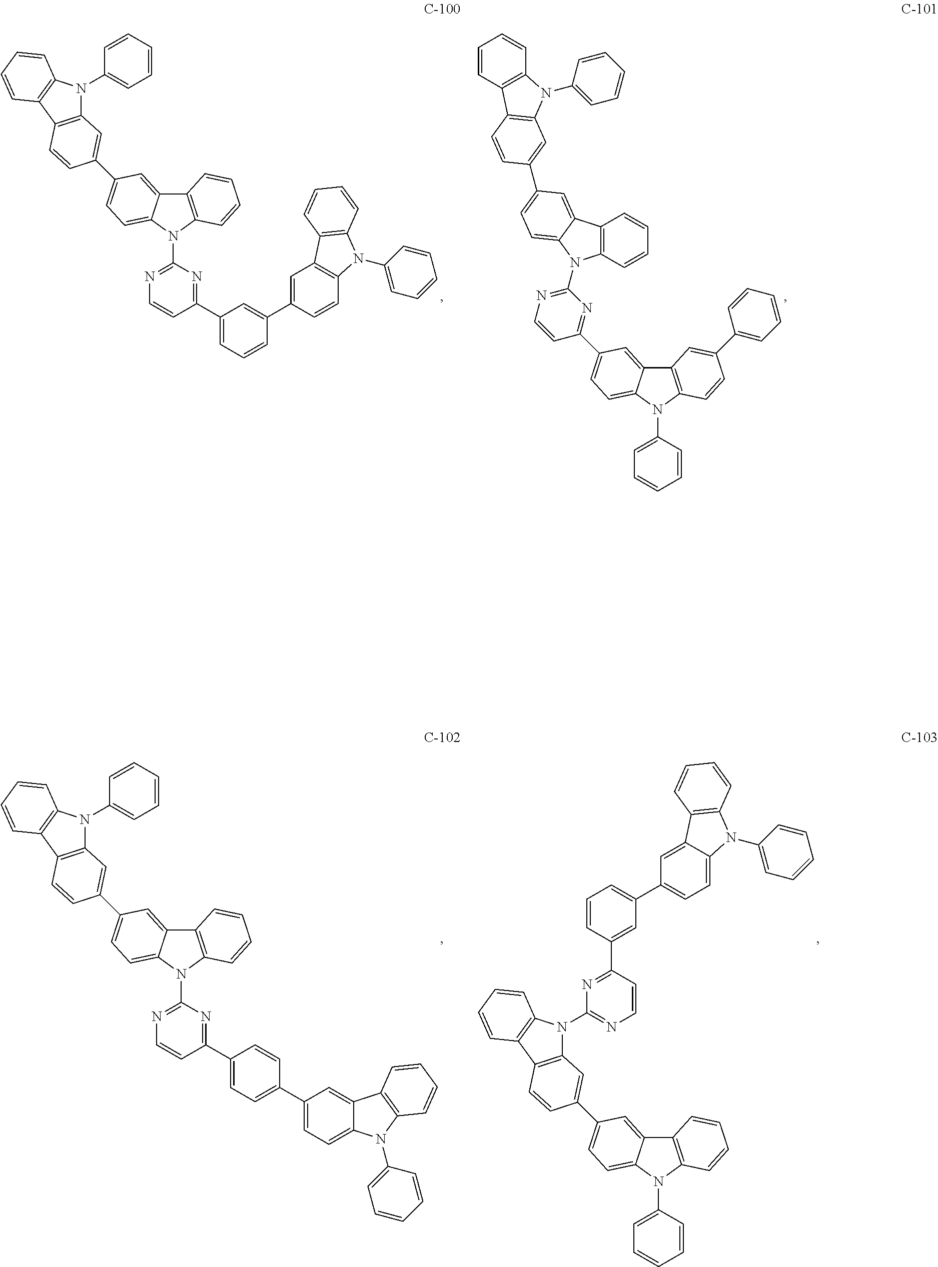 [SMILES: c1ccc(-n2c3ccccc3c3cc(-c4cccc(-c5ccnc(-n6c7ccccc7c7cc(-c8ccc9c%10ccccc%10n(-c%10ccccc%10)c9c8)ccc76)n5)c4)ccc32)cc1 ; c1ccc(-c2ccc3c(c2)c2cc(-c4ccnc(-n5c6ccccc6c6cc(-c7ccc8c9ccccc9n(-c9ccccc9)c8c7)ccc65)n4)ccc2n3-c2ccccc2)cc1 ; c1ccc(-n2c3ccccc3c3cc(-c4ccc(-c5ccnc(-n6c7ccccc7c7cc(-c8ccc9c%10ccccc%10n(-c%10ccccc%10)c9c8)ccc76)n5)cc4)ccc32)cc1 ; c1ccc(-n2c3ccccc3c3cc(-c4cccc(-c5ccnc(-n6c7ccccc7c7ccc(-c8ccc9c(c8)c8ccccc8n9-c8ccccc8)cc76)n5)c4)ccc32)cc1]

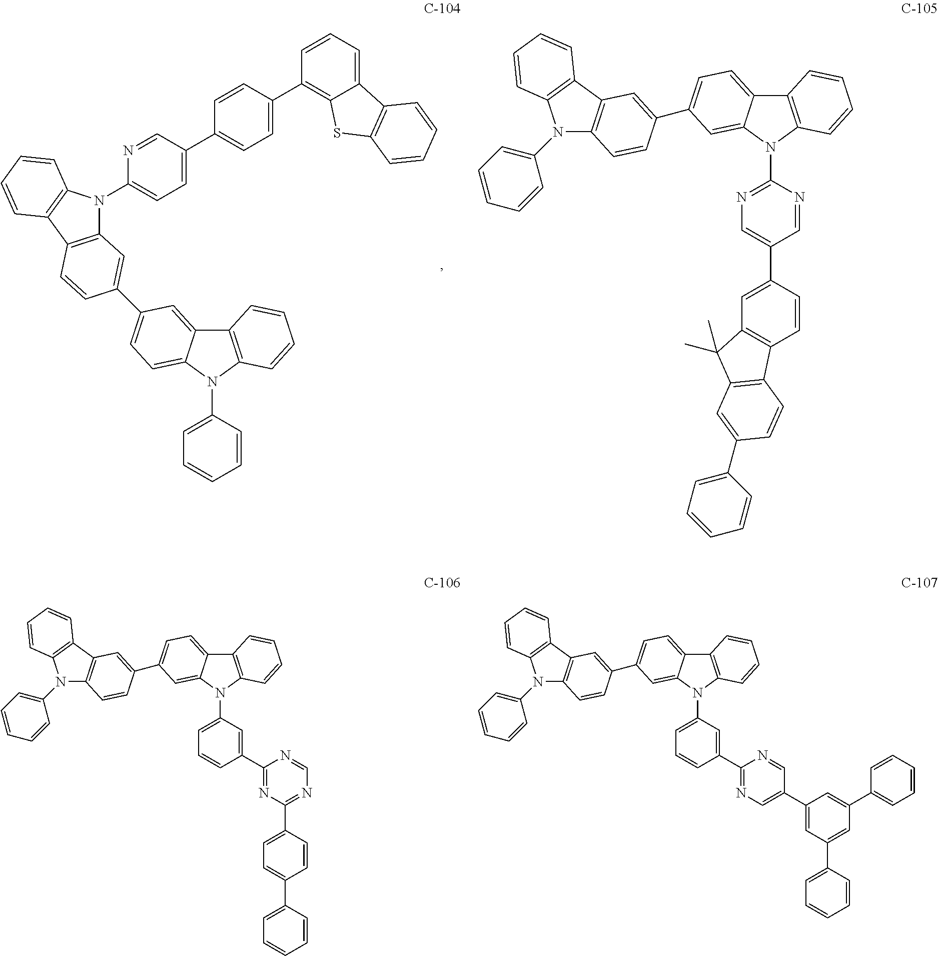 [SMILES: c1ccc(-n2c3ccccc3c3cc(-c4ccc5c6ccccc6n(-c6ccc(-c7ccc(-c8cccc9c8sc8ccccc89)cc7)cn6)c5c4)ccc32)cc1 ; CC1(C)c2cc(-c3ccccc3)ccc2-c2ccc(-c3cnc(-n4c5ccccc5c5ccc(-c6ccc7c(c6)c6ccccc6n7-c6ccccc6)cc54)nc3)cc21 ; c1ccc(-c2ccc(-c3ncnc(-c4cccc(-n5c6ccccc6c6ccc(-c7ccc8c(c7)c7ccccc7n8-c7ccccc7)cc65)c4)n3)cc2)cc1 ; c1ccc(-c2cc(-c3ccccc3)cc(-c3cnc(-c4cccc(-n5c6ccccc6c6ccc(-c7ccc8c(c7)c7ccccc7n8-c7ccccc7)cc65)c4)nc3)c2)cc1]

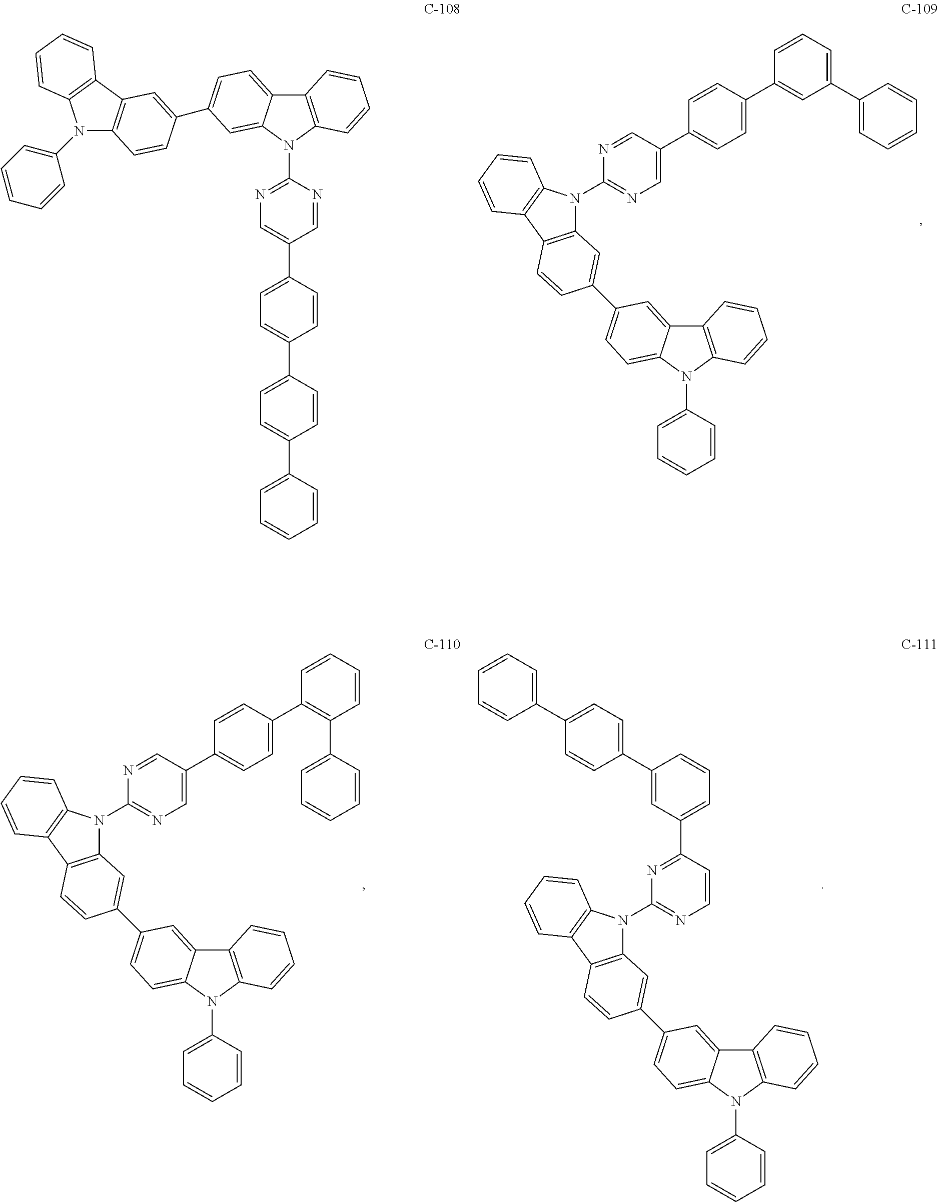 [SMILES: c1ccc(-c2ccc(-c3ccc(-c4cnc(-n5c6ccccc6c6ccc(-c7ccc8c(c7)c7ccccc7n8-c7ccccc7)cc65)nc4)cc3)cc2)cc1 ; c1ccc(-c2cccc(-c3ccc(-c4cnc(-n5c6ccccc6c6ccc(-c7ccc8c(c7)c7ccccc7n8-c7ccccc7)cc65)nc4)cc3)c2)cc1 ; c1ccc(-c2ccccc2-c2ccc(-c3cnc(-n4c5ccccc5c5ccc(-c6ccc7c(c6)c6ccccc6n7-c6ccccc6)cc54)nc3)cc2)cc1 ; c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1]

The organic electroluminescent compounds of the present invention can be prepared according to reactions well-known in the art, for example, the following reaction schemes:

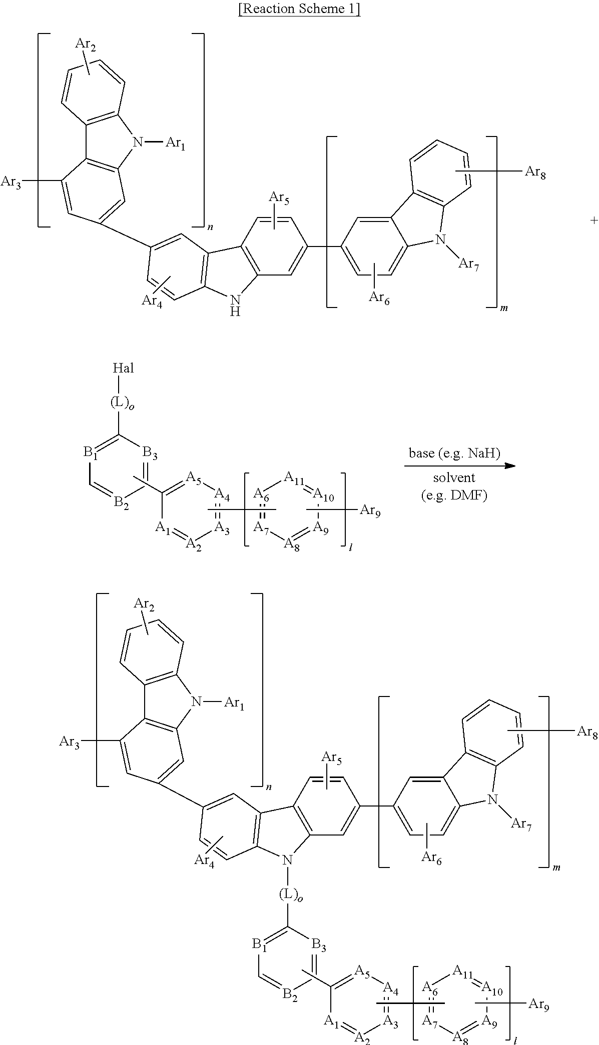

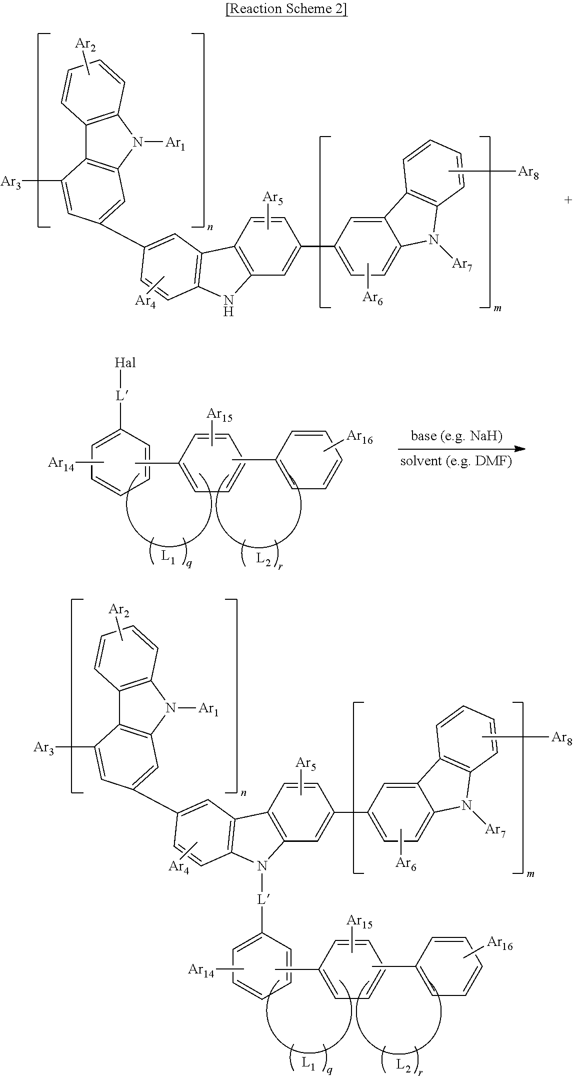

Wherein, in Reaction Schemes 1 and 2, L, L′, L₁, L₂, A₁ to A₁₁, B₁ to B₃, Ar₁ to Ar₉, Ar₁₄ to Ar₁₆, o, m, n, l, q and r are as defined in formulas 1 and 2 above, and Hal represents a halogen atom.

In addition, the present invention provides an organic electroluminescent material comprising the organic electroluminescent compound of formulas 1 or 2, and an organic electroluminescent device comprising the material.

The above material can be comprised of the organic electroluminescent compound according to the present invention alone, or can further include conventional materials generally contained in organic electroluminescent materials.

Said organic electroluminescent device comprises a first electrode, a second electrode, and at least one organic layer between said first and second electrodes. Said organic layer may comprise at least one organic electroluminescent compound of formulas 1 and 2 according to the present invention.

One of the first and second electrodes is an anode, and the other is a cathode. The organic layer comprises a light-emitting layer, and at least one layer selected from the group consisting of a hole injection layer, a hole transport layer, an electron transport layer, an electron injection layer, an interlayer, a hole blocking layer and an electron blocking layer.

The organic electroluminescent compound of formulas 1 and 2 according to the present invention can be comprised of in the light-emitting layer. Where used in the light-emitting layer, the organic electroluminescent compound of formulas 1 and 2 according to the present invention can be comprised as a host material.

Preferably, the light-emitting layer can further comprise at least one dopant and, if needed, another compound as a second host material in addition to the organic electroluminescent compound of formulas 1 and 2 according to the present invention, wherein the ratio of the organic electroluminescent compound according to the present invention (a first host material) to the second host material can be in the range of 1:99 to 99:1.

The second host material can be from any of the known phosphorescent dopants. Specifically, the phosphorescent dopant selected from the group consisting of the compounds of formulas 3 to 5 below is preferable in view of luminous efficiency.

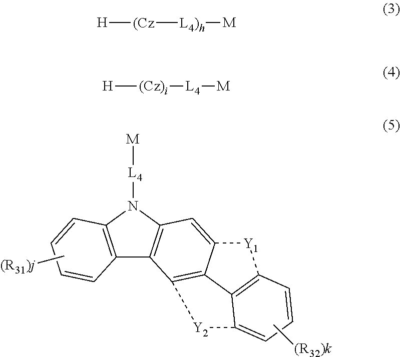

wherein

Cz represents the following structure;

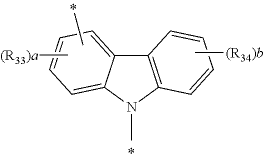

R₃₁ to R₃₄ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, or R₃₅R₃₆R₃₇Si—; R₃₅ to R₃₇ each independently represent a substituted or unsubstituted (C1-C30)alkyl group, or a substituted or unsubstituted (C6-C30)aryl group; L₄ represents a single bond, a substituted or unsubstituted (C6-C30)arylene group, or a substituted or unsubstituted 3- to 30-membered heteroarylene group; M represents a substituted or unsubstituted (C6-C30)aryl group, or a substituted or unsubstituted 3- to 30-membered heteroaryl group; Y₁ and Y₂ represent —O—, —S—, —N(R₄₁)— or —C(R₄₂)(R₄₃)—, provided that Y₁ and Y₂ do not simultaneously exist; R₄₁ to R₄₃ each independently represent a substituted or unsubstituted (C1-C30)alkyl group, a substituted or unsubstituted (C6-C30)aryl group, or a substituted or unsubstituted 3- to 30-membered heteroaryl group, and R₄₂ and R₄₃ are the same or different; h and i each independently represent an integer of 1 to 3; j, k, a and b each independently represent an integer of 0 to 4; and where h, i, j, k, a or b is an integer of 2 or more, each of (Cz-L₄), each of (Cz), each of R₃₁, each of R₃₂, each of R₃₃ or each of R₃₄ is the same or different.

Specifically, preferable examples of the second host material are as follows:

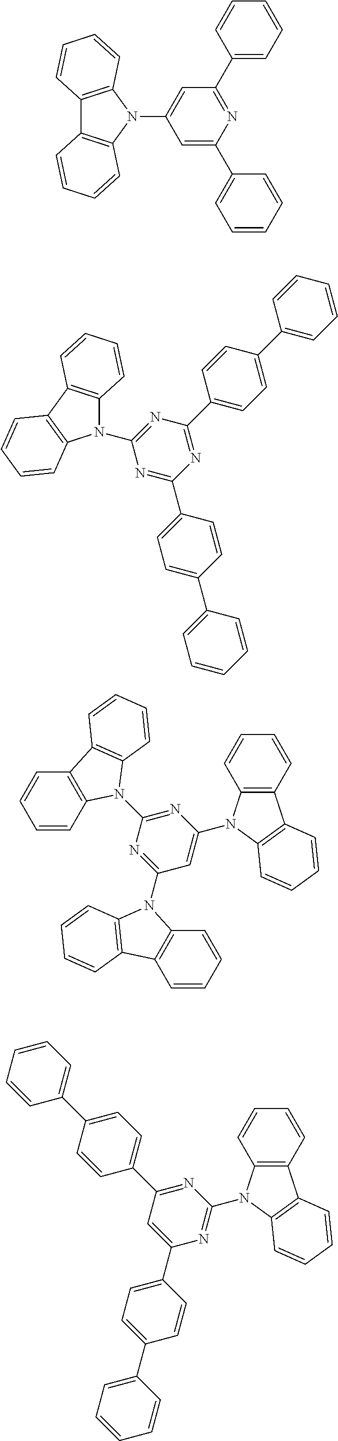 [SMILES: c1ccc(-c2cc(-n3c4ccccc4c4ccccc43)cc(-c3ccccc3)n2)cc1 ; c1ccc(-c2ccc(-c3nc(-c4ccc(-c5ccccc5)cc4)nc(-n4c5ccccc5c5ccccc54)n3)cc2)cc1 ; c1ccc2c(c1)c1ccccc1n2-c1cc(-n2c3ccccc3c3ccccc32)nc(-n2c3ccccc3c3ccccc32)n1 ; c1ccc(-c2ccc(-c3cc(-c4ccc(-c5ccccc5)cc4)nc(-n4c5ccccc5c5ccccc54)n3)cc2)cc1]

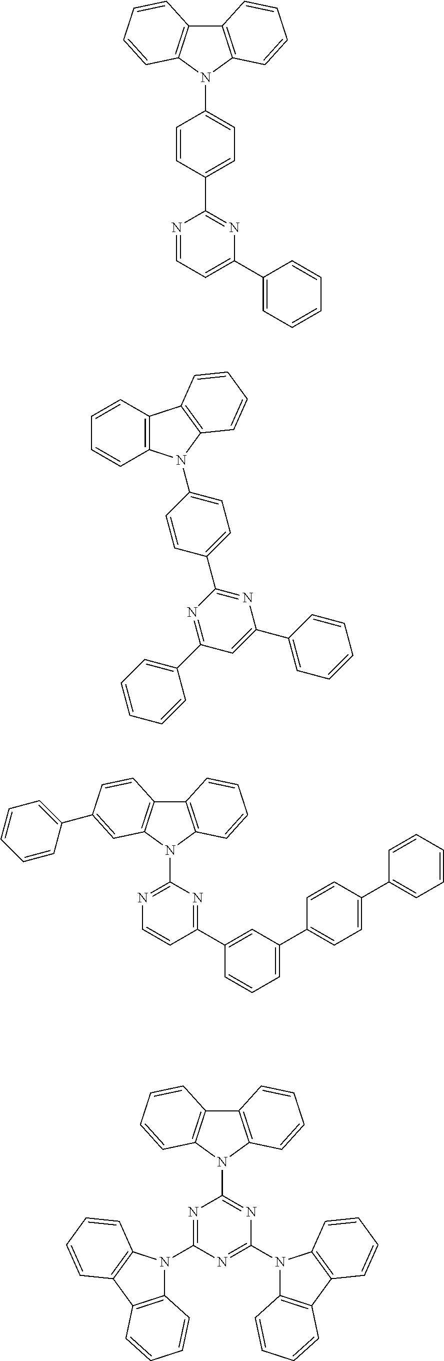 [SMILES: c1ccc(-c2ccnc(-c3ccc(-n4c5ccccc5c5ccccc54)cc3)n2)cc1 ; c1ccc(-c2cc(-c3ccccc3)nc(-c3ccc(-n4c5ccccc5c5ccccc54)cc3)n2)cc1 ; c1ccc(-c2ccc(-c3cccc(-c4ccnc(-n5c6ccccc6c6ccc(-c7ccccc7)cc65)n4)c3)cc2)cc1 ; c1ccc2c(c1)c1ccccc1n2-c1nc(-n2c3ccccc3c3ccccc32)nc(-n2c3ccccc3c3ccccc32)n1]

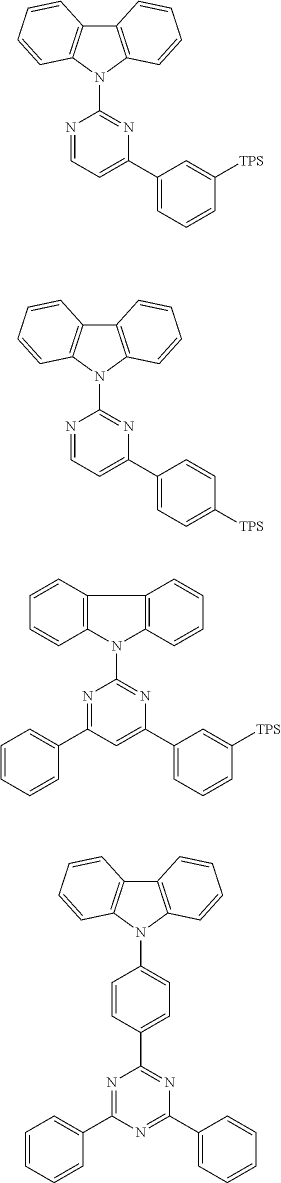

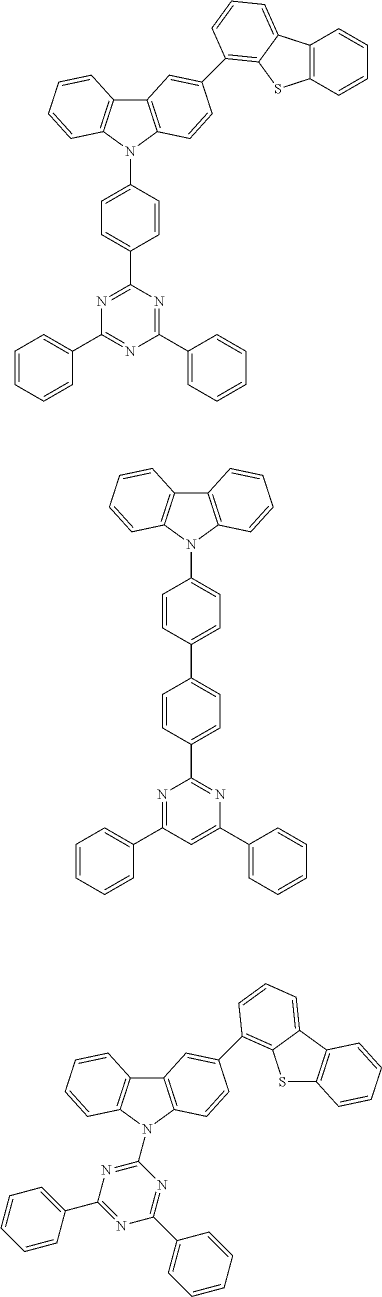 [SMILES: c1ccc(-c2nc(-c3ccccc3)nc(-c3ccc(-n4c5ccccc5c5cc(-c6cccc7c6sc6ccccc67)ccc54)cc3)n2)cc1 ; c1ccc(-c2cc(-c3ccccc3)nc(-c3ccc(-c4ccc(-n5c6ccccc6c6ccccc65)cc4)cc3)n2)cc1 ; c1ccc(-c2nc(-c3ccccc3)nc(-n3c4ccccc4c4cc(-c5cccc6c5sc5ccccc56)ccc43)n2)cc1]

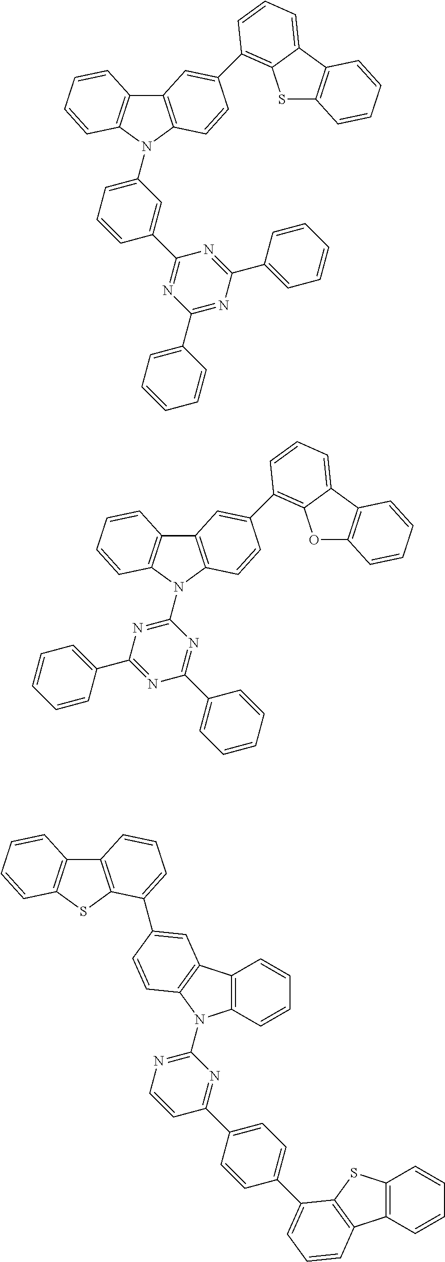 [SMILES: c1ccc(-c2nc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-n3c4ccccc4c4cc(-c5cccc6c5oc5ccccc56)ccc43)n2)cc1 ; c1ccc2c(c1)sc1c(-c3ccc(-c4ccnc(-n5c6ccccc6c6cc(-c7cccc8c7sc7ccccc78)ccc65)n4)cc3)cccc12]

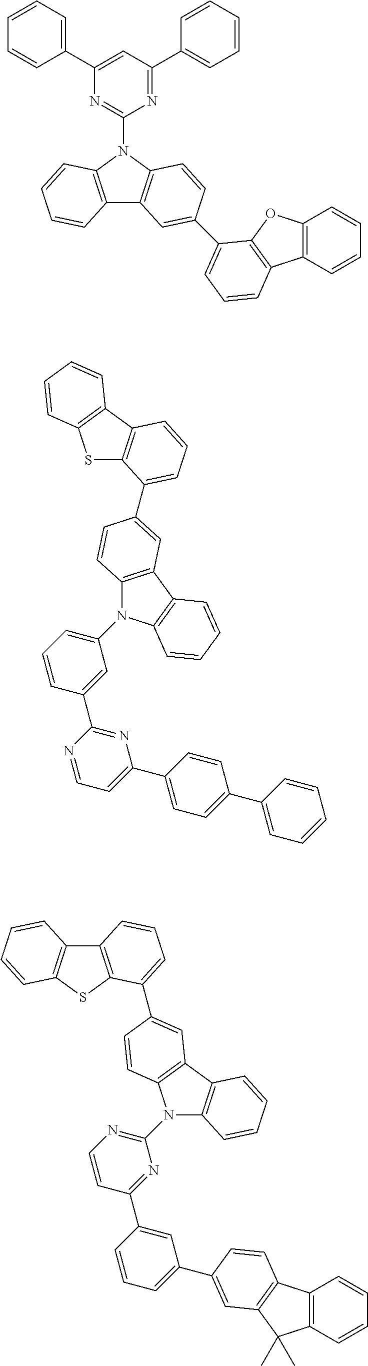 [SMILES: c1ccc(-c2cc(-c3ccccc3)nc(-n3c4ccccc4c4cc(-c5cccc6c5oc5ccccc56)ccc43)n2)cc1 ; c1ccc(-c2ccc(-c3ccnc(-c4cccc(-n5c6ccccc6c6cc(-c7cccc8c7sc7ccccc78)ccc65)c4)n3)cc2)cc1 ; CC1(C)c2ccccc2-c2ccc(-c3cccc(-c4ccnc(-n5c6ccccc6c6cc(-c7cccc8c7sc7ccccc78)ccc65)n4)c3)cc21]

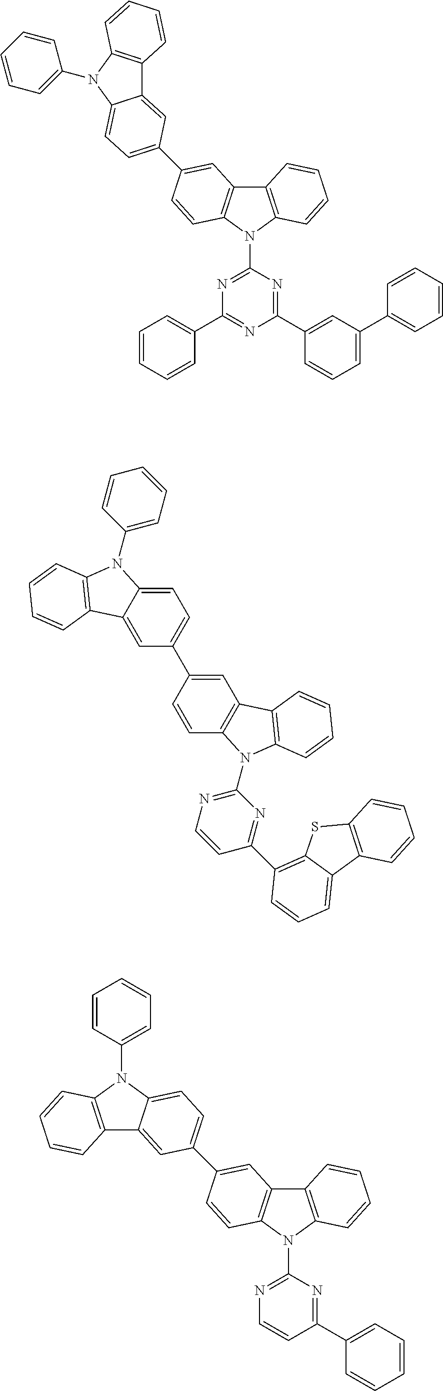 [SMILES: c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-n2c3ccccc3c3cc(-c4ccc5c(c4)c4ccccc4n5-c4nccc(-c5cccc6c5sc5ccccc56)n4)ccc32)cc1 ; c1ccc(-c2ccnc(-n3c4ccccc4c4cc(-c5ccc6c(c5)c5ccccc5n6-c5ccccc5)ccc43)n2)cc1]

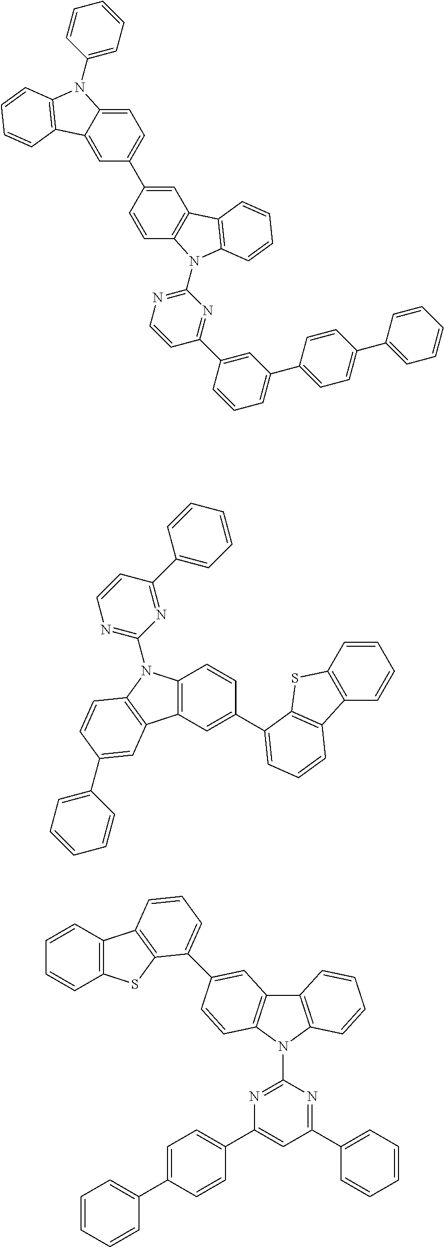 [SMILES: c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-c2ccc3c(c2)c2cc(-c4cccc5c4sc4ccccc45)ccc2n3-c2nccc(-c3ccccc3)n2)cc1 ; c1ccc(-c2ccc(-c3cc(-c4ccccc4)nc(-n4c5ccccc5c5cc(-c6cccc7c6sc6ccccc67)ccc54)n3)cc2)cc1]

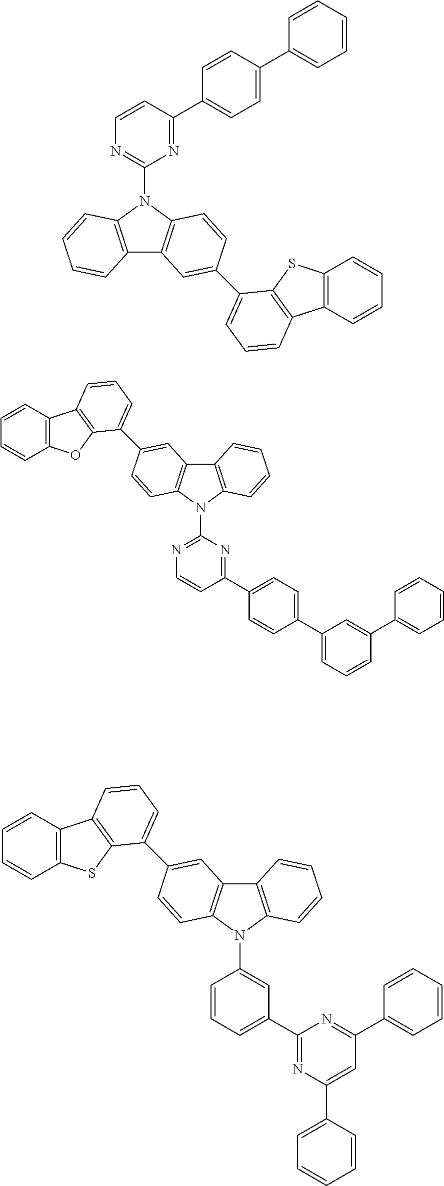 [SMILES: c1ccc(-c2ccc(-c3ccnc(-n4c5ccccc5c5cc(-c6cccc7c6sc6ccccc67)ccc54)n3)cc2)cc1 ; c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1]

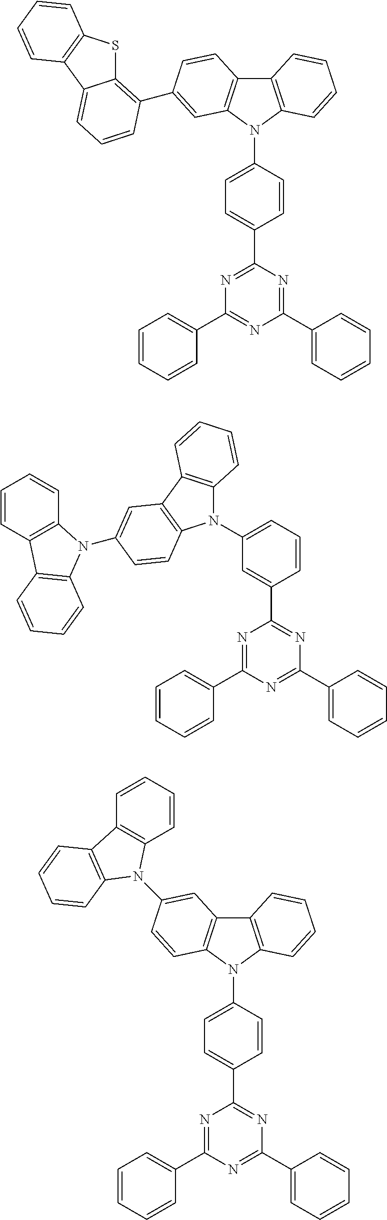 [SMILES: c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

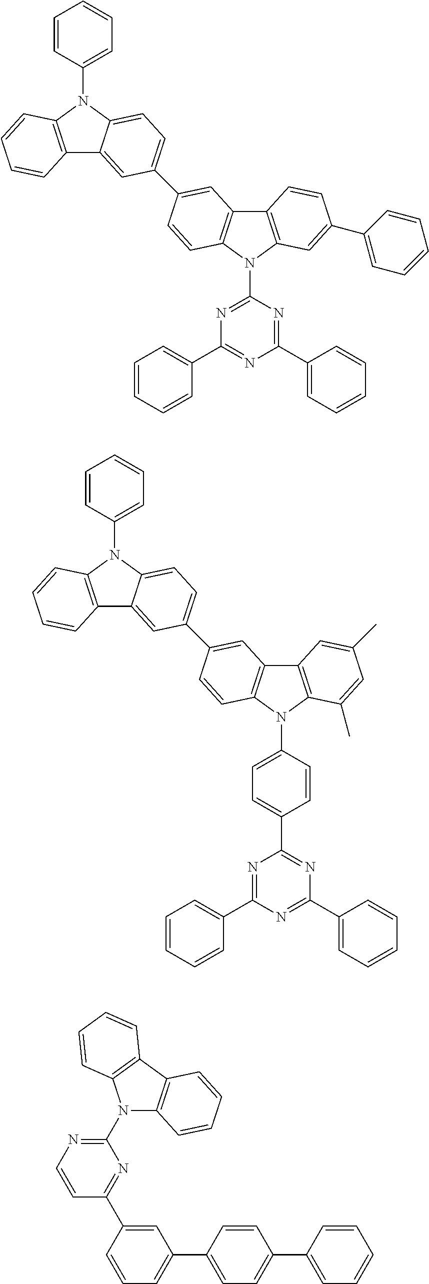 [SMILES: c1ccc(-c2ccc3c4cc(-c5ccc6c(c5)c5ccccc5n6-c5ccccc5)ccc4n(-c4nc(-c5ccccc5)nc(-c5ccccc5)n4)c3c2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2ccc(-c3cccc(-c4ccnc(-n5c6ccccc6c6ccccc65)n4)c3)cc2)cc1]

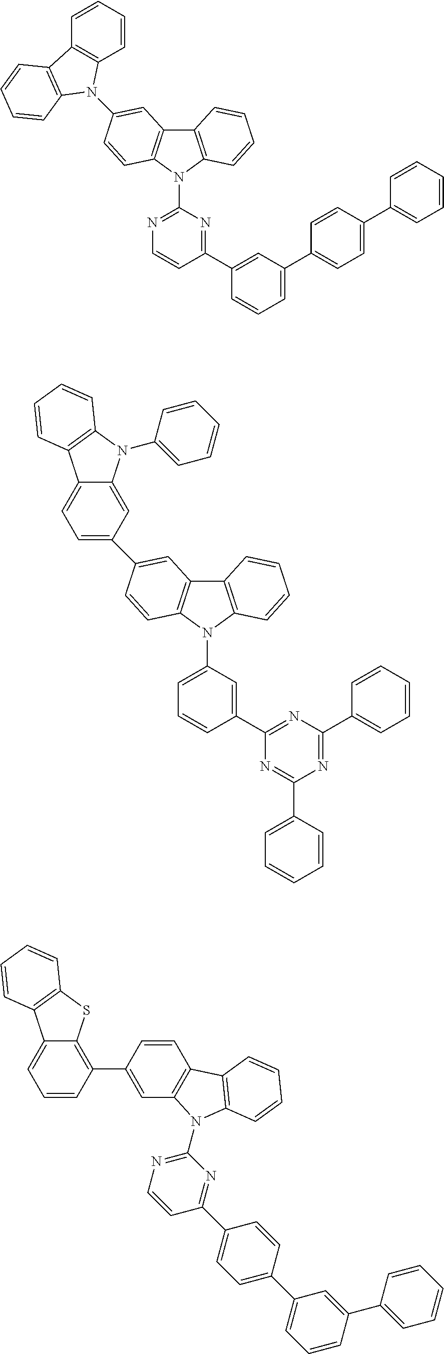 [SMILES: c1ccc(-c2ccc(-c3cccc(-c4ccnc(-n5c6ccccc6c6cc(-n7c8ccccc8c8ccccc87)ccc65)n4)c3)cc2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cccc(-c3ccc(-c4ccnc(-n5c6ccccc6c6ccc(-c7cccc8c7sc7ccccc78)cc65)n4)cc3)c2)cc1]

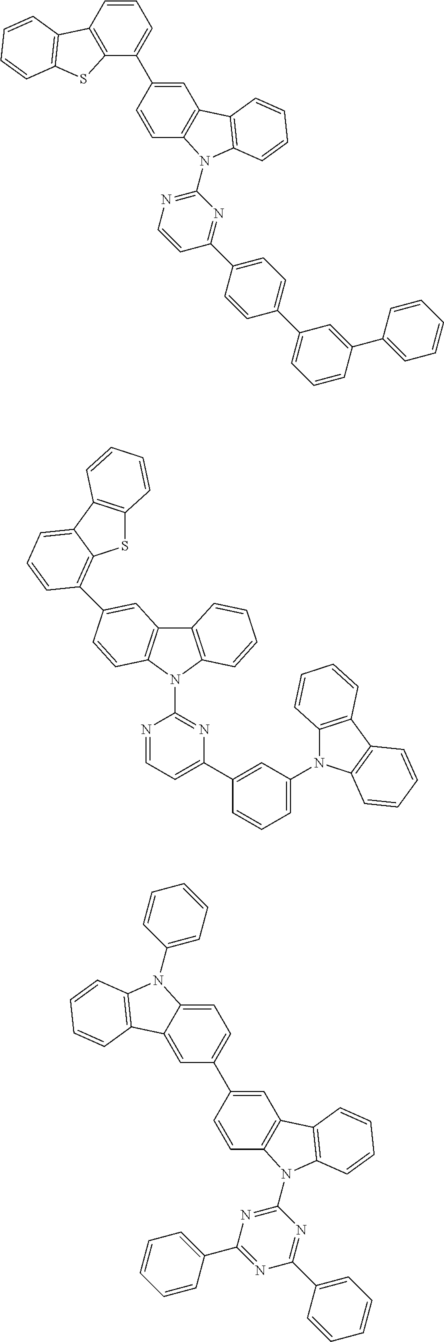 [SMILES: c1ccc(-c2cccc(-c3ccc(-c4ccnc(-n5c6ccccc6c6cc(-c7cccc8c7sc7ccccc78)ccc65)n4)cc3)c2)cc1 ; c1cc(-c2ccnc(-n3c4ccccc4c4cc(-c5cccc6c5sc5ccccc56)ccc43)n2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

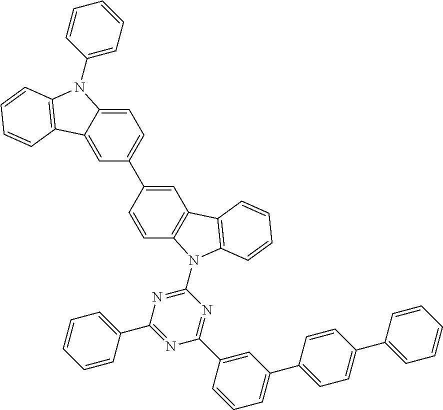 [SMILES: c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1]

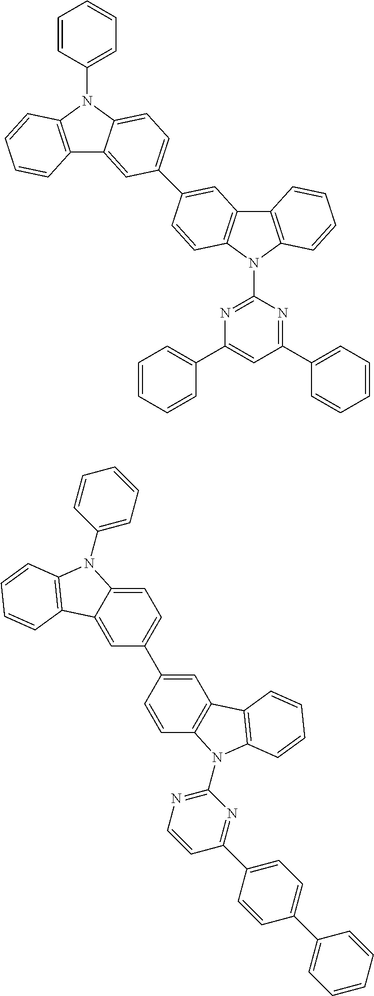 [SMILES: c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2ccc(-c3ccnc(-n4c5ccccc5c5cc(-c6ccc7c(c6)c6ccccc6n7-c6ccccc6)ccc54)n3)cc2)cc1]

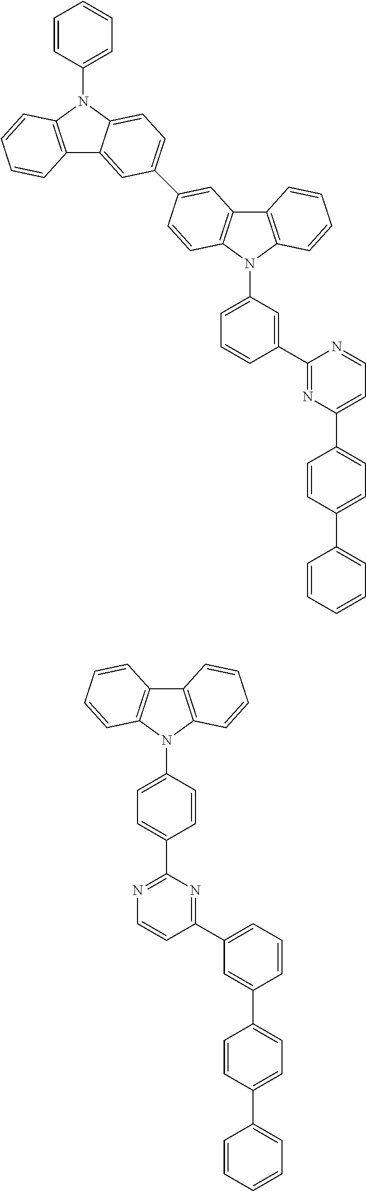 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1]

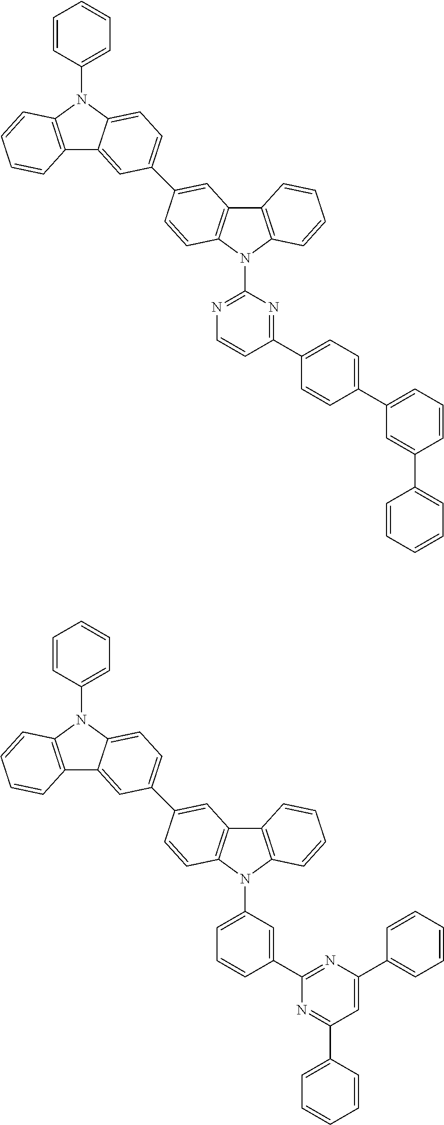 [SMILES: c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1]

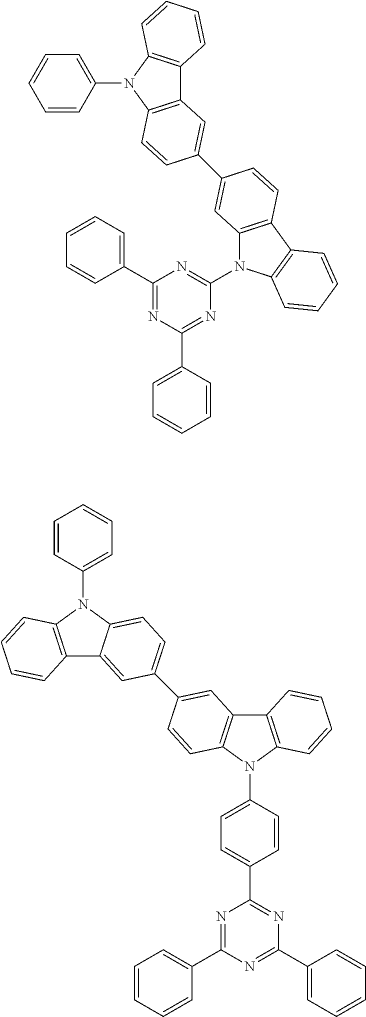 [SMILES: c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

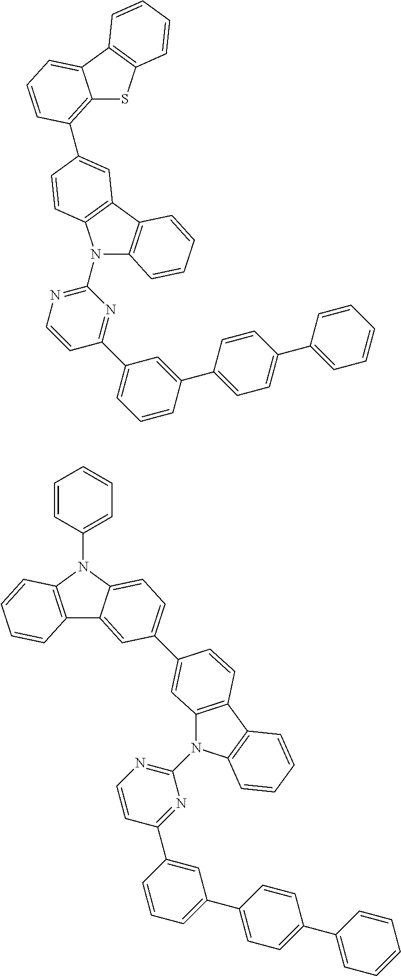 [SMILES: c1ccc(-c2ccc(-c3cccc(-c4ccnc(-n5c6ccccc6c6cc(-c7cccc8c7sc7ccccc78)ccc65)n4)c3)cc2)cc1 ; c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1]

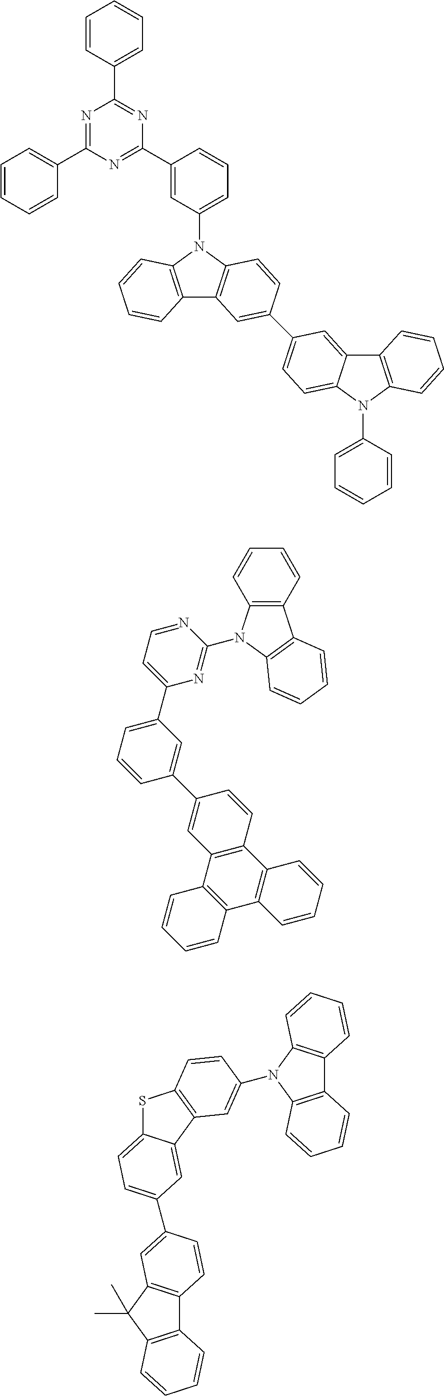 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1cc(-c2ccc3c4ccccc4c4ccccc4c3c2)cc(-c2ccnc(-n3c4ccccc4c4ccccc43)n2)c1 ; CC1(C)c2ccccc2-c2ccc(-c3ccc4sc5ccc(-n6c7ccccc7c7ccccc76)cc5c4c3)cc21]

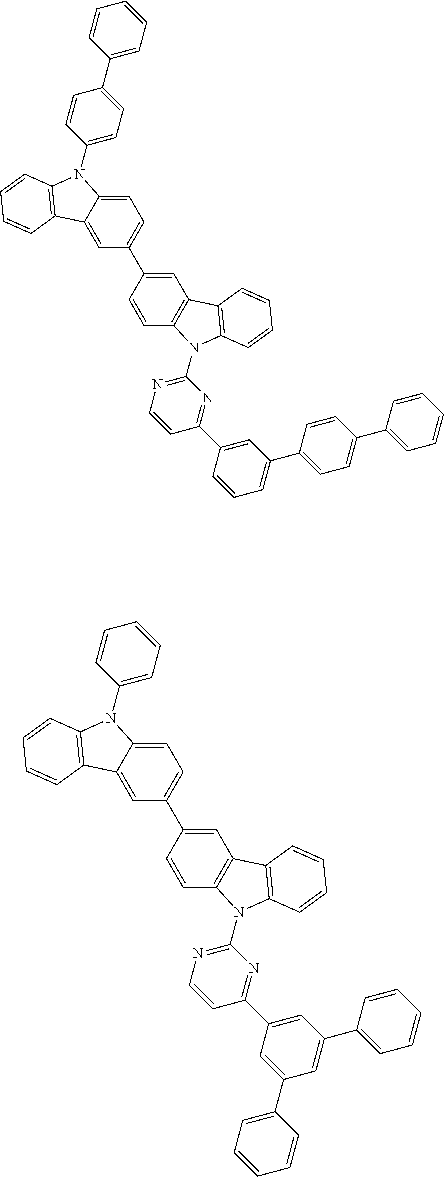 [SMILES: c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

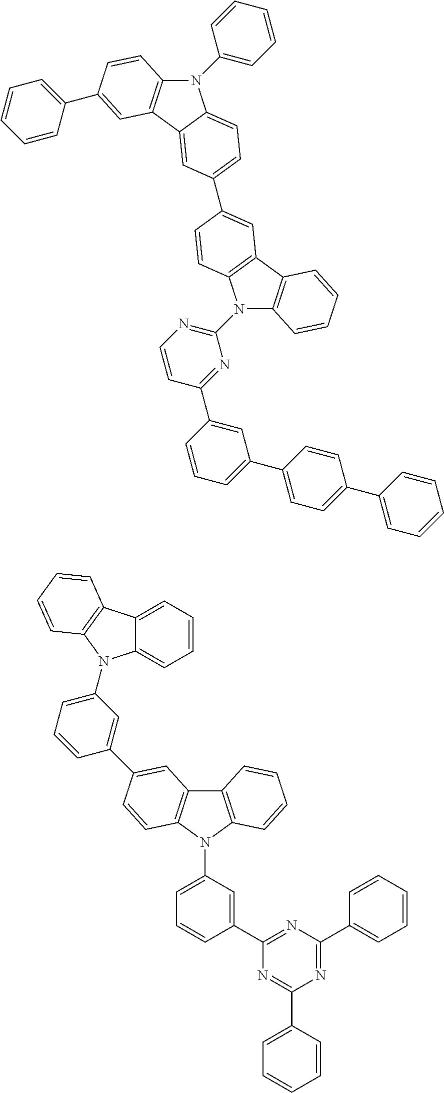 [SMILES: c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1 ; c1ccc(-c2nc(-c3ccccc3)nc(-c3cccc(-n4c5ccccc5c5cc(-c6cccc(-n7c8ccccc8c8ccccc87)c6)ccc54)c3)n2)cc1]

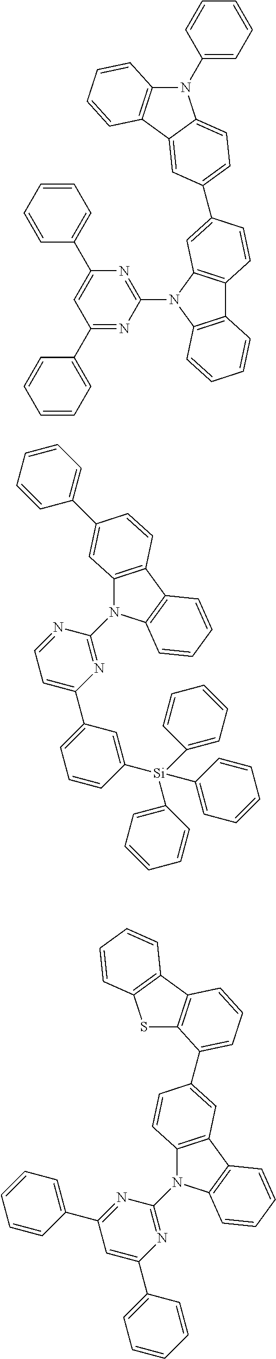

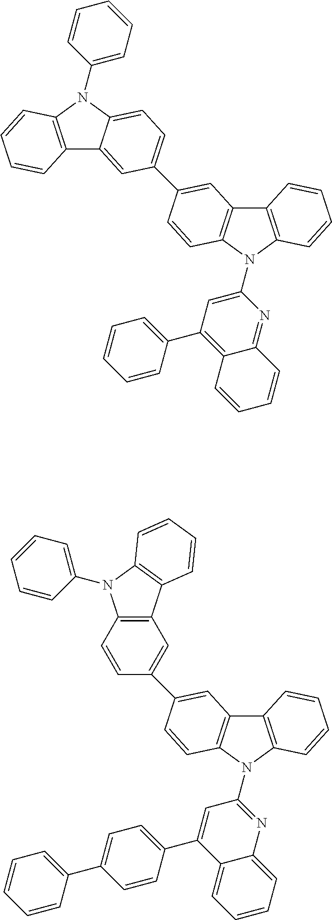 [SMILES: c1ccc(-c2cc(-n3c4ccccc4c4cc(-c5ccc6c(c5)c5ccccc5n6-c5ccccc5)ccc43)nc3ccccc23)cc1 ; c1ccc(-c2ccc(-c3cc(-n4c5ccccc5c5cc(-c6ccc7c(c6)c6ccccc6n7-c6ccccc6)ccc54)nc4ccccc34)cc2)cc1]

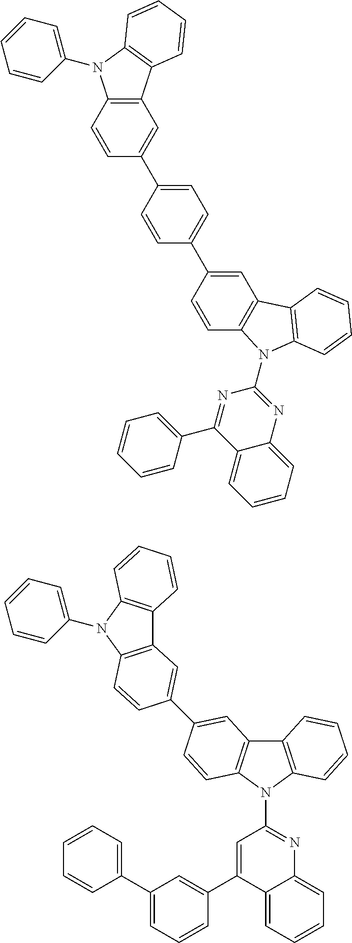

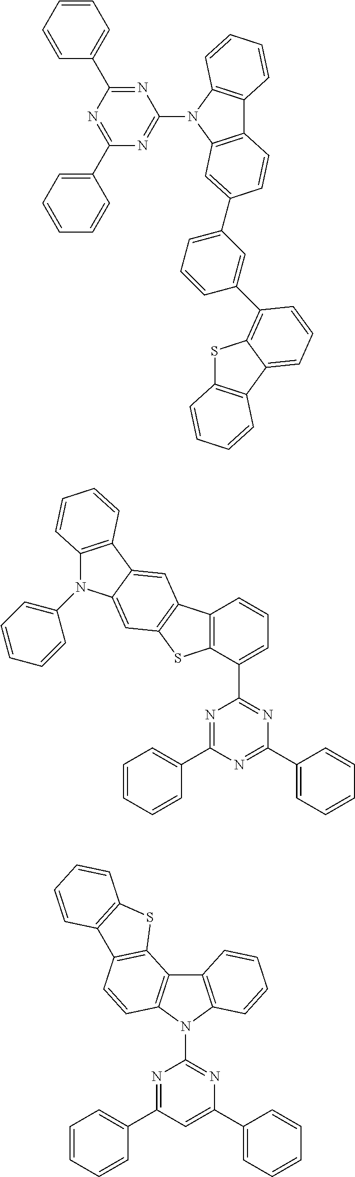 [SMILES: c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3cccc4c3sc3cc5c(cc34)c3ccccc3n5-c3ccccc3)n2)cc1 ; c1ccc(-c2cc(-c3ccccc3)nc(-n3c4ccccc4c4c5sc6ccccc6c5ccc43)n2)cc1]

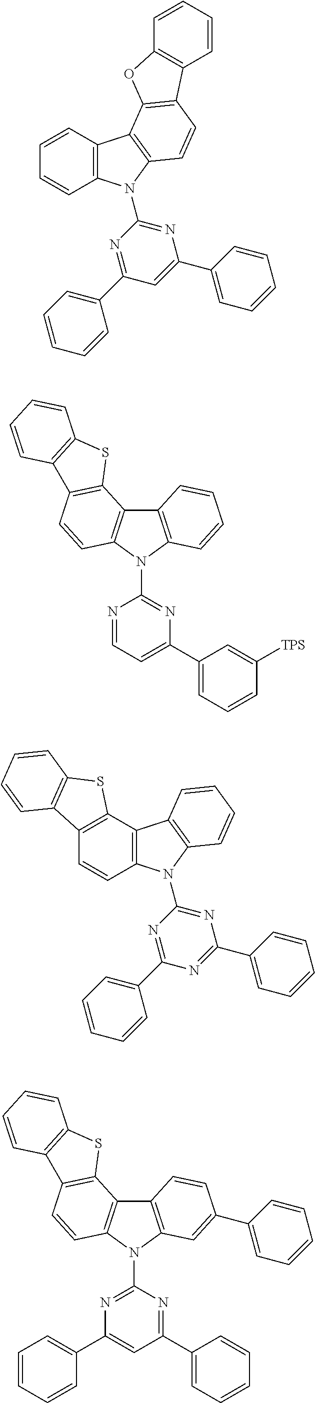

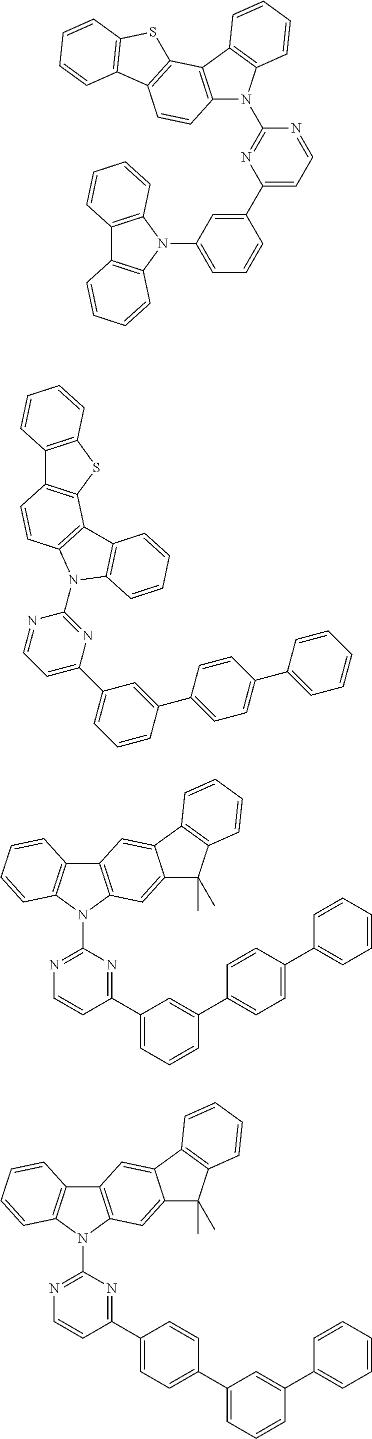 [SMILES: c1cc(-c2ccnc(-n3c4ccccc4c4c5sc6ccccc6c5ccc43)n2)cc(-n2c3ccccc3c3ccccc32)c1 ; c1ccc(-c2ccc(-c3cccc(-c4ccnc(-n5c6ccccc6c6c7sc8ccccc8c7ccc65)n4)c3)cc2)cc1 ; CC1(C)c2ccccc2-c2cc3c4ccccc4n(-c4nccc(-c5cccc(-c6ccc(-c7ccccc7)cc6)c5)n4)c3cc21 ; CC1(C)c2ccccc2-c2cc3c4ccccc4n(-c4nccc(-c5ccc(-c6cccc(-c7ccccc7)c6)cc5)n4)c3cc21]

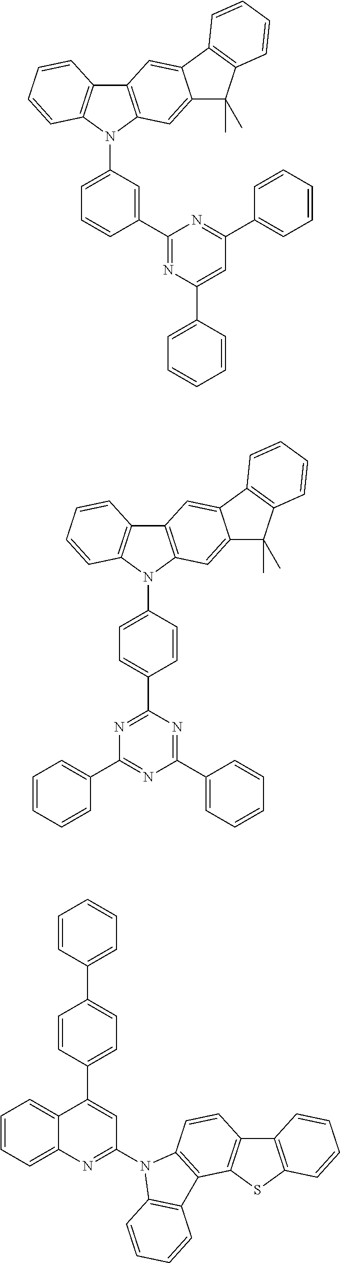 [SMILES: CC1(C)c2ccccc2-c2cc3c4ccccc4n(-c4cccc(-c5nc(-c6ccccc6)cc(-c6ccccc6)n5)c4)c3cc21 ; CC1(C)c2ccccc2-c2cc3c4ccccc4n(-c4ccc(-c5nc(-c6ccccc6)nc(-c6ccccc6)n5)cc4)c3cc21 ; c1ccc(-c2ccc(-c3cc(-n4c5ccccc5c5c6sc7ccccc7c6ccc54)nc4ccccc34)cc2)cc1]

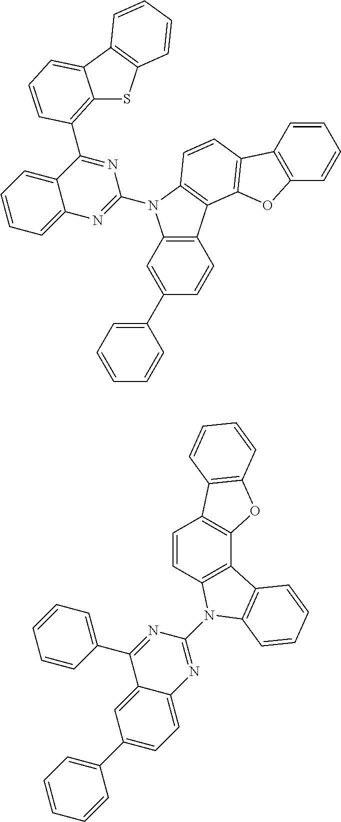 [SMILES: c1ccc(-c2ccc3c4c5oc6ccccc6c5ccc4n(-c4nc(-c5cccc6c5sc5ccccc56)c5ccccc5n4)c3c2)cc1 ; c1ccc(-c2ccc3nc(-n4c5ccccc5c5c6oc7ccccc7c6ccc54)nc(-c4ccccc4)c3c2)cc1]

When the compounds of formulas 1 and 2 are used in the light-emitting layer as phosphorescent host materials, the light-emitting layer can comprise one or more phosphorescent dopants.

Specifically, the light-emitting layer can comprise the phosphorescent dopant material selected from compounds represented by the following formulas 6 to 7.

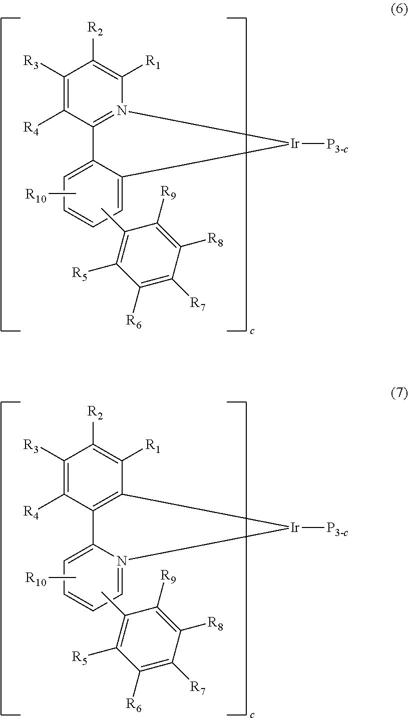

wherein

P is L is an organic ligand;

R₁ to R₁₀ each independently represent hydrogen, deuterium, a halogen; a substituted or unsubstituted (C1-C30)alkyl group, a (C1-C30)alkyl group unsubstituted or substituted with a halogen, a substituted or unsubstituted (C3-C30)cycloalkyl group, a substituted or unsubstituted (C1-C30)alkoxy group, a substituted or unsubstituted (C6-C30)aryl group, or a substituted or unsubstituted 3- to 30-membered heteroaryl group;

c is an integer of 1 to 3.

The phosphorescent dopant applied to an organic electroluminescent device according to one embodiment of the present invention is not limited especially. However, phosphorescent dopants selected from the group consisting of the following compounds are preferable:

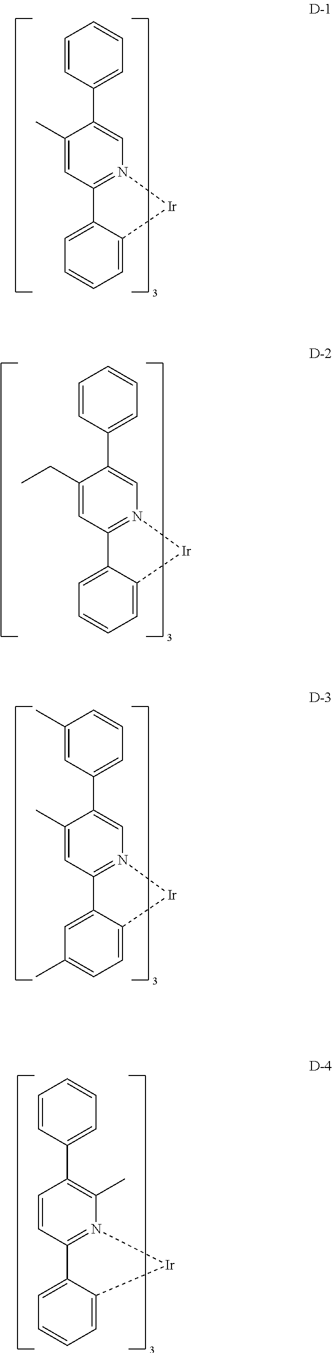

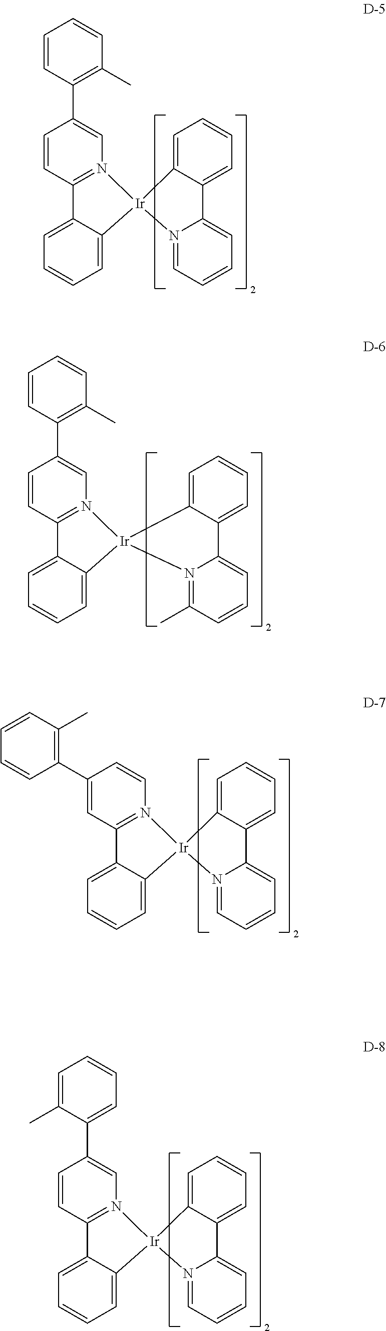

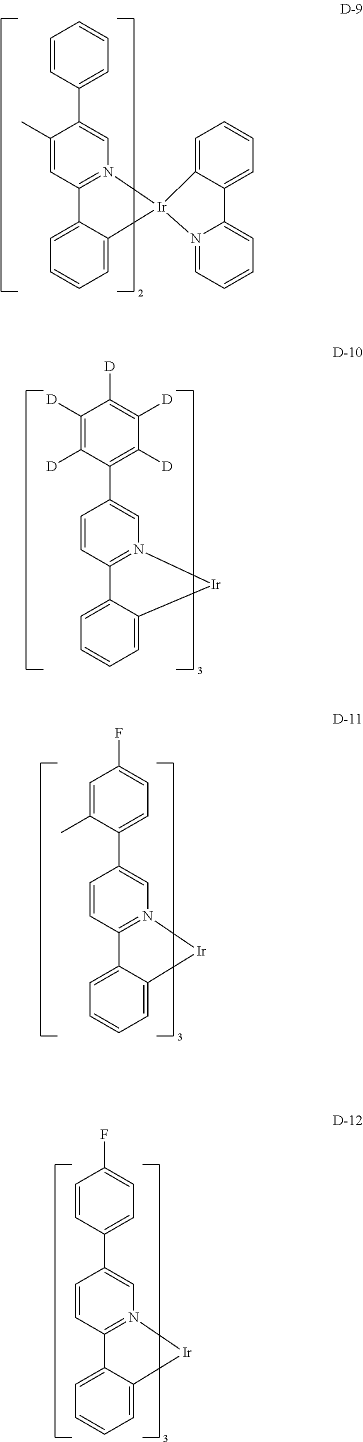

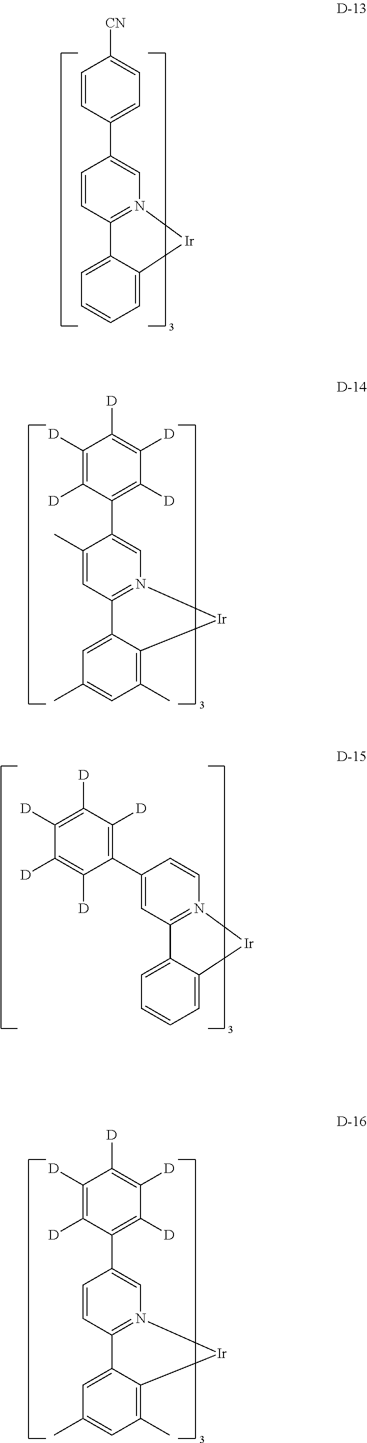

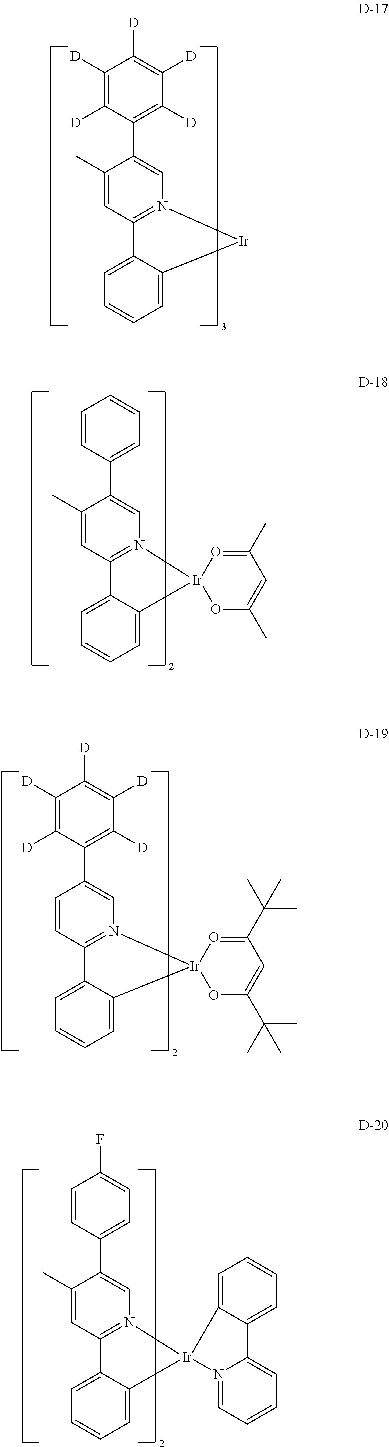

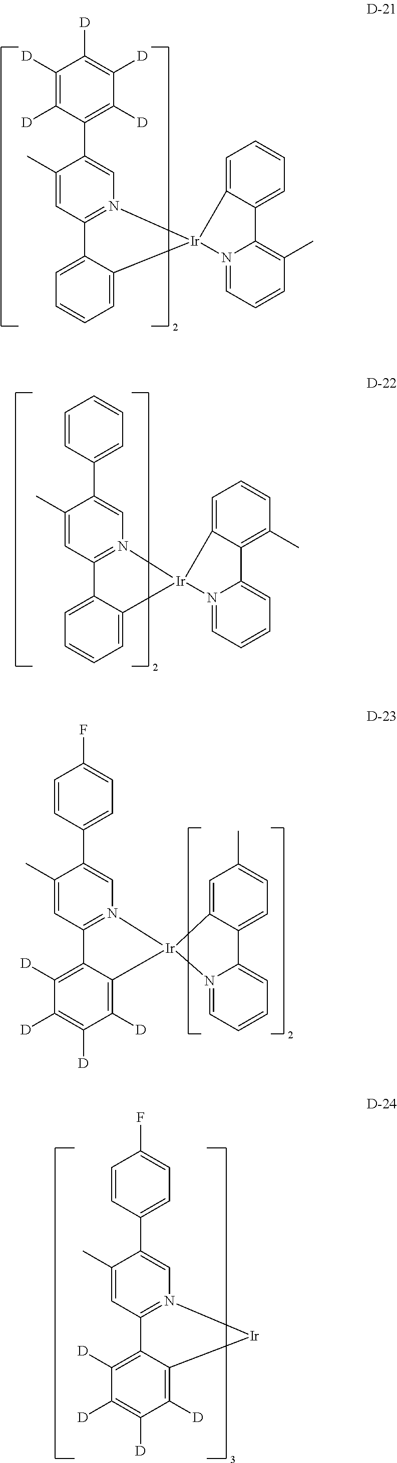

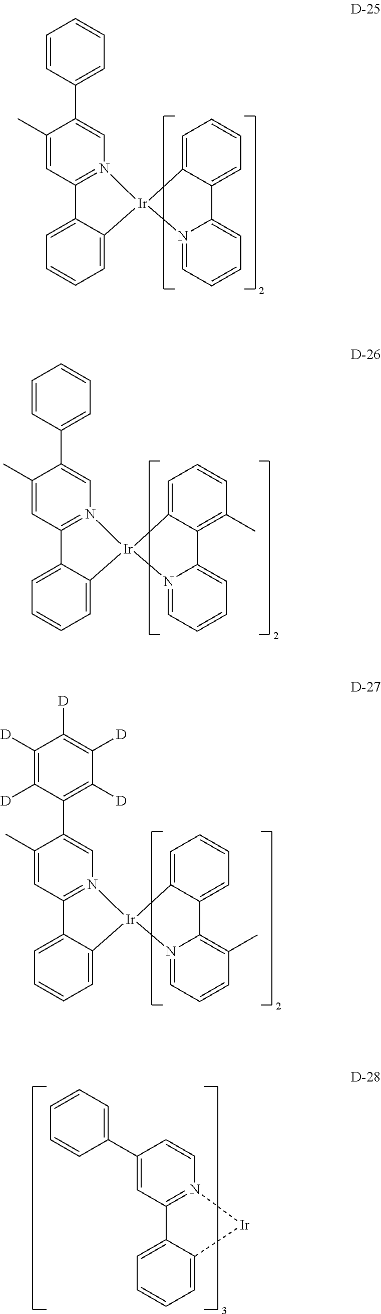

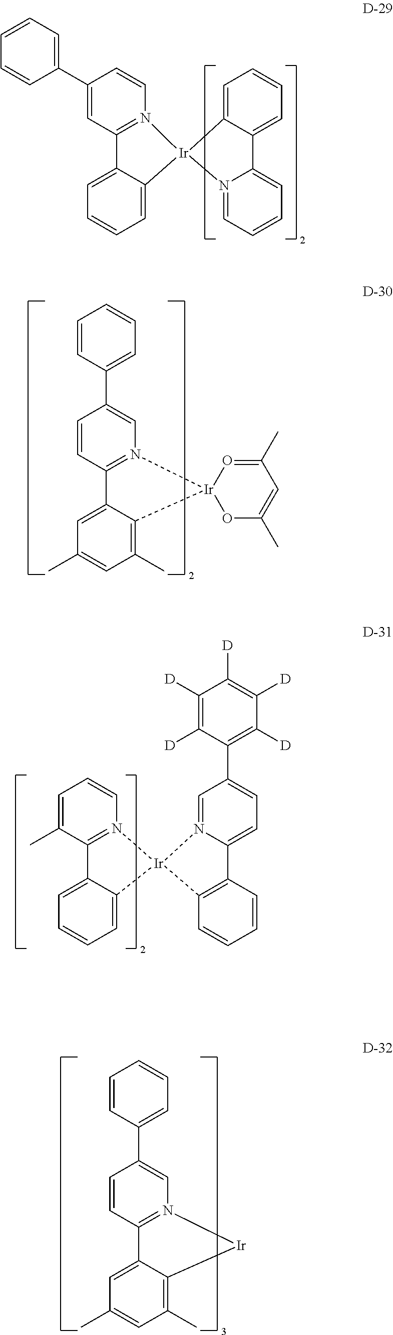

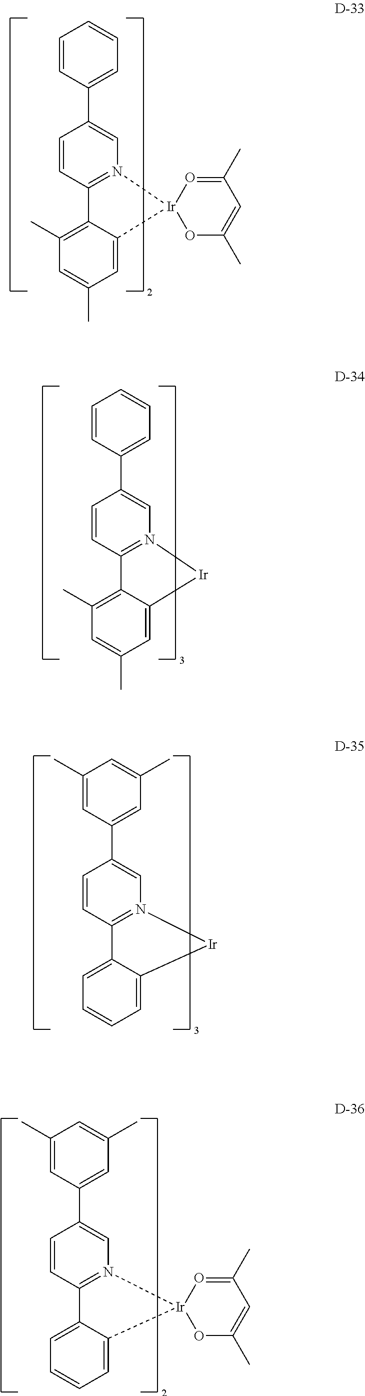

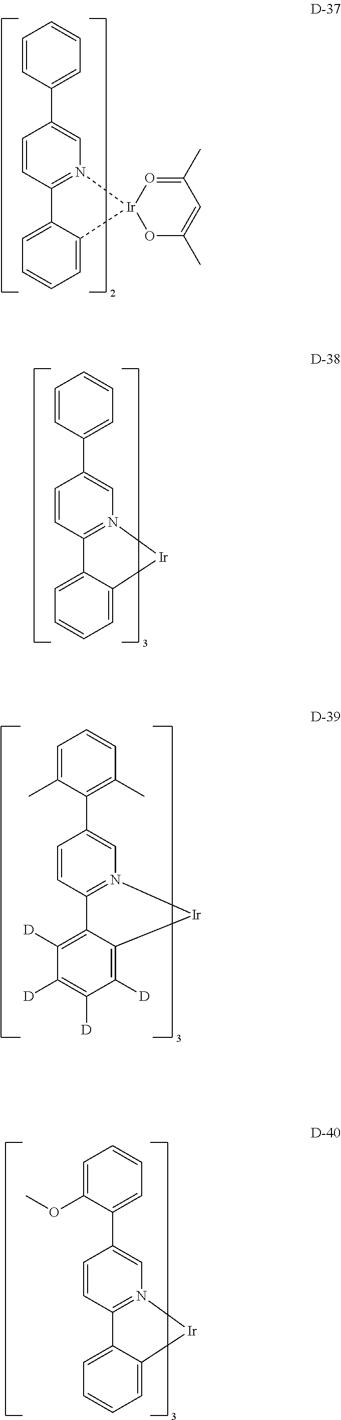

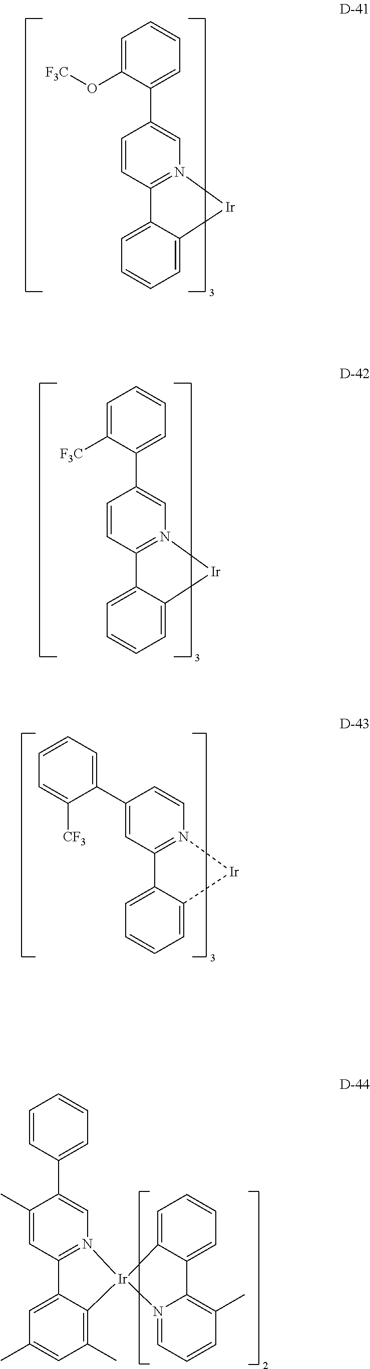

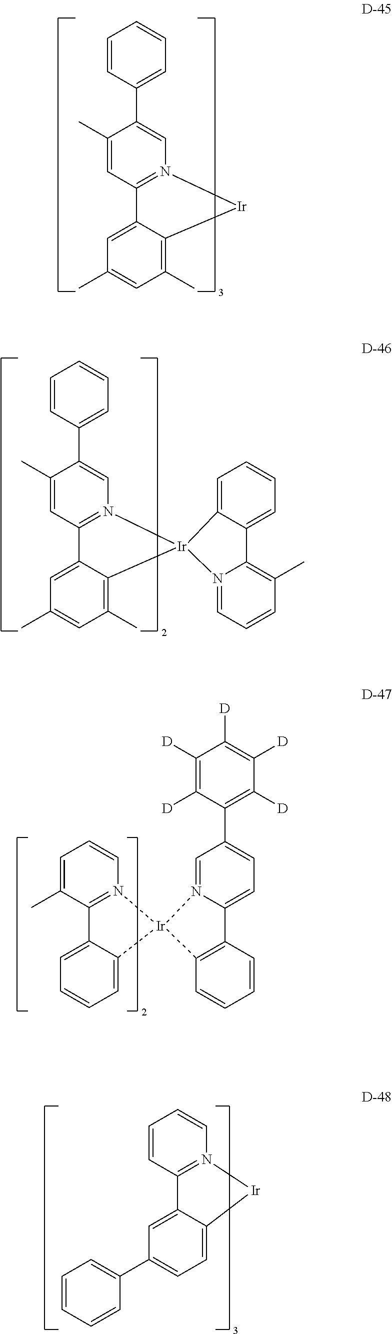

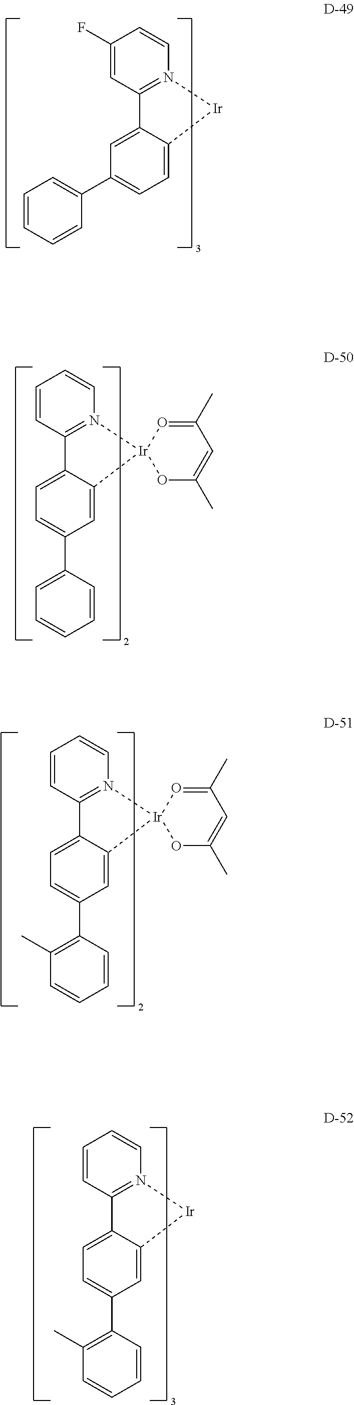

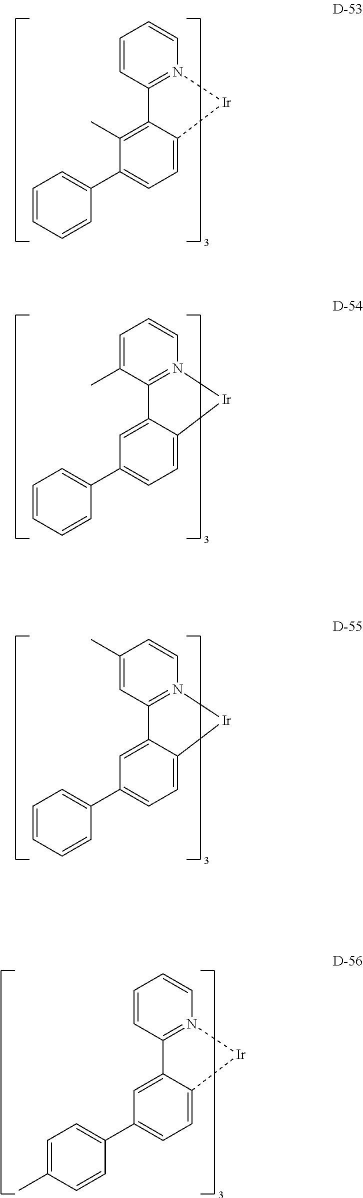

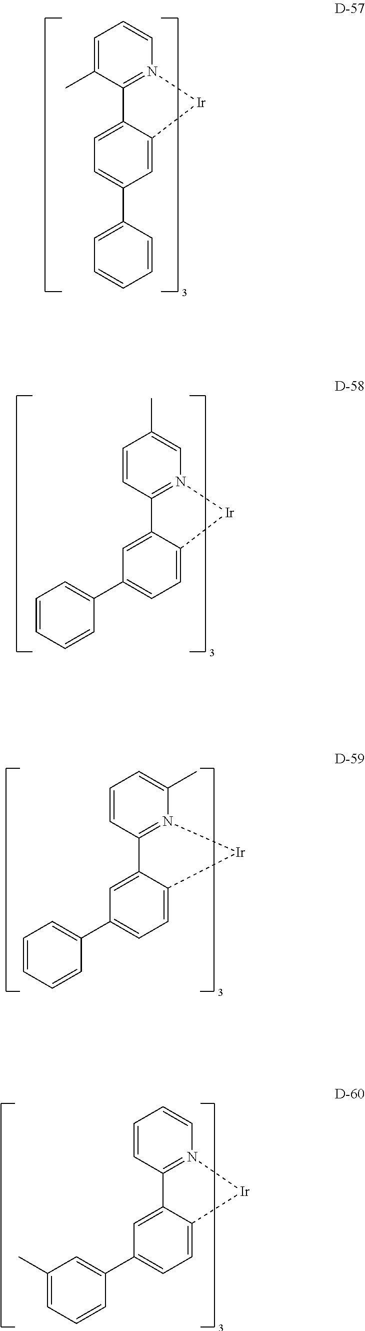

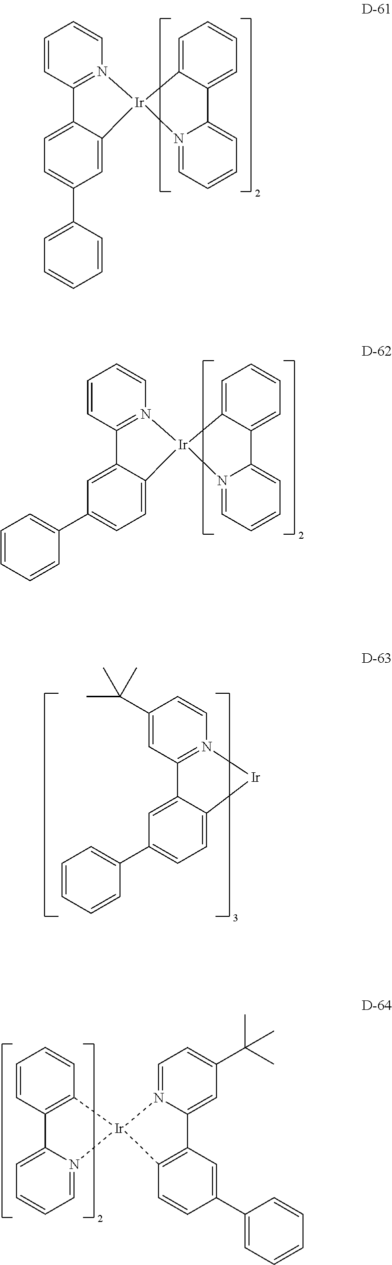

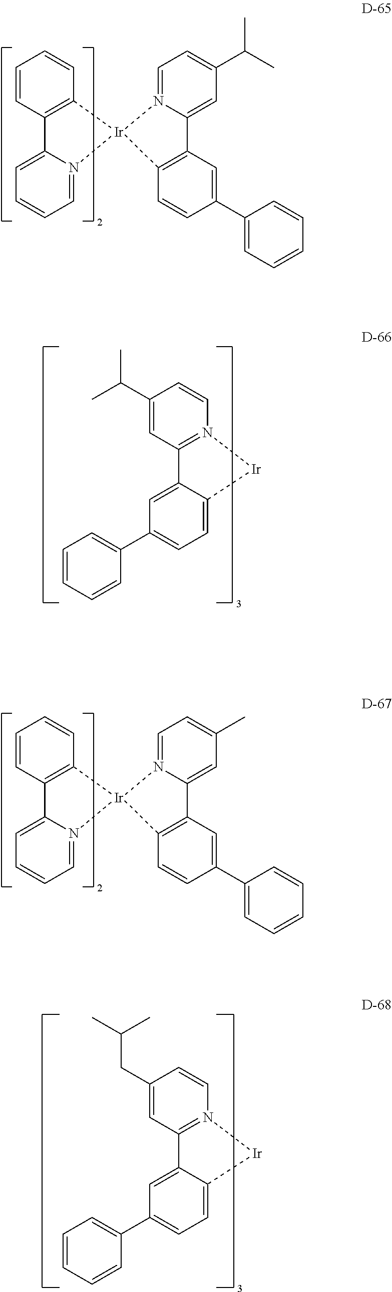

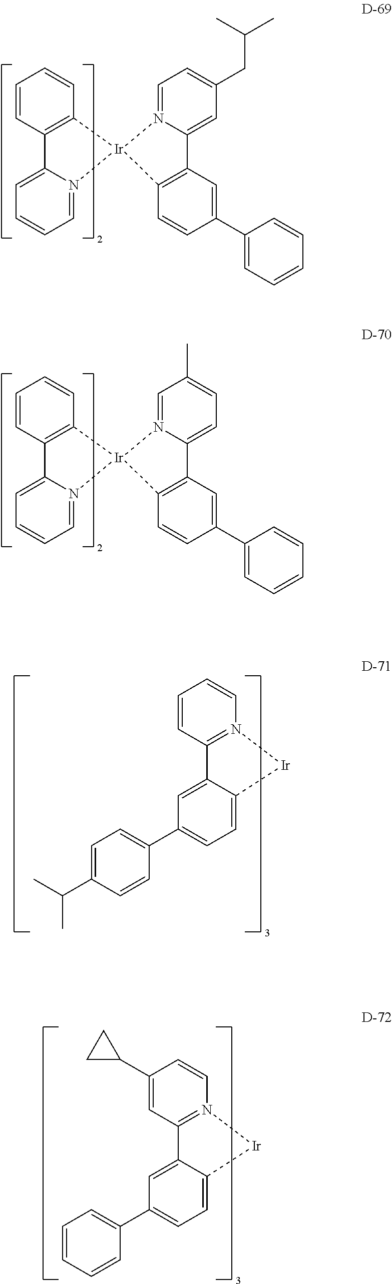

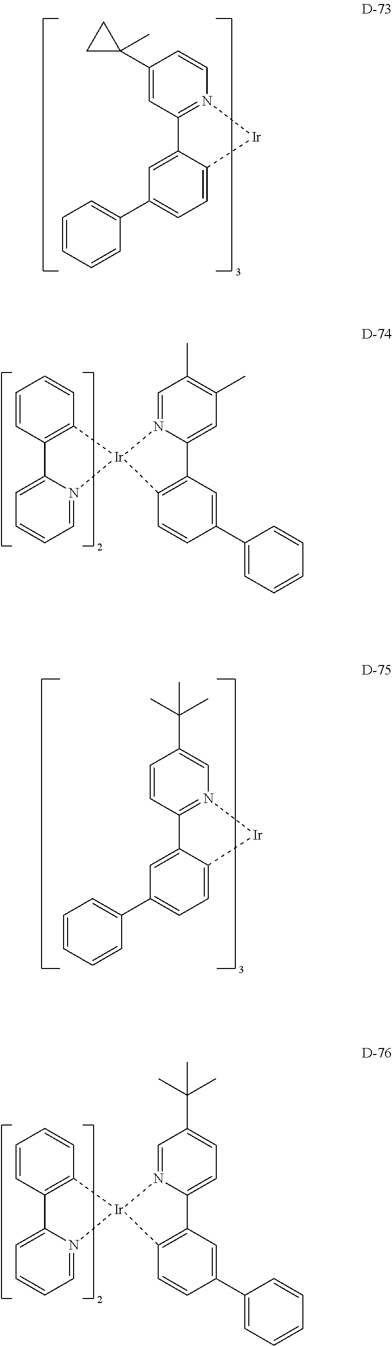

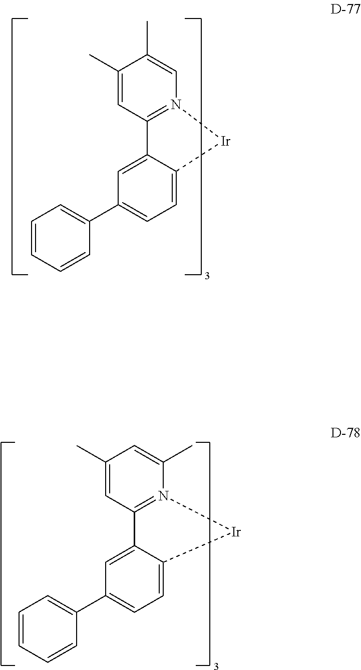

The organic layer of the organic electroluminescent device according to the present invention may further comprise, in addition to the organic electroluminescent compounds represented by formula 1, at least one amine-based compound selected from the group consisting of arylamine-based compounds and styrylarylamine-based compounds.

The representative arylamine-based compounds or styrylarylamine-based compounds are exemplified in Korean Patent Appln. No. 10-2008-0123276, No. 10-2008-0107606, and No. 10-2009-0042825, but not limited thereto, and various arylamine-based compounds and styrylarylamine-base compounds known in the art can be used.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may further comprise a light-emitting layer and a charge generating layer.

In addition, the organic electroluminescent device according to the present invention may emit white light by further comprising at least one light-emitting layer which comprises a blue electroluminescent compound, a red electroluminescent compound or a green electroluminescent compound known in the field, besides the organic electroluminescent compound according to the present invention. The blue electroluminescent compound, the red electroluminescent compound and the green electroluminescent compound are exemplified in Korean Appln. No. 10-2008-0123276, No. 10-2008-0107606, and No. 10-2008-0118428, but not limited thereto, and various blue electroluminescent compounds, various red electroluminescent compounds and various green electroluminescent compounds well-known in the art can be used. Also, if needed, a yellow or orange light-emitting layer can be comprised in the device.

According to the present invention, at least one layer (hereinafter, “a surface layer”) of the organic electroluminescent device preferably selected from a chalcogenide layer, a metal halide layer and a metal oxide layer; may be placed on an inner surface(s) of one or both electrode(s). Specifically, a chalcogenide (includes oxides) layer of silicon or aluminum is preferably placed on an anode surface of an electroluminescent medium layer, and a metal halide layer or a metal oxide layer is placed on a cathode surface of an electroluminescent medium layer. Such a surface layer provides operation stability for the organic electroluminescent device. Preferably, said chalcogenide includes SiOₓ(1≦X≦2), AlO_{X}(1≦X≦1.5), SiON, or SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

In order to form each layer of the organic electroluminescent device according to the present invention, dry film-forming methods such as vacuum evaporation, sputtering, plasma and ion plating methods, or wet film-forming methods such as spin coating, dip coating, and flow coating methods can be used.

When applying a wet film-forming method, a thin film can be formed by dissolving or diffusing materials which will form each layer into any suitable solvent such as ethanol, chloroform, tetrahydrofuran, dioxane, etc. The solvent can be any solvent which dissolves or diffuses the materials, unless the solvent has problems in film formation properties.

Hereinafter, the representative organic electroluminescent compound, the preparation method of the compound, and the luminescent properties of the device comprising the compound of the present invention will be explained in detail with reference to the following examples, but not limited thereto:

### EXAMPLE 1

### Preparation of Compound C-5

Compound C-5, which is the organic electroluminescent compound of the present invention, wherein a nitrogen-containing hetero ring is bonded to a carbazolyl group substituted with a 3-carbazolyl group was prepared according to the following Reaction 1.

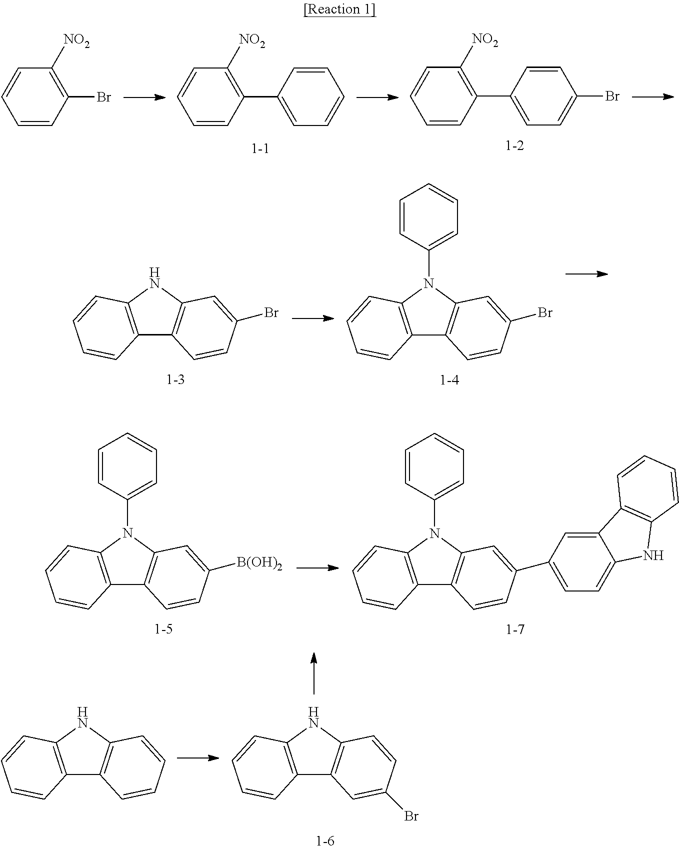

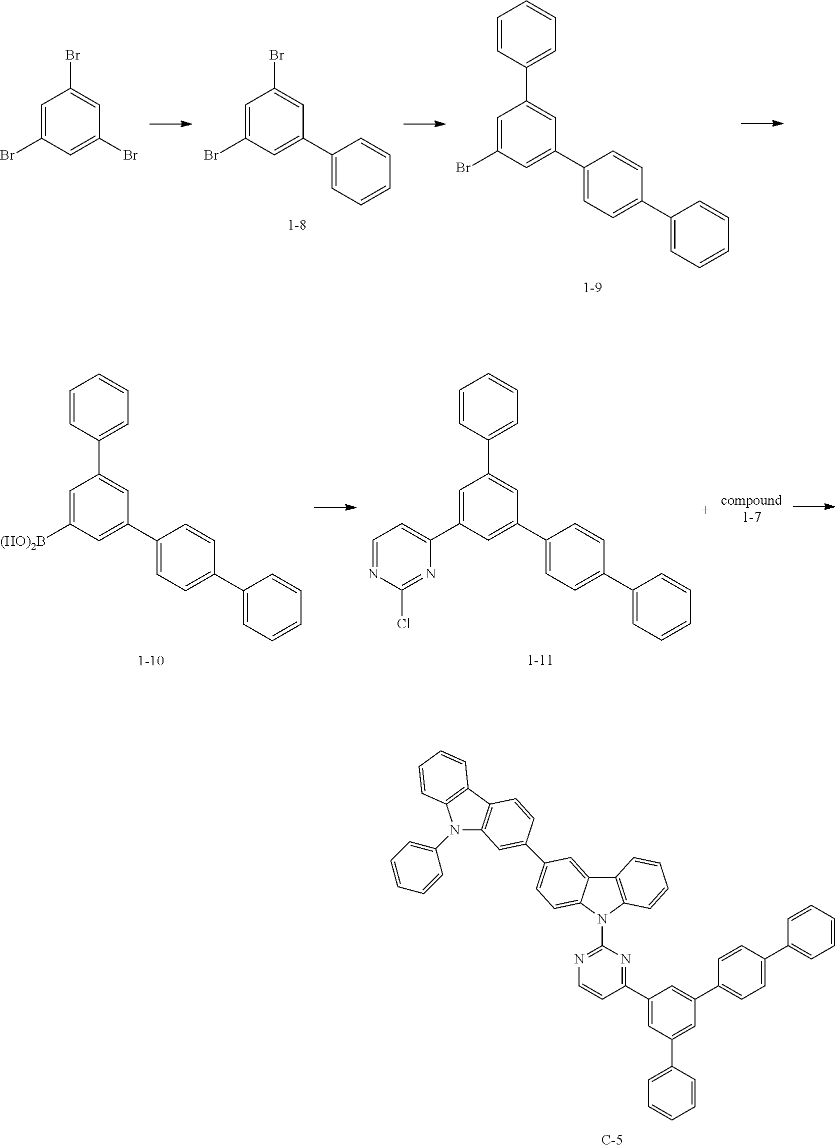

### Preparation of Compound 1-1

After dissolving bromonitrobenzene (30 g, 148.5 mmol), phenylboronic acid (27 g, 222. 7 mmol), Pd(PPh₃)₄ (5.14 g, 4.45 mmol), Na₂CO₃ (2 M, 190 mL) and ethanol 100 mL in toluene 500 mL, the mixture was stirred under reflux for 5 hours. After terminating the reaction, the mixture was cooled to room temperature, and distilled water was added. The mixture was extracted with ethyl acetate, and dried with magnesium sulfate. Then, the resulting product was distilled under reduced pressure, and separated through a column to obtain compound 1-1 (26 g, 130.5 mmol, 87.87%).

### Preparation of Compound 1-2

Compound 1-1 (26 g, 130.5 mmol) was dissolved in carbon tetrachloride 400 mL, and FeCl₃ (2.1 g, 13.05 mmol) was added. Then, Br₂ (6 mL, 117.4 mmol) was added at 0° C., and the mixture was stirred at room temperature for 12 hours. Then, after adding distilled water and neutralizing the mixture by adding KOH, the mixture was extracted with methylene chloride (MC). The extracted solution was dried with magnesium sulfate. Then, the extracted solution was distilled under reduced pressure, and separated through a column to obtain compound 1-2 (28 g, 100.6 mmol, 77.08%).

### Preparation of Compound 1-3

After dissolving compound 1-2 (28 g, 100.6 mmol) in triethyl phosphate 300 mL, the mixture was reacted at 150° C. for 7 hours. After terminating the reaction, the mixture was cooled to room temperature, and distilled under reduced pressure. The mixture was extracted with methylene chloride (MC), and washed with distilled water. The remaining moisture was removed with magnesium sulfate. After drying, the resulting product was distilled under reduced pressure, and separated through a column to obtain compound 1-3 (10 g, 40.63 mmol, 40.38%).

### Preparation of Compound 1-4

After mixing compound 1-3 (10 g, 40.63 mmol), CuI (3.8 g, 20.3 mmol), K₃PO₄ (21.56 g, 101.58 mmol), toluene 300 mL, iodobenzene 9.09 mL, and ethylenediamine (2.7 mL, 40.63 mmol), the mixture was stirred under reflux for 12 hours. Then, the mixture was cooled to room temperature and filtered under reduced pressure. The remaining solution was washed with distilled water and extracted with methylene chloride (MC). Then, the resulting product was dried with magnesium sulfate, distilled under reduced pressure, and separated through a column to obtain compound 1-4 (12 g, 37.24 mmol, 91.65%).

### Preparation of Compound 1-5

Compound 1-4 (20 g, 62.07 mmol) was dissolved in tetrahydrofuran (THF) 200 mL, and n-buLi (29 mL, 74.48 mmol) in 2.5 M hexane was slowly added to the mixture at −78° C. After one hour, triisopropylborate (19.9 mL, 86.90 mmol) was added. After stirring the mixture at room temperature for 12 hours, distilled water was added and the mixture was extracted with ethyl acetate (EA). Then, the resulting product was dried with magnesium sulfate, and distilled under reduced pressure. The resulting product was recrystallized with ethyl acetate (EA) and hexane to obtain compound 1-5 (12 g, 41.79 mmol, 67.33%).

### Preparation of Compound 1-6

Carbazole (20 g, 119.6 mmol) was dissolved in dimethylformamide (DMF) 200 mL, and N-bromosuccinimide (NBS) (21.2 g, 119.6 mmol) was added at 0° C. After stirring for 12 hours, distilled water was added, and the obtained solid was filtered under reduced pressure. The obtained solid was added to methanol, and after stirring, the solution was filtered under reduced pressure. The re-obtained solid was added to ethyl acetate (EA) and methanol, and stirred. Then, the mixture was filtered under reduced pressure to obtain compound 1-6 (17 g, 69.07 mmol, 58.04%).

### Preparation of Compound 1-7

After mixing compound 1-5 (12 g, 41.79 mmol), compound 1-6 (11.3 g, 45.97 mmol), Pd(PPh₃)₄ (1.4 g, 1.25 mmol), K₂CO₃ (2 M, 52 mL), toluene 150 mL and ethanol 30 mL, the mixture was stirred under reflux. After 5 hours, the mixture was cooled to room temperature and distilled water was added. The mixture was extracted with ethyl acetate (EA) and dried with magnesium sulfate. The resulting product was distilled under reduced pressure, and recrystallized with ethyl acetate (EA) and methanol to obtain 1-7 (10 g, 24.48 mmol, 58.57%).

### Preparation of Compound 1-8

After mixing 1,3,5-tribromobenzen (40 g, 127.06 mmol), phenyl boronic acid (17.04 g, 139.7 mmol), PdCl(PPh₃)₂ (1.78 g, 2.54 mmol), toluene 500 mL, and Na₂CO₃ (2 M, 130 mL), the mixture was stirred under reflux. After 3 hours, the mixture was cooled to room temperature, and distilled water was added. The mixture was extracted with ethyl acetate (EA) and dried with magnesium sulfate. After drying under reduced pressure, the resulting product was separated through a column to obtain compound 1-8 (24 g, 76.9 mmol, 60.56%).

### Preparation of Compound 1-9

Compound 1-8 (24 g, 76.9 mmo.), 4-biphenylboronic acid (16.75 g, 84.6 mmol), PdCl(PPh₃)₂ (1.07 g, 1.53 mmol), toluene 200 mL, and Na₂CO₃ (2 M, 75 mL) were dissolved in ethanol 20 mL. After stirring under reflux for 5 hours, the mixture was cooled to room temperature, and distilled water was added. The mixture was extracted with ethyl acetate (EA) and dried with magnesium sulfate. After distilling under reduced pressure, the resulting product was separated through a column to obtain compound 1-9 (19 g, 49.15 mmol, 64.12%).

### Preparation of Compound 1-10

Compound 1-9 (19 g, 49.35 mmol) was dissolved in THF 200 mL, and n-buLi (23.6 mL, 59.22 mmol) in 2.5 M hexane was slowly added at −78° C. After one hour, trimethylborate (8.2 mL, 73.96 mmol) was added. After stirring the mixture at room temperature for 12 hours, distilled water was added, and the mixture was extracted with ethyl acetate (EA). The resulting product was dried with magnesium sulfate and distilled under reduced pressure. The resulting product was recrystallized with ethyl acetate and hexane to obtain compound 1-10 (14 g, 39.97 mmol, 80.99%).

### Preparation of Compound 1-11

After mixing compound 1-10 (14 g, 39.97 mmol), 2,4-dichloropyrimidine (7.14 g, 47.96 mmol), Pd(PPh₃)₄ (1.38 g, 1.19 mmol), toluene 200 mL, Na₂CO₃ (2 M, 40 mL) and ethanol 20 mL, the mixture was stirred under reflux. After 5 hours, the mixture was cooled to room temperature, distilled water was added, and the mixture was extracted with ethyl acetate (EA). The resulting product was dried with magnesium sulfate and distilled under reduced pressure. The resulting product was separated through a column to obtain compound 1-11 (11 g, 31.82 mmol, 79.62%).

### Preparation of Compound C-5

After dissolving compound 1-7 (5 g, 12.24 mmol), compound 1-11 (6.15 g, 14.68 mmol) in DMF 300 mL, NaH (0.73 g, 18.36 mmol; dissolved in mineral oil in concentration of 60%) was slowly added. After stirring the mixture at room temperature for 12 hours, distilled water was added, and the obtained solid was filtered under reduced pressure. The resulting product was separated through a column to obtain compound C-5 (5 g, 6.32 mmol, 51.64%).

MS/FAB: found 790.95; calculated 790.31

### EXAMPLE 2

### Preparation of Compound C-14

Compound C-14 which is the organic electroluminescent compound of the present invention wherein nitrogen-containing hetero ring is bonded to a carbazolyl group substituted with a 3-carbazolyl group can be prepared according to the following Reaction 2.

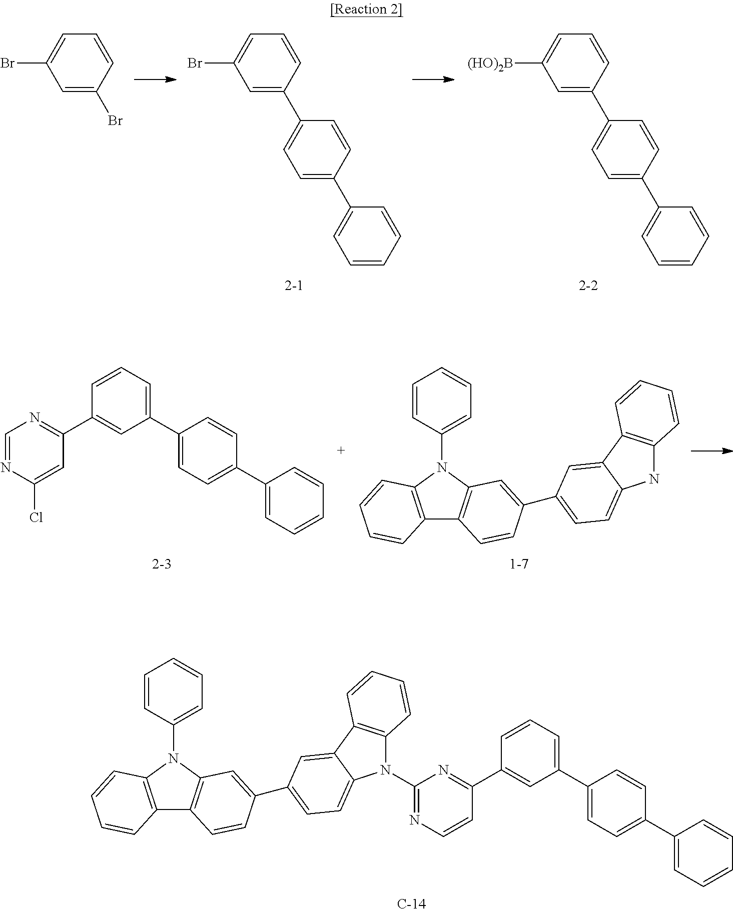

### Preparation of Compound 2-1

After dissolving 1,3-dibromobenzen (36.5 mL, 302.98 mmol), 4-biphenylboronic acid (40 g, 201.98 mmol), Pd(PPh₃)₄ (4.25 g, 6.05 mmol), Na₂CO₃ (2 M, 250 mL) and ethanol 100 mL in toluene 400 mL, the mixture was stirred under reflux. After 12 hours, the mixture was cooled to room temperature, and distilled water was added. The mixture was extracted with ethyl acetate (EA) and dried with magnesium sulfate. The resulting product was distilled under reduced pressure and separated through a column to obtain compound 2-1 (25 g, 80.85 mmol, 40.12%).

### Preparation of Compound 2-2

Compound 2-1 (25 g, 80.85 mmol) was dissolved in THF, and n-buLi (42 mL, 105.10 mmol) in 2.5 M hexane was slowly added at −78° C. After one hour, trimethylborate (14.42 mL, 129.3 mmol) was added. The mixture was stirred at room temperature for 12 hours, and distilled water was added. The mixture was extracted with ethyl acetate (EA) and dried with magnesium sulfate. The resulting product was distilled under reduced pressure and recrystallized with methylenechloride (MC) and hexane to obtain compound 2-2 (20 g, 72.96 mmol, 90.24%).

### Preparation of Compound 2-3

After dissolving compound 2-2 (20 g, 72.96 mmol), 2,4-dichloropyrimidine (9.8 g, 80.25 mmol), Pd(PPh₃)₄ (2.28 g, 2.18 mmol), Na₂CO₃ (2 M, 80 mL) and ethanol 50 mL in toluene 150 mL, the mixture was stirred under reflux for 5 hours. The mixture was cooled to room temperature, and distilled water was added. The mixture was extracted with ethyl acetate (EA) and dried with magnesium sulfate. The resulting product was distilled under reduced pressure, and recrystallized with ethyl acetate (EA) and methanol to obtain compound 2-3 (11 g, 32.08 mmol, 43.97%).

### Preparation of Compound C-14

Compound 1-7 (5.2 g, 12.83 mmol) and compound 2-3 (4 g, 11.66 mmol) was dissolved in DMF 150 mL, and NaH (0.7 g, 17.50 mmol; dissolved in mineral oil in concentration of 60%) was added. The mixture was stirred at room temperature for 12 hours, and methanol and distilled water were added. The obtained solid was filtered under reduced pressure, and separated through a column to obtain compound C-14 (4.5 g, 6.29 mmol, 53.98%).

MS/FAB: found 714.85; calculated 714.28.

### DEVICE EXAMPLE 1

### Production of an OLED Device Using the Compound According to the Present Invention

An OLED device using the organic electroluminescent compound according to the present invention was produced as follows, and then data of device characteristics was measured for the resulting OLED device.

First, a transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N¹′-([1,1-bi phenyl]-4,4′-diyl)bis(N¹-(naphthalene-1-yl)-N⁴,N⁴-diphenylbenzen-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminobiphenyl was introduced into another cell of said vacuum vapor depositing apparatus, and was evaporated by applying an electric current to the cell, thereby forming a hole transport layer having a thickness of 20 nm on the hole injection layer. After the hole injection layer and the hole transport layer were formed as above, a light-emitting layer was deposited on said layers as follows.

Compound C-111 was introduced into one cell of the vacuum vapor depositing apparatus, as a host material, and D-5 was introduced into another cell as another host material, as a dopant material, and the two materials were evaporated at different rates, and deposited in a doping amount of 15 wt % based on the total amount of the host and dopant to form a light-emitting layer having a thickness of 30 nm on the hole transport layer. Then, in order to form an electron transport layer on the formed light-emitting layer, 2-(4-(9,10-di(naphthalen-2-yl)anthracen-2-yl)phenyl)-1-phenyl-1H-benzo[d]imidazole was introduced into a cell, and lithium quinolate was introduced into another cell, and the two materials were evaporated at the same rate to deposit in a doping amount of 50 wt %, respectively. Thus, an electron transport layer having a thickness of 30 nm was formed on the light-emitting layer. Then, in order to form an electron injection layer, after depositing lithium quinolate in a thickness of 2 nm, an Al cathode having a thickness of 150 nm was deposited by another vacuum vapor deposition apparatus. Thus, an OLED device was produced. All the materials used for producing the OLED device were purified by vacuum sublimation at 10⁻⁶ torr prior to use.

On the test of the finally obtained organic electroluminescent device according to the present invention, the produced OLED device showed a green emission having a luminance of 600 cd/m² and a current density of 1.36 mA/cm².

### COMPARATIVE EXAMPLE 1

### Production of an OLED Device Using Conventional Electroluminescent Compounds

An OLED device was produced in the same manner as in Device Example 1, except that 4,4′-bis(carbazol-9-yl)biphenyl (CBP), instead of the compound according to the present invention, was introduced into the cell of the vacuum vapor depositing apparatus as a host material, and compound D-5 was used as a dopant; and a hole blocking layer was deposited by using aluminum(III)bis(2-methyl-8-quinolinato)ₚ-phenylphenolate (BAIq).

On the test of the finally obtained organic electroluminescent device, the OLED device showed a green emission having a luminance of 600 cd/m² and a current density of 1.76 mA/cm².

It is confirmed that the organic electroluminescent compounds according to the present invention have high luminous efficiency of green color, compared with conventional phosphorescent host materials, and thus have an advantage of providing an organic electroluminescent device which induces increased power efficiency and improves power consumption.

Although the invention is explained with reference to the above examples, the present invention is not limited to the above examples. One skilled in the art can modify or change the invention within the purpose or scope of the present invention, and such modification and change are also included in the present invention.

1. An organic electroluminescent compound represented by the following formula 1: 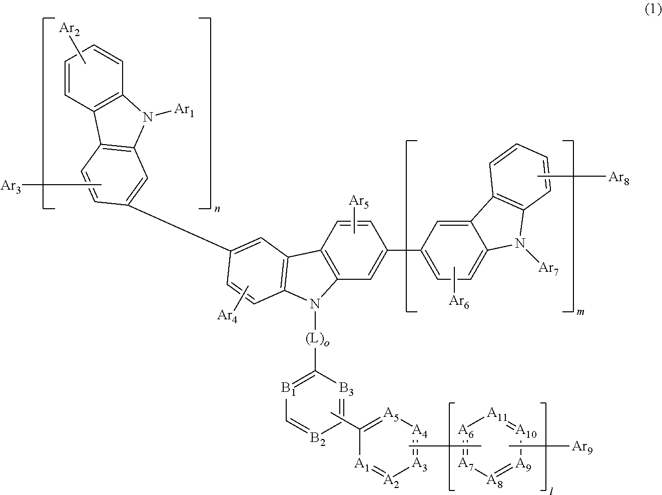
wherein
L represents a substituted or unsubstituted (C6-C30)arylene group, or a substituted or unsubstituted 3- to 30-membered heteroarylene group;
A₁ to A₁₁ each independently represent CR₁₁ or N;
B₁ to B₃ each independently represent CR₂₁ or N, provided that B₁ to B₃ are not simultaneously CR₂₁;
Ar₁ to Ar₉ each independently represent hydrogen, deuterium, a halogen, a cyano group, a nitro group, a hydroxyl group, a substituted or unsubstituted (C1-C30)alkyl group, a substituted or unsubstituted (C3-C30)cycloalkyl group, a substituted or unsubstituted (C6-C30)aryl group, a substituted or unsubstituted 3- to 30-membered heteroaryl group, —NR₁₂R₁₃, —SiR₁₄R₁₅R₁₆, —SR₁₇ or —OR₁₈;
R₁₁ to R₁₈ and R₂₁ each independently represent hydrogen, deuterium, a halogen, a substituted or unsubstituted (C1-C30)alkyl group, a substituted or unsubstituted (C3-C30)cycloalkyl group, a substituted or unsubstituted (C6-C30)aryl group, or a substituted or unsubstituted 3- to 30-membered heteroaryl group; or are linked to an adjacent substituent(s) to form a substituted or unsubstituted mono- or polycyclic 3- to 30-membered alicyclic or aromatic ring whose carbon atom(s) may be replaced by at least one heteroatom selected from nitrogen, oxygen and sulfur;
o represents an integer of 0 to 2; where o is 2, each of L is the same or different;
m and n each independently represent 0 or 1, and m+n=1;
l represents an integer of 1 to 4; where l is an integer of 2 or more, each of A₆ to A₁₁ is the same or different; and
the heteraryl(ene) group contains at least one hetero atom selected from B, N, O, S, P(═O), Si and P.

2. The organic electroluminescent compound according to claim 1, wherein L represents a substituted or unsubstituted (C6-C20)arylene group; A₁ to A₁₁ each independently represent CR₁₁ or N; B₁ to B₃ each independently represent CR₂₁ or N, provided that B₁ to B₃ are not simultaneously CR₂₁; Ar₁ to Ar₉ each independently represent hydrogen, a halogen, an unsubstituted (C1-C10)alkyl group, an unsubstituted (C3-C10)cycloalkyl group, a substituted or unsubstituted (C6-C20)aryl group, a substituted or unsubstituted 3- to 20-membered heteroaryl group, or —SiR₁₄R₁₅R₁₆; R₁₁ to R₁₈ and R₂₁ each independently represent hydrogen, a halogen, an unsubstituted (C1-C10)alkyl group, an unsubstituted (C3-C10)cycloalkyl group, a substituted or unsubstituted (C6-C20)aryl group, or an unsubstituted 3- to 20-membered heteroaryl group; or are linked to an adjacent substituent(s) to form a substituted or unsubstituted mono- or polycyclic 3- to 20-membered aromatic ring whose carbon atom(s) may be replaced by at least one heteroatom selected from nitrogen, oxygen and sulfur; o represents an integer of 0 to 2; where o is 2, each of L is the same or different; m and n each independently represent 0 or 1, and m+n=1; and I represents 1 or 2; where l is 2, each of A₆ to A₁₁ is the same or different.

3. The organic electroluminescent compound according to claim 1, wherein L represents a (C6-C15)arylene group unsubstituted or substituted with a (C1-C6)alkyl group; A₁ to A₁₁ each independently represent CR₁₁ or N; B₁ to B₃ each independently represent CR₂₁ or N, provided that B₁ to B₃ are not simultaneously CR₂₁; Ar₁ to Ar₉ each independently represent hydrogen, a halogen, an unsubstituted (C1-C6)alkyl group, an unsubstituted (C3-C7)cycloalkyl group; a (C6-C15)aryl group unsubstituted or substituted with deuterium, a halogen, a (C1-C6)alkyl group, a (C6-C15)aryl group, a (C6-C15)aryloxy group, or a 3- to 15-membered heteroaryl group; a 3- to 15-membered heteroaryl group unsubstituted or substituted with a (C6-C15)aryl group; or —SiR₁₄R₁₅R₁₆; R₁₁ to R₁₈ and R₂₁ each independently represent hydrogen, a halogen, an unsubstituted (C1-C6)alkyl group, an unsubstituted (C3-C7)cycloalkyl group; a (C6-C15)aryl group unsubstituted or substituted with deuterium, a halogen, or a (C1-C6)alkyl group; or an unsubstituted 3- to 15-membered heteroaryl group; or are linked to an adjacent substituent(s) to form a mono- or polycyclic 3- to 15-membered aromatic ring unsubstituted or substituted with a (C1-C6)alkyl group or a (C6-C15)aryl group, whose carbon atom(s) may be replaced by at least one heteroatom selected from nitrogen, oxygen and sulfur; o represents an integer of 0 to 2; where o is 2, each of L is the same or different; m and n each independently represent 0 or 1, and m+n=1; and I represents 1 or 2; where l is 2, each of A₆ to A₁₁ is the same or different.

4. The organic electroluminescent compound according to claim 1, wherein L represents a phenylene, naphthylene, biphenylene, fluorenylene, anthracenylene, pyridinylene, pyrimidinylene, triazinylene, furanylene, thiophenylene, dibenzothiophenylene, dibenzofuranylene or phenylene-dibenzothiophenylene group;
wherein Ar₁ to Ar₉ each independently represent hydrogen, deuterium, chlorine, fluorine, a phenyl group, a naphthyl group, a biphenyl group, a fluorenyl group, a phenanthryl group, an anthryl group, a fluoranthenyl group, a triphenylenyl group, a pyrenyl group, a chrysenyl group, a naphthacenyl group, a pherylenyl group, a pyridyl group, a pyrrolyl group, a furanyl group, a thiophenyl group, an imidazolyl group, a benzoimidazolyl group, a pyrazinyl group, a pyrimidinyl group, a pyridazinyl group, a quinolyl group, a triazinyl group, a benzofuranyl group, a dibenzofuranyl group, a benzothiophenyl group, a dibenzothiophenyl group, a pyrazolyl group, an indolyl group, a carbazolyl group, a thiazolyl group, an oxazolyl group, a benzothiazolyl group, a benzoxazolyl group, a phenanthrolinyl group or an N-carbazolyl group;
wherein R₁₁ to R₁₈ and R₂₁ each independently represent hydrogen, deuterium, a phenyl group, a naphthyl group, a biphenyl group, a fluorenyl group, a phenanthryl group, an anthryl group, a fluoranthenyl group, a triphenylenyl group, a pyrenyl group, a chrysenyl group, a naphthacenyl group, a pherylenyl group, a pyridyl group, a pyrrolyl group, a furanyl group, a thiophenyl group, an imidazolyl group, a benzoimidazolyl group, a pyrazinyl group, a pyrimidinyl group, a pyridazinyl group, a quinolyl group, a triazinyl group, a benzofuranyl group, a dibenzofuranyl group, a dibenzothiophenyl group, a benzothiophenyl group, a pyrazolyl group, an indolyl group, a carbazolyl group, a thiazolyl group, an oxazolyl group, a benzothiazolyl group, a benzoxazolyl group, a phenanthrolinyl group or an N-carbazolyl group.

5. The organic electroluminescent compound according to claim 1, wherein the substituents on L, Ar₁ to Ar₉, R₁₁ to R₁₈ and R₂₁ each independently are at least one selected from the group consisting of deuterium, a halogen, a (C1-C30)alkyl group, a (C1-C30)alkyl group substituted with a halogen, a (C6-C30)aryl group, a (C6-C30)aryloxy group, a 3- to 30-membered heteroaryl group, a 3- to 30-membered heteroaryl group substituted with a (C6-C30)aryl group, a (C3-C30)cycloalkyl group, a 3- to 30-membered heterocycloalkyl group, a tri(C1-C30)alkylsilyl group, a tri(C6-C30)arylsilyl group, a di(C1-C30)alkyl(C6-C30)arylsilyl group, a (C1-C30)alkyldi(C6-C30)arylsilyl group, a (C2-C30)alkenyl group, a (C2-C30)alkynyl group, a cyano group, a carbazolyl group, a di(C1-C30)alkylamino group, a di(C6-C30)arylamino group, a (C1-C30)alkyl(C6-C30)arylamino group, a di(C6-C30)arylboronyl group, a di(C1-C30)alkylboronyl group, a (C1-C30)alkyl(C6-C30)arylboronyl group, a (C6-C30)ar(C1-C30)alkyl group, a (C1-C30)alkyl(C6-C30)aryl group, a carboxyl group, a nitro group and a hydroxyl group.

6. The organic electroluminescent compound according to claim 1, wherein the substituents on L, Ar₁ to Ar₉, R₁₁ to R₁₈ and R₂₁ each independently are at least one selected from the group consisting of deuterium, chlorine, a methyl group, an ethyl group, an n-propyl group, an i-propyl group, an n-butyl group, an i-butyl group, a t-butyl group, an n-pentyl group, an i-pentyl group, an n-hexyl group, an n-heptyl group, an n-octyl group, a 2-ethylhexyl group, an n-nonyl group, a decyl group, a dodecyl group, a hexadecyl group, a trifluoromethyl group, a perfluoroethyl group, a trifluoroethyl group, a perfluoropropyl group, a perfluorobutyl group, a phenyl group, a naphthyl group, a biphenyl group, a fluorenyl group, a phenanthryl group, an anthryl group, a fluoranthenyl group, a triphenylenyl group, a pyrenyl group, a chrysenyl group, a naphthacenyl group, a perylenyl group, a trimethylsilyl group, a triethylsilyl group, a tripropylsilyl group, a tri(t-butyl)silyl group, a t-butyldimethylsilyl group, a dimethylphenylsilyl group and a triphenylsilyl group.

7. An organic electroluminescent compound represented by the following formula 2: 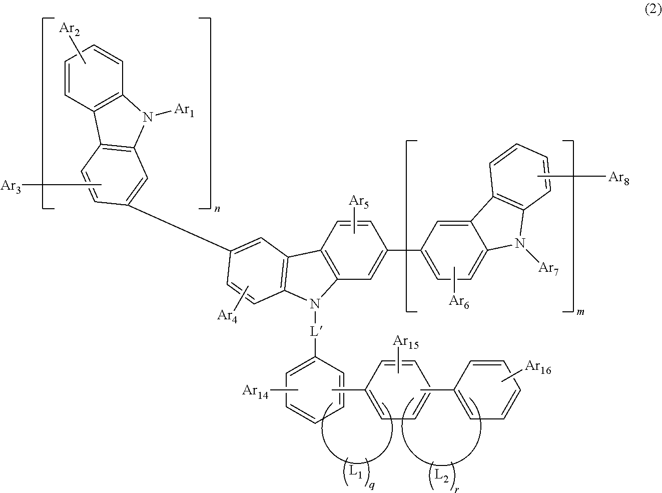
Wherein
L′ represents a substituted or unsubstituted, nitrogen-containing 3- to 30-membered heteroarylene;
m, n and Ar₁ to Ar₈ are as defined in claim 1;
Ar₁₄ to Ar₁₆ are as defined in R₁₁ of claim 1;
L₁ and L₂ each independently are selected from the group consisting of —CR₅₁R₅₂—, —O—, —NR₅₃ and —S—, wherein R₅₁ to R₅₃ are as defined in R₁₁ of claim 1;
q and r each independently represent 0 to 1, and q+r=1.

8. The organic electroluminescent compound according to claim 1, wherein the compound is selected from the group consisting of:

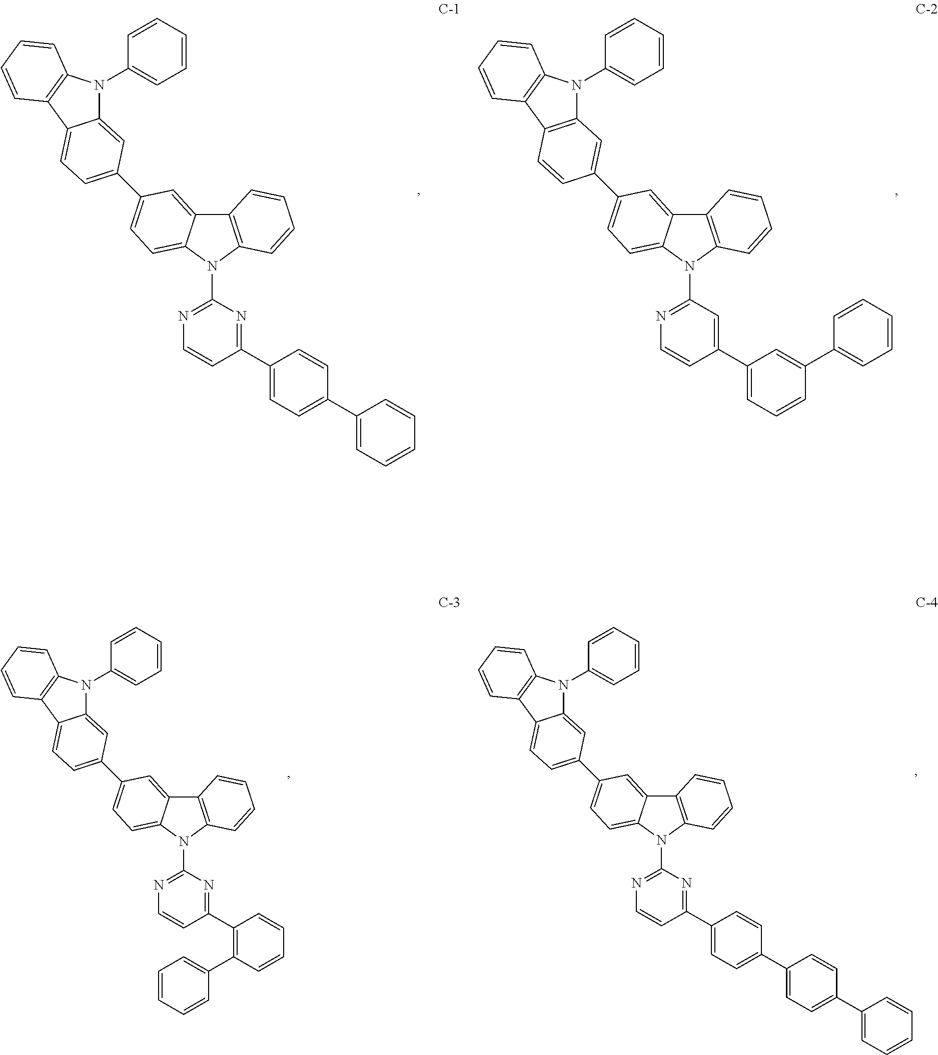 [SMILES: c1ccc(-c2ccc(-c3ccnc(-n4c5ccccc5c5cc(-c6ccc7c8ccccc8n(-c8ccccc8)c7c6)ccc54)n3)cc2)cc1 ; c1ccc(-c2cccc(-c3ccnc(-n4c5ccccc5c5cc(-c6ccc7c8ccccc8n(-c8ccccc8)c7c6)ccc54)c3)c2)cc1 ; c1ccc(-c2ccccc2-c2ccnc(-n3c4ccccc4c4cc(-c5ccc6c7ccccc7n(-c7ccccc7)c6c5)ccc43)n2)cc1 ; c1ccc(-c2ccc(-c3ccc(-c4ccnc(-n5c6ccccc6c6cc(-c7ccc8c9ccccc9n(-c9ccccc9)c8c7)ccc65)n4)cc3)cc2)cc1]

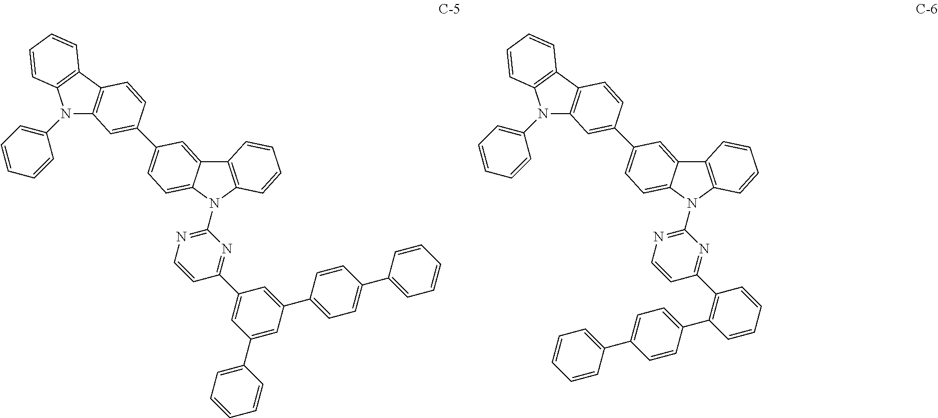 [SMILES: c1ccc(-c2ccc(-c3cc(-c4ccccc4)cc(-c4ccnc(-n5c6ccccc6c6cc(-c7ccc8c9ccccc9n(-c9ccccc9)c8c7)ccc65)n4)c3)cc2)cc1 ; c1ccc(-c2ccc(-c3ccccc3-c3ccnc(-n4c5ccccc5c5cc(-c6ccc7c8ccccc8n(-c8ccccc8)c7c6)ccc54)n3)cc2)cc1]

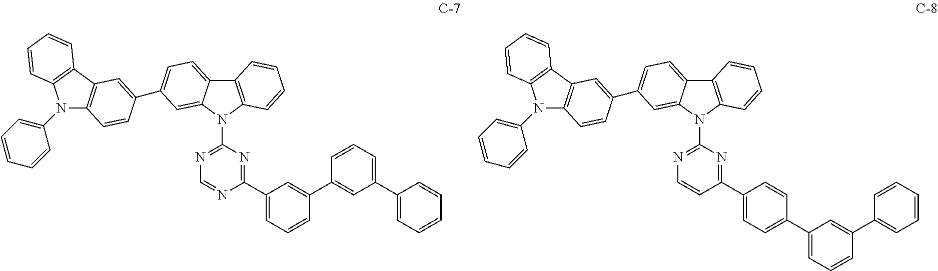 [SMILES: c1ccc(-c2cccc(-c3cccc(-c4ncnc(-n5c6ccccc6c6ccc(-c7ccc8c(c7)c7ccccc7n8-c7ccccc7)cc65)n4)c3)c2)cc1 ; c1ccc(-c2cccc(-c3ccc(-c4ccnc(-n5c6ccccc6c6ccc(-c7ccc8c(c7)c7ccccc7n8-c7ccccc7)cc65)n4)cc3)c2)cc1]

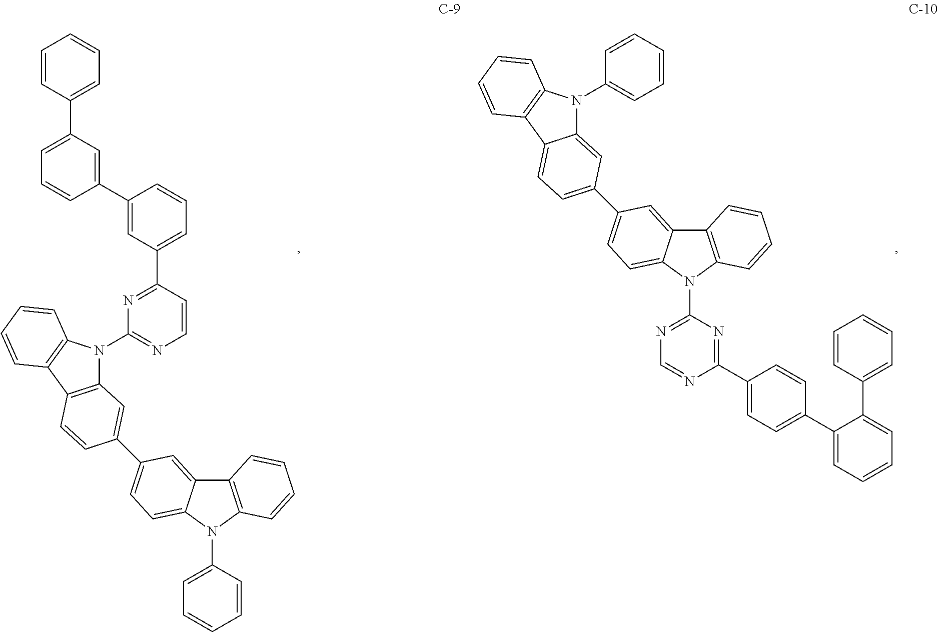 [SMILES: c1ccc(-c2cccc(-c3cccc(-c4ccnc(-n5c6ccccc6c6ccc(-c7ccc8c(c7)c7ccccc7n8-c7ccccc7)cc65)n4)c3)c2)cc1 ; c1ccc(-c2ccccc2-c2ccc(-c3ncnc(-n4c5ccccc5c5cc(-c6ccc7c8ccccc8n(-c8ccccc8)c7c6)ccc54)n3)cc2)cc1]

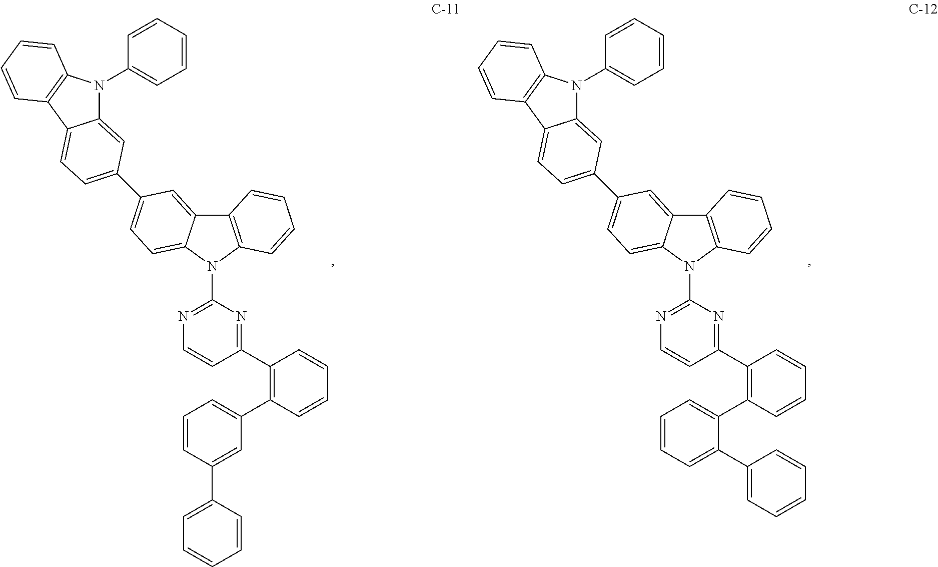 [SMILES: c1ccc(-c2cccc(-c3ccccc3-c3ccnc(-n4c5ccccc5c5cc(-c6ccc7c8ccccc8n(-c8ccccc8)c7c6)ccc54)n3)c2)cc1 ; c1ccc(-c2ccccc2-c2ccccc2-c2ccnc(-n3c4ccccc4c4cc(-c5ccc6c7ccccc7n(-c7ccccc7)c6c5)ccc43)n2)cc1]

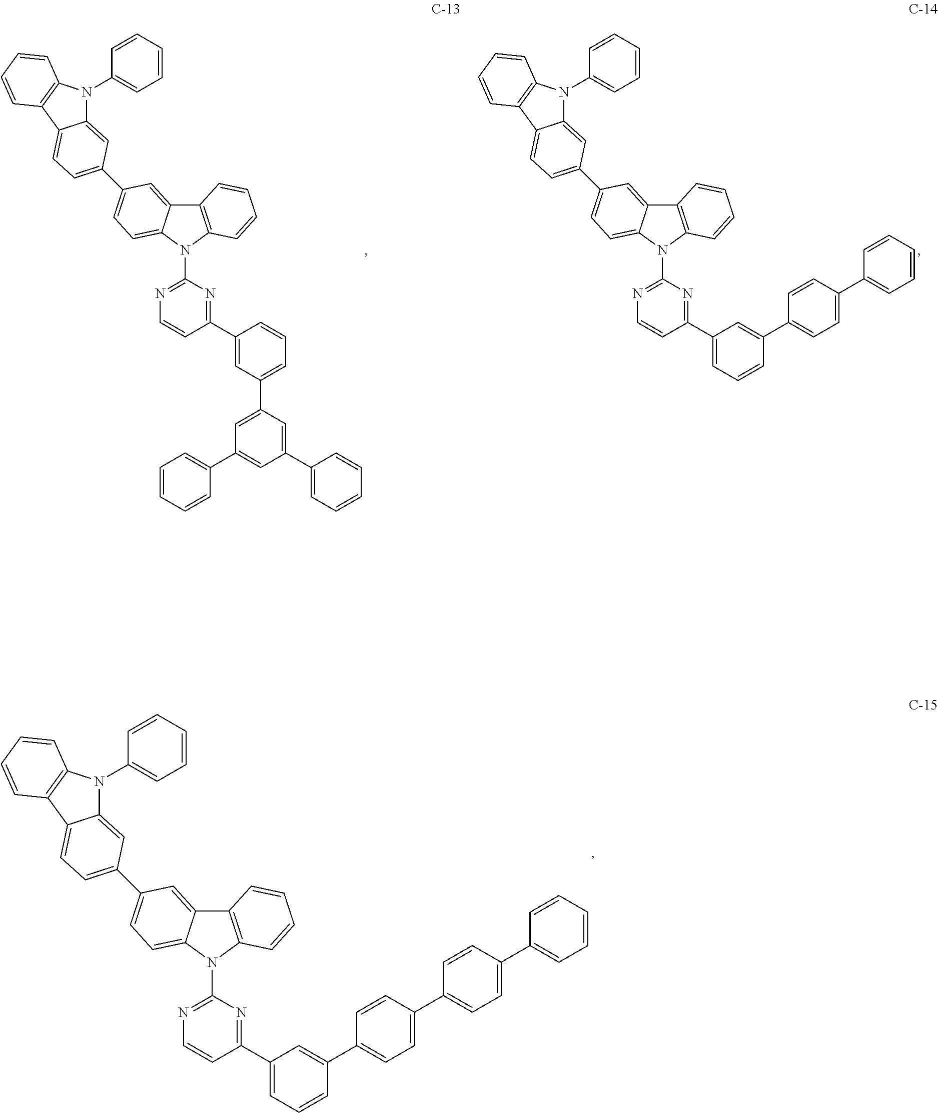 [SMILES: c1ccc(-c2cc(-c3ccccc3)cc(-c3cccc(-c4ccnc(-n5c6ccccc6c6cc(-c7ccc8c9ccccc9n(-c9ccccc9)c8c7)ccc65)n4)c3)c2)cc1 ; c1ccc(-c2ccc(-c3cccc(-c4ccnc(-n5c6ccccc6c6cc(-c7ccc8c9ccccc9n(-c9ccccc9)c8c7)ccc65)n4)c3)cc2)cc1 ; c1ccc(-c2ccc(-c3ccc(-c4cccc(-c5ccnc(-n6c7ccccc7c7cc(-c8ccc9c%10ccccc%10n(-c%10ccccc%10)c9c8)ccc76)n5)c4)cc3)cc2)cc1]

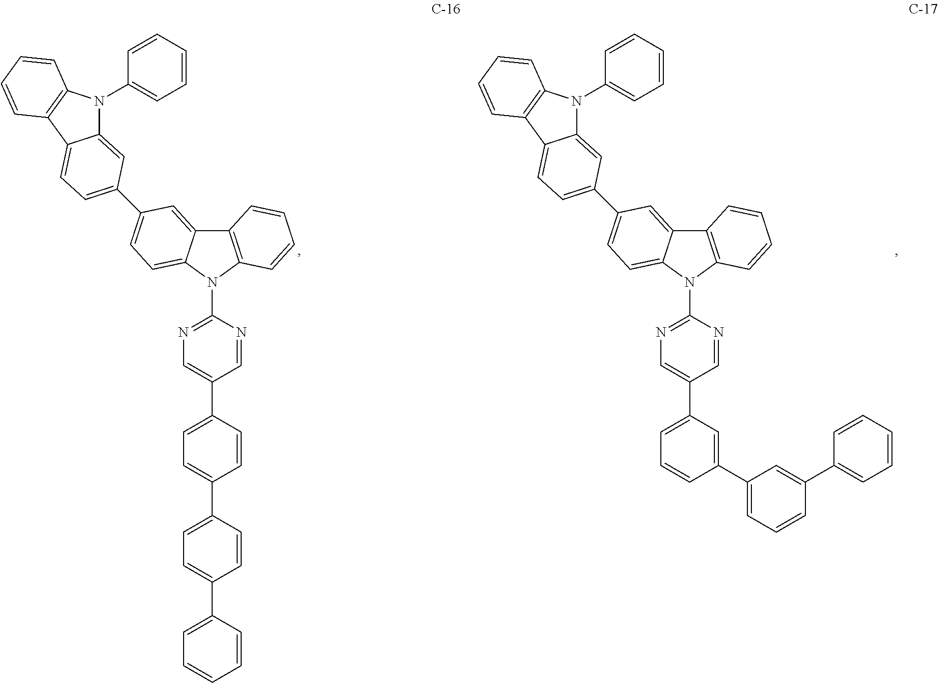 [SMILES: c1ccc(-c2ccc(-c3ccc(-c4cnc(-n5c6ccccc6c6cc(-c7ccc8c9ccccc9n(-c9ccccc9)c8c7)ccc65)nc4)cc3)cc2)cc1 ; c1ccc(-c2cccc(-c3cccc(-c4cnc(-n5c6ccccc6c6cc(-c7ccc8c9ccccc9n(-c9ccccc9)c8c7)ccc65)nc4)c3)c2)cc1]

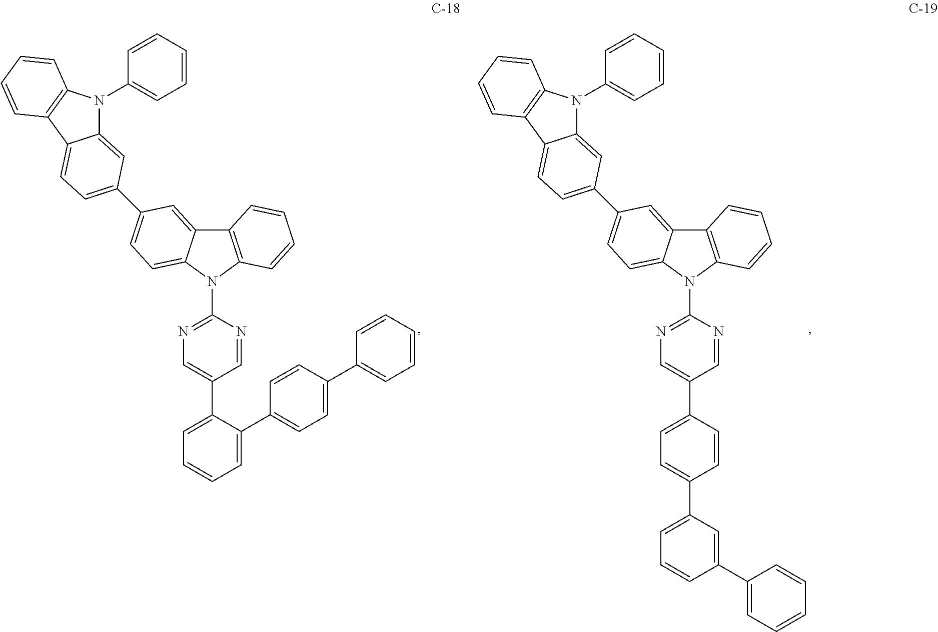 [SMILES: c1ccc(-c2ccc(-c3ccccc3-c3cnc(-n4c5ccccc5c5cc(-c6ccc7c8ccccc8n(-c8ccccc8)c7c6)ccc54)nc3)cc2)cc1 ; c1ccc(-c2cccc(-c3ccc(-c4cnc(-n5c6ccccc6c6cc(-c7ccc8c9ccccc9n(-c9ccccc9)c8c7)ccc65)nc4)cc3)c2)cc1]

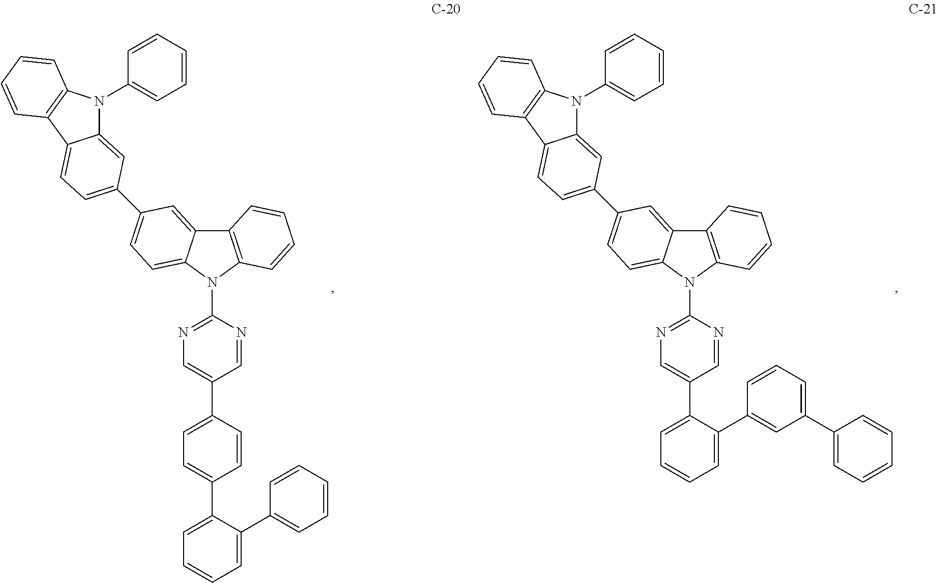 [SMILES: c1ccc(-c2ccccc2-c2ccc(-c3cnc(-n4c5ccccc5c5cc(-c6ccc7c8ccccc8n(-c8ccccc8)c7c6)ccc54)nc3)cc2)cc1 ; c1ccc(-c2cccc(-c3ccccc3-c3cnc(-n4c5ccccc5c5cc(-c6ccc7c8ccccc8n(-c8ccccc8)c7c6)ccc54)nc3)c2)cc1]

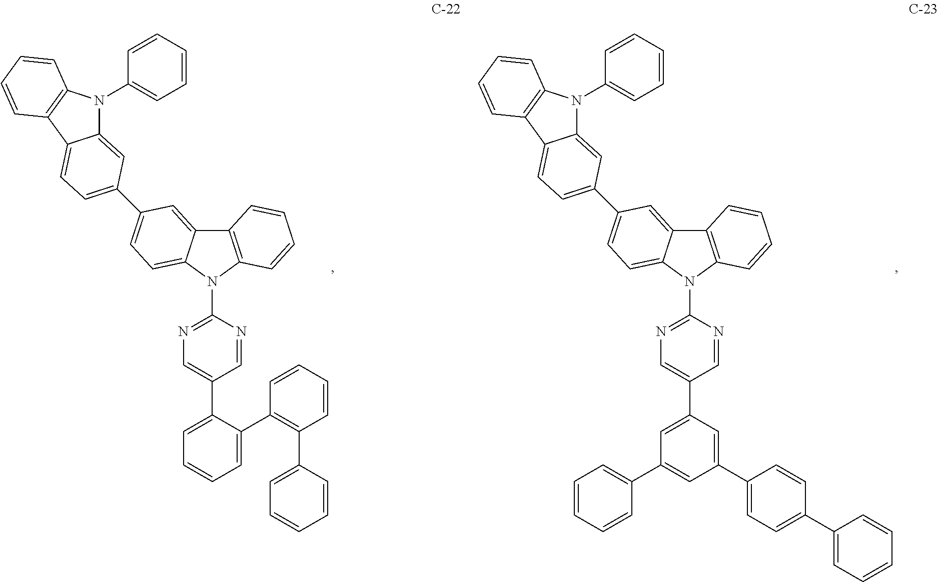 [SMILES: c1ccc(-c2ccccc2-c2ccccc2-c2cnc(-n3c4ccccc4c4cc(-c5ccc6c7ccccc7n(-c7ccccc7)c6c5)ccc43)nc2)cc1 ; c1ccc(-c2ccc(-c3cc(-c4ccccc4)cc(-c4cnc(-n5c6ccccc6c6cc(-c7ccc8c9ccccc9n(-c9ccccc9)c8c7)ccc65)nc4)c3)cc2)cc1]

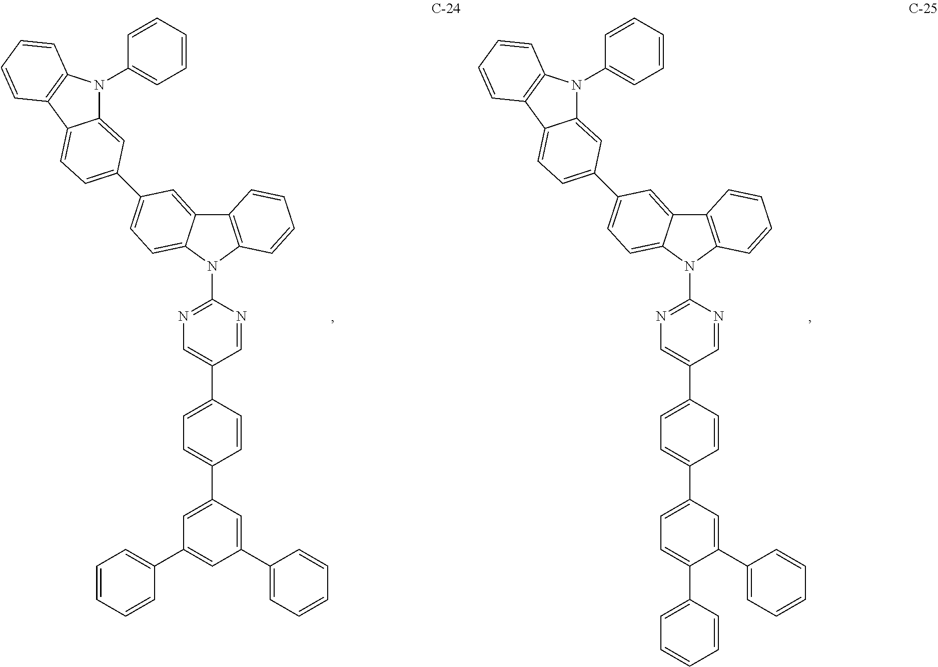 [SMILES: c1ccc(-c2cc(-c3ccccc3)cc(-c3ccc(-c4cnc(-n5c6ccccc6c6cc(-c7ccc8c9ccccc9n(-c9ccccc9)c8c7)ccc65)nc4)cc3)c2)cc1 ; c1ccc(-c2ccc(-c3ccc(-c4cnc(-n5c6ccccc6c6cc(-c7ccc8c9ccccc9n(-c9ccccc9)c8c7)ccc65)nc4)cc3)cc2-c2ccccc2)cc1]

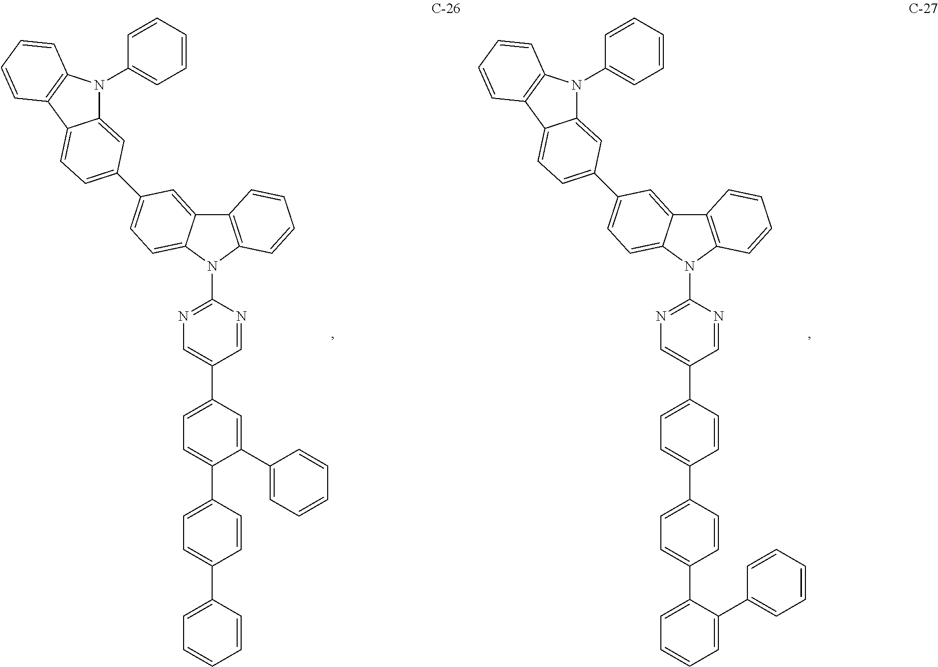 [SMILES: c1ccc(-c2ccc(-c3ccc(-c4cnc(-n5c6ccccc6c6cc(-c7ccc8c9ccccc9n(-c9ccccc9)c8c7)ccc65)nc4)cc3-c3ccccc3)cc2)cc1 ; c1ccc(-c2ccccc2-c2ccc(-c3ccc(-c4cnc(-n5c6ccccc6c6cc(-c7ccc8c9ccccc9n(-c9ccccc9)c8c7)ccc65)nc4)cc3)cc2)cc1]

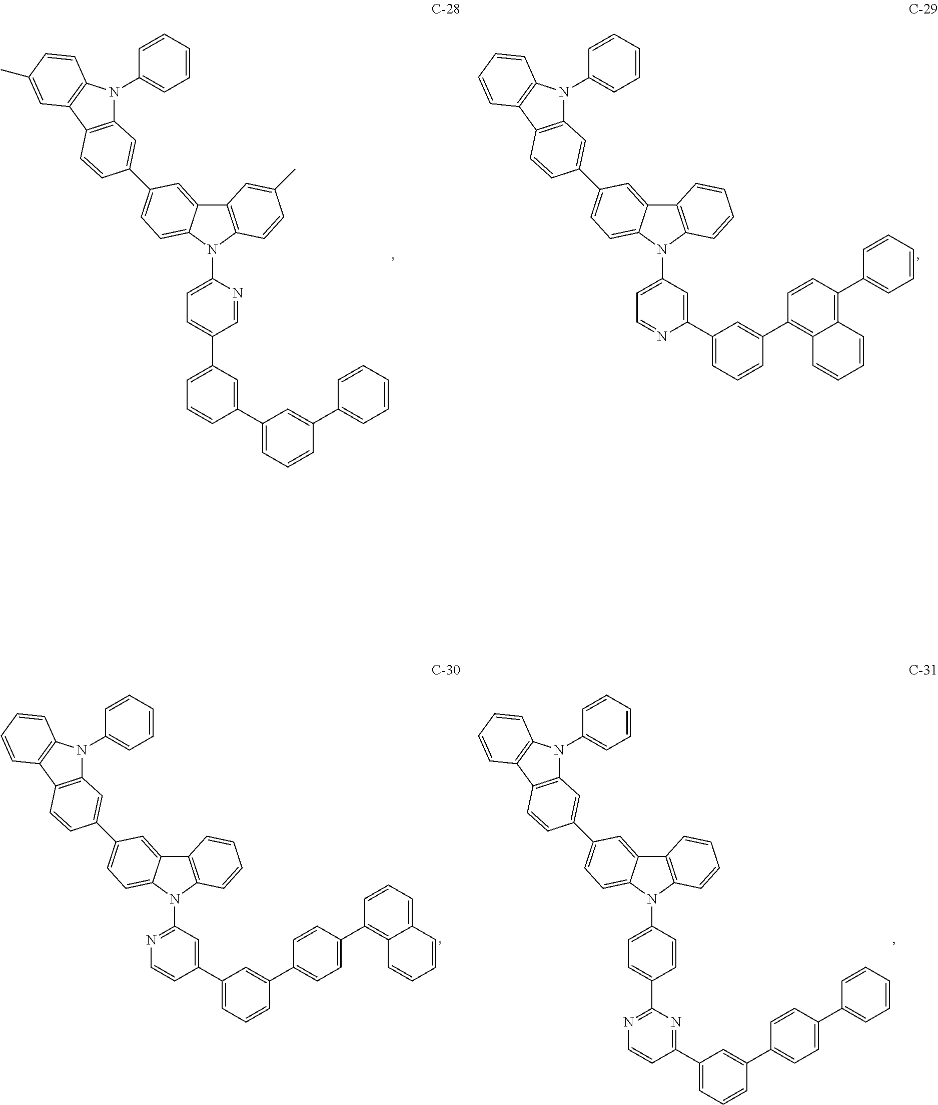 [SMILES: Cc1ccc2c(c1)c1ccc(-c3ccc4c(c3)c3cc(C)ccc3n4-c3ccc(-c4cccc(-c5cccc(-c6ccccc6)c5)c4)cn3)cc1n2-c1ccccc1 ; c1ccc(-c2ccc(-c3cccc(-c4cc(-n5c6ccccc6c6cc(-c7ccc8c9ccccc9n(-c9ccccc9)c8c7)ccc65)ccn4)c3)c3ccccc23)cc1 ; c1ccc(-n2c3ccccc3c3ccc(-c4ccc5c(c4)c4ccccc4n5-c4cc(-c5cccc(-c6ccc(-c7cccc8ccccc78)cc6)c5)ccn4)cc32)cc1 ; c1ccc(-c2ccc(-c3cccc(-c4ccnc(-c5ccc(-n6c7ccccc7c7cc(-c8ccc9c%10ccccc%10n(-c%10ccccc%10)c9c8)ccc76)cc5)n4)c3)cc2)cc1]

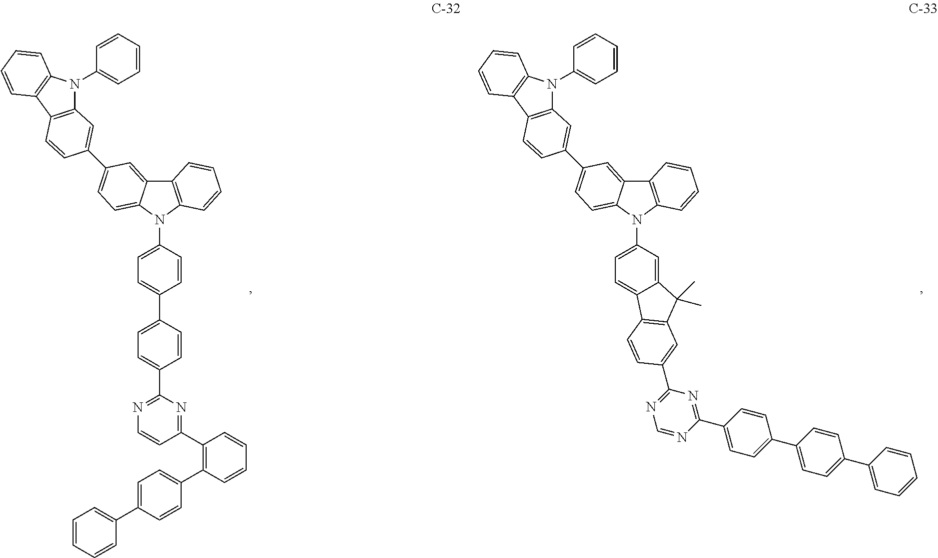 [SMILES: c1ccc(-c2ccc(-c3ccccc3-c3ccnc(-c4ccc(-c5ccc(-n6c7ccccc7c7cc(-c8ccc9c%10ccccc%10n(-c%10ccccc%10)c9c8)ccc76)cc5)cc4)n3)cc2)cc1 ; CC1(C)c2cc(-c3ncnc(-c4ccc(-c5ccc(-c6ccccc6)cc5)cc4)n3)ccc2-c2ccc(-n3c4ccccc4c4cc(-c5ccc6c7ccccc7n(-c7ccccc7)c6c5)ccc43)cc21]

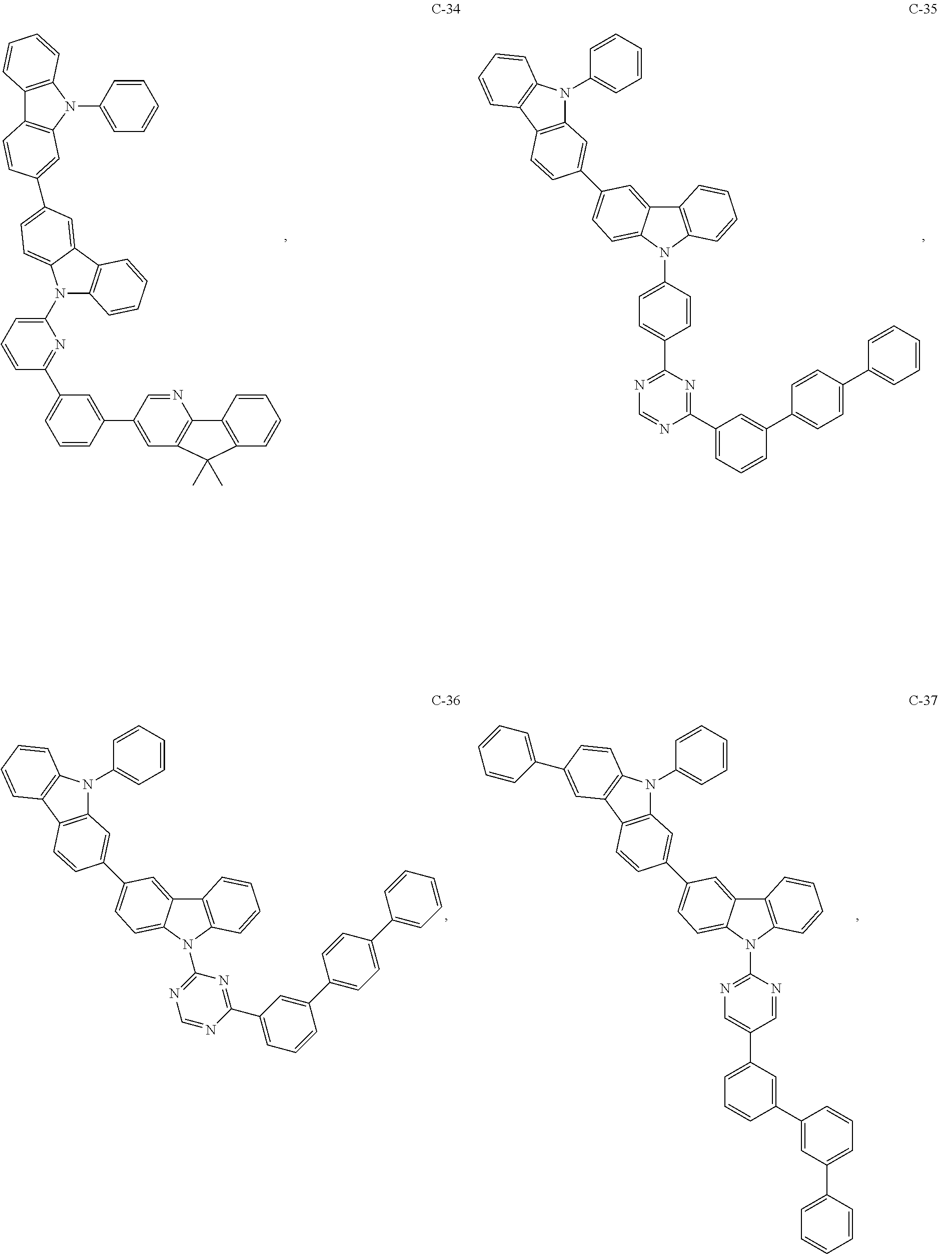 [SMILES: CC1(C)c2ccccc2-c2ncc(-c3cccc(-c4cccc(-n5c6ccccc6c6cc(-c7ccc8c9ccccc9n(-c9ccccc9)c8c7)ccc65)n4)c3)cc21 ; c1ccc(-c2ccc(-c3cccc(-c4ncnc(-c5ccc(-n6c7ccccc7c7cc(-c8ccc9c%10ccccc%10n(-c%10ccccc%10)c9c8)ccc76)cc5)n4)c3)cc2)cc1 ; c1ccc(-c2ccc(-c3cccc(-c4ncnc(-n5c6ccccc6c6cc(-c7ccc8c9ccccc9n(-c9ccccc9)c8c7)ccc65)n4)c3)cc2)cc1 ; c1ccc(-c2cccc(-c3cccc(-c4cnc(-n5c6ccccc6c6cc(-c7ccc8c9cc(-c%10ccccc%10)ccc9n(-c9ccccc9)c8c7)ccc65)nc4)c3)c2)cc1]

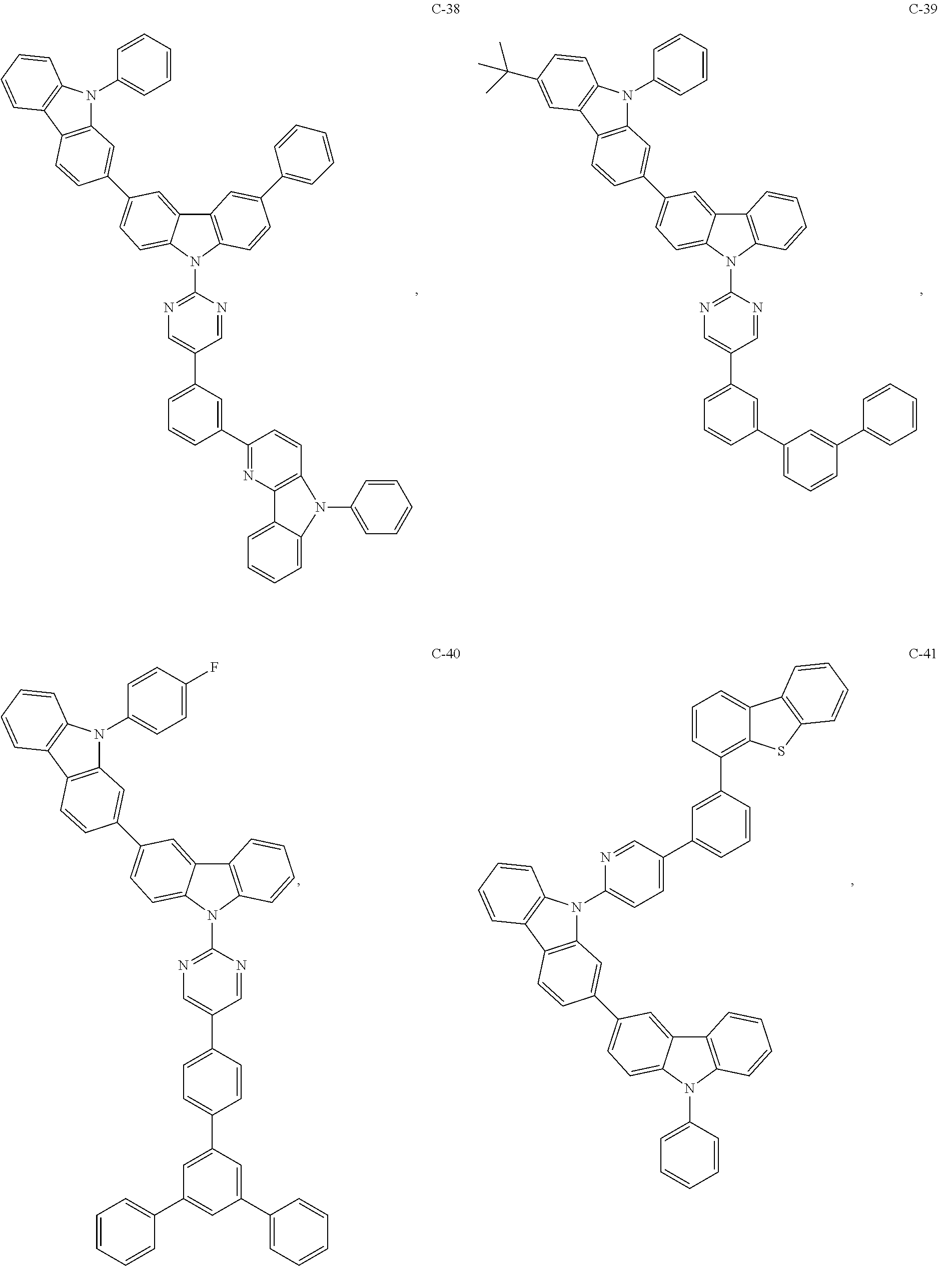 [SMILES: c1ccc(-c2ccc3c(c2)c2cc(-c4ccc5c6ccccc6n(-c6ccccc6)c5c4)ccc2n3-c2ncc(-c3cccc(-c4ccc5c(n4)c4ccccc4n5-c4ccccc4)c3)cn2)cc1 ; CC(C)(C)c1ccc2c(c1)c1ccc(-c3ccc4c(c3)c3ccccc3n4-c3ncc(-c4cccc(-c5cccc(-c6ccccc6)c5)c4)cn3)cc1n2-c1ccccc1 ; Fc1ccc(-n2c3ccccc3c3ccc(-c4ccc5c(c4)c4ccccc4n5-c4ncc(-c5ccc(-c6cc(-c7ccccc7)cc(-c7ccccc7)c6)cc5)cn4)cc32)cc1 ; c1ccc(-n2c3ccccc3c3cc(-c4ccc5c6ccccc6n(-c6ccc(-c7cccc(-c8cccc9c8sc8ccccc89)c7)cn6)c5c4)ccc32)cc1]

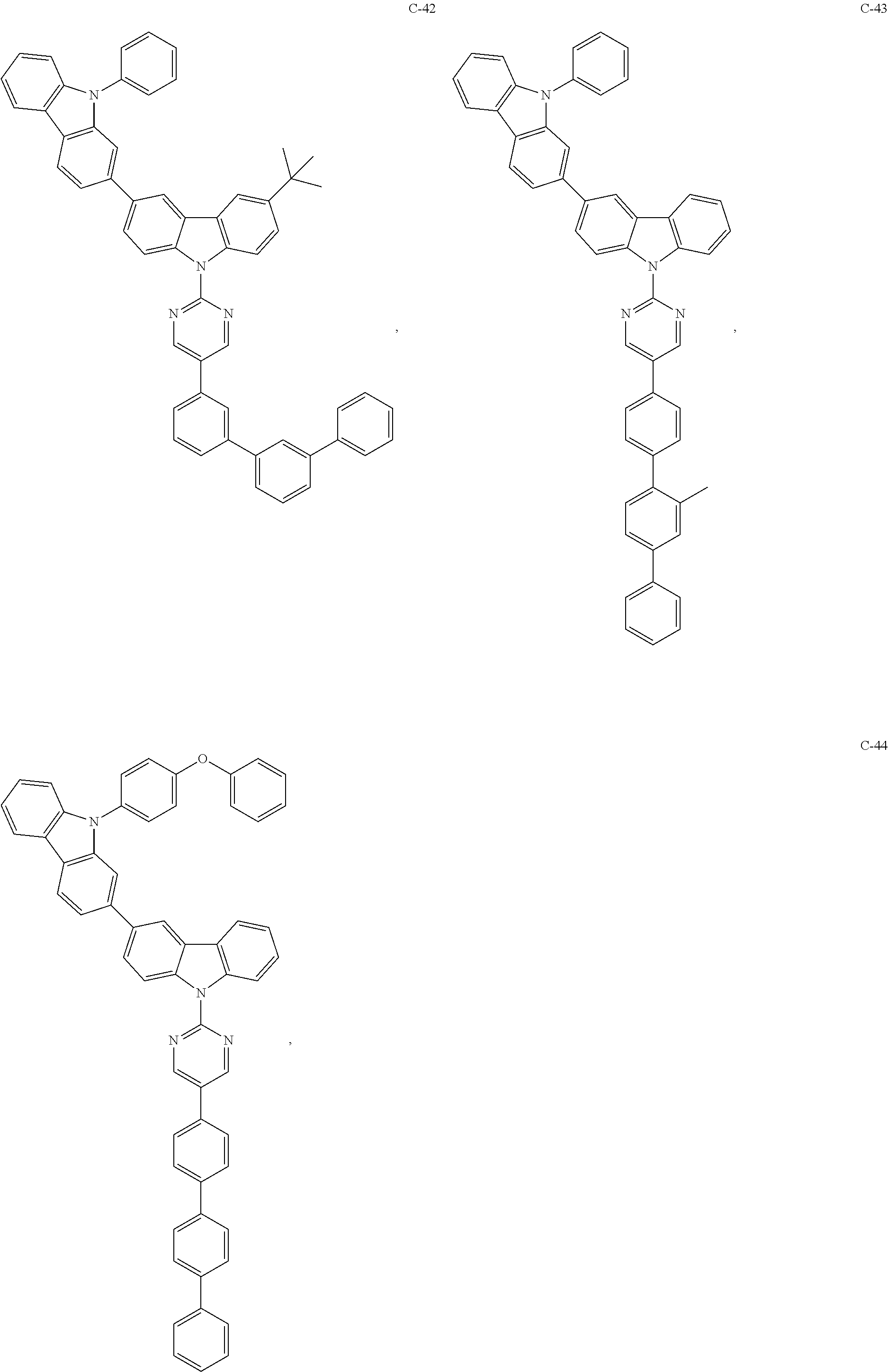 [SMILES: CC(C)(C)c1ccc2c(c1)c1cc(-c3ccc4c5ccccc5n(-c5ccccc5)c4c3)ccc1n2-c1ncc(-c2cccc(-c3cccc(-c4ccccc4)c3)c2)cn1 ; Cc1cc(-c2ccccc2)ccc1-c1ccc(-c2cnc(-n3c4ccccc4c4cc(-c5ccc6c7ccccc7n(-c7ccccc7)c6c5)ccc43)nc2)cc1 ; c1ccc(Oc2ccc(-n3c4ccccc4c4ccc(-c5ccc6c(c5)c5ccccc5n6-c5ncc(-c6ccc(-c7ccc(-c8ccccc8)cc7)cc6)cn5)cc43)cc2)cc1]

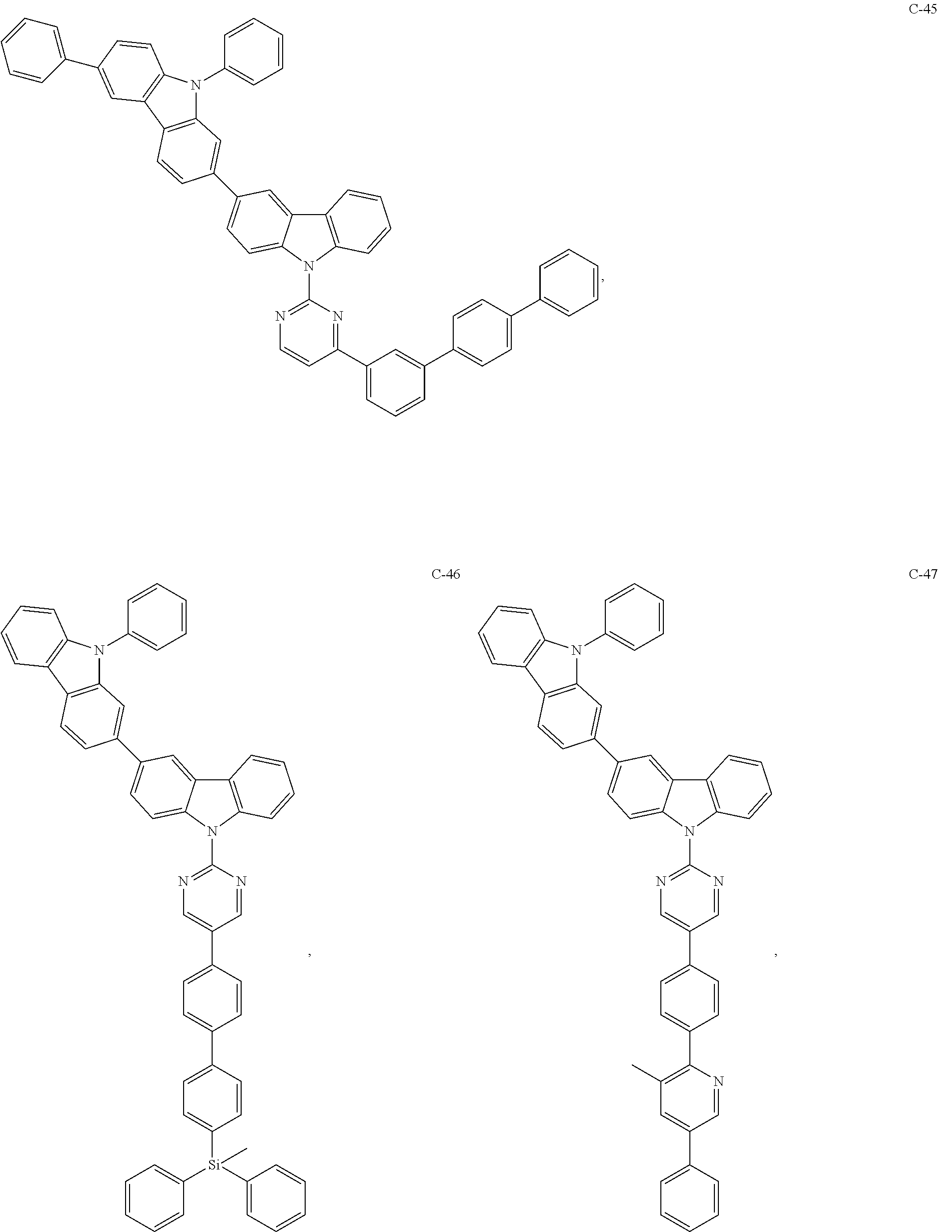 [SMILES: c1ccc(-c2ccc(-c3cccc(-c4ccnc(-n5c6ccccc6c6cc(-c7ccc8c9cc(-c%10ccccc%10)ccc9n(-c9ccccc9)c8c7)ccc65)n4)c3)cc2)cc1 ; C[Si](c1ccccc1)(c1ccccc1)c1ccc(-c2ccc(-c3cnc(-n4c5ccccc5c5cc(-c6ccc7c8ccccc8n(-c8ccccc8)c7c6)ccc54)nc3)cc2)cc1 ; Cc1cc(-c2ccccc2)cnc1-c1ccc(-c2cnc(-n3c4ccccc4c4cc(-c5ccc6c7ccccc7n(-c7ccccc7)c6c5)ccc43)nc2)cc1]

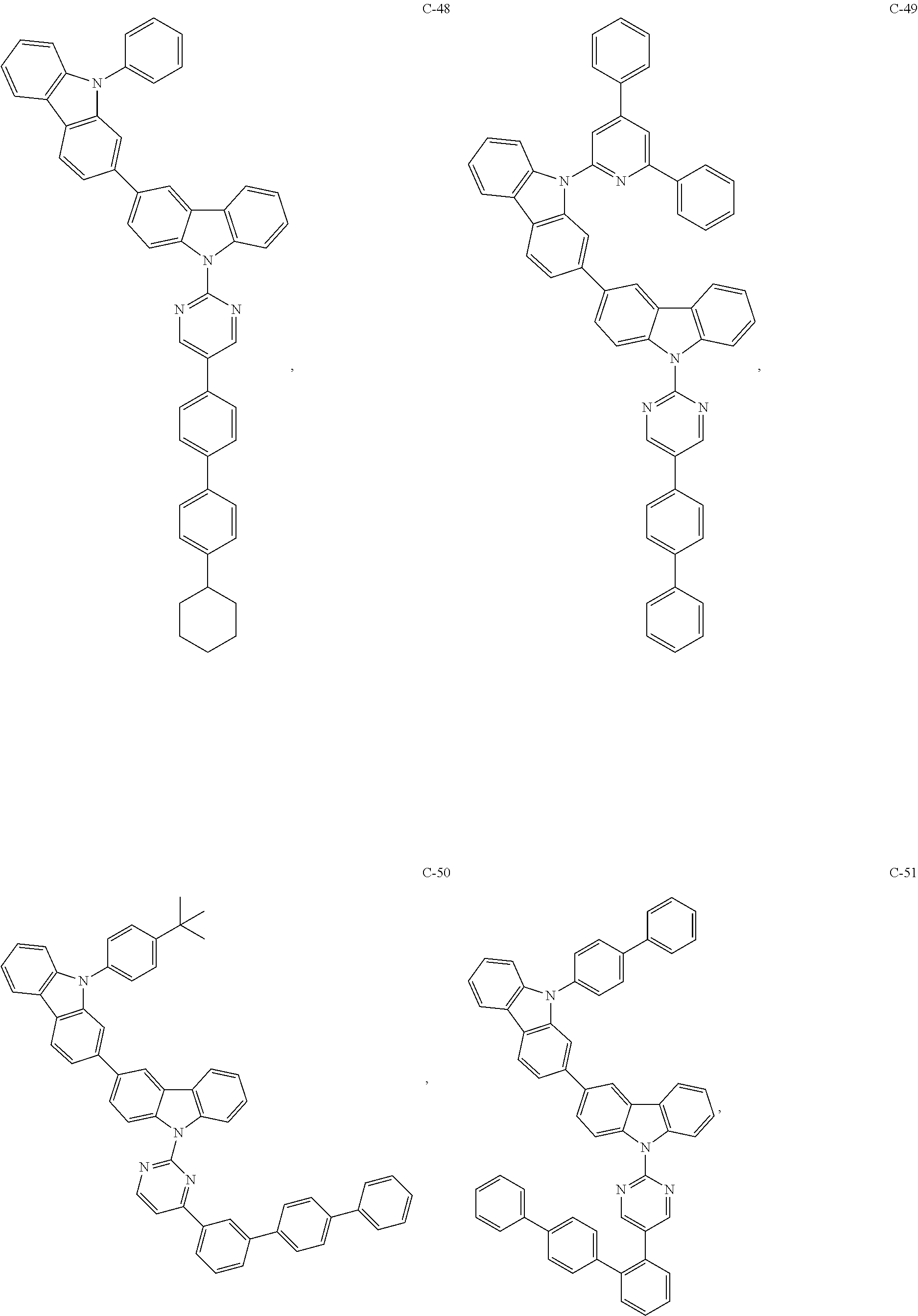 [SMILES: c1ccc(-n2c3ccccc3c3ccc(-c4ccc5c(c4)c4ccccc4n5-c4ncc(-c5ccc(-c6ccc(C7CCCCC7)cc6)cc5)cn4)cc32)cc1 ; c1ccc(-c2ccc(-c3cnc(-n4c5ccccc5c5cc(-c6ccc7c8ccccc8n(-c8cc(-c9ccccc9)cc(-c9ccccc9)n8)c7c6)ccc54)nc3)cc2)cc1 ; CC(C)(C)c1ccc(-n2c3ccccc3c3ccc(-c4ccc5c(c4)c4ccccc4n5-c4nccc(-c5cccc(-c6ccc(-c7ccccc7)cc6)c5)n4)cc32)cc1 ; c1ccc(-c2ccc(-c3ccccc3-c3cnc(-n4c5ccccc5c5cc(-c6ccc7c8ccccc8n(-c8ccc(-c9ccccc9)cc8)c7c6)ccc54)nc3)cc2)cc1]

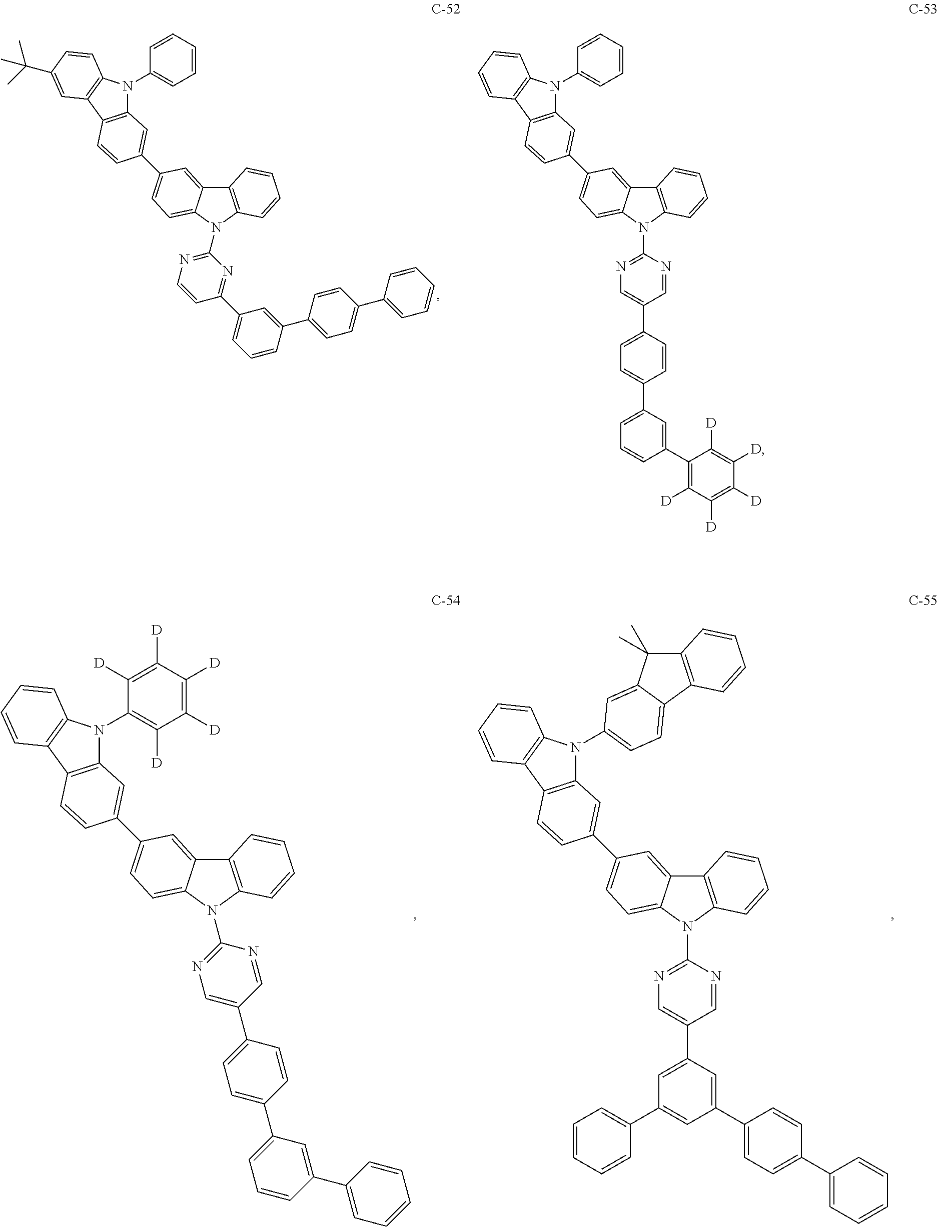

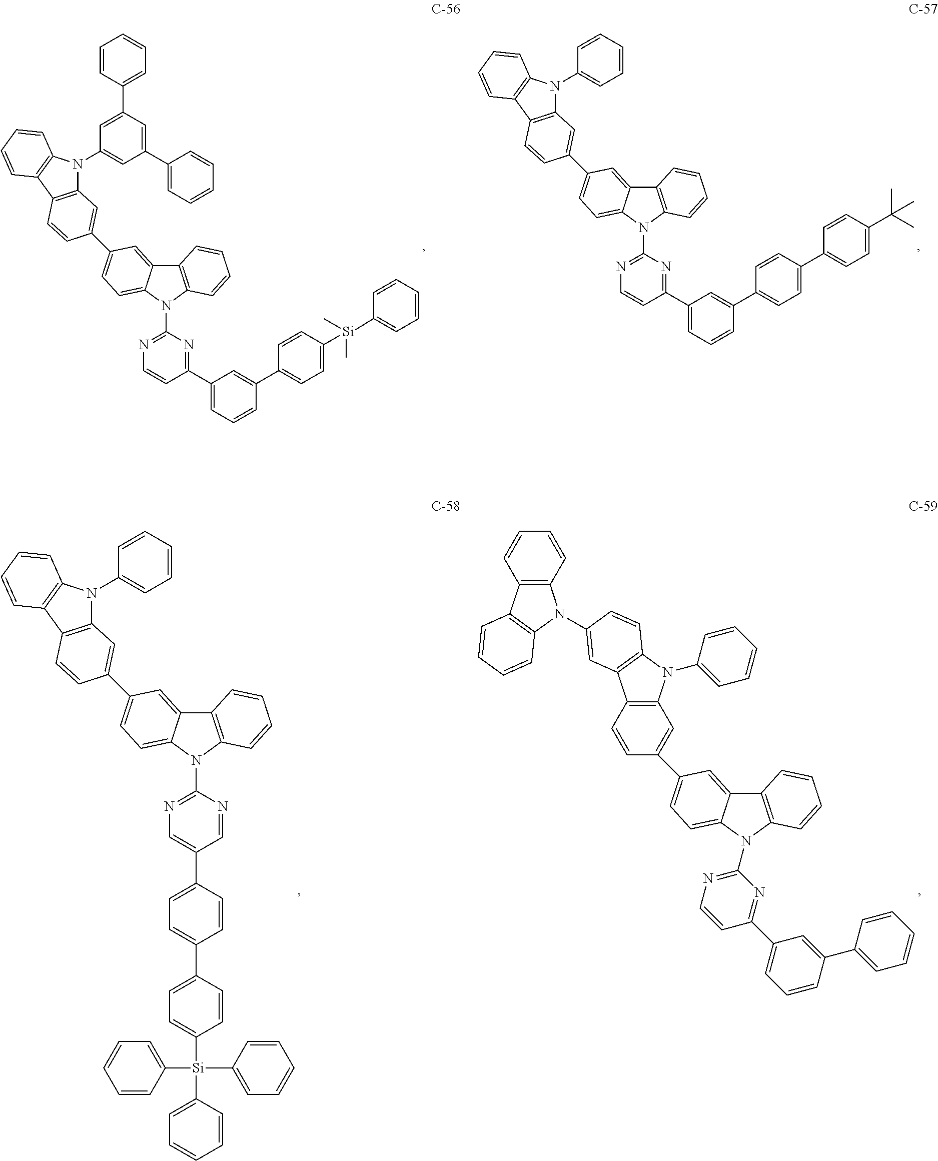 [SMILES: C[Si](C)(c1ccccc1)c1ccc(-c2cccc(-c3ccnc(-n4c5ccccc5c5cc(-c6ccc7c8ccccc8n(-c8cc(-c9ccccc9)cc(-c9ccccc9)c8)c7c6)ccc54)n3)c2)cc1 ; CC(C)(C)c1ccc(-c2ccc(-c3cccc(-c4ccnc(-n5c6ccccc6c6cc(-c7ccc8c9ccccc9n(-c9ccccc9)c8c7)ccc65)n4)c3)cc2)cc1 ; c1ccc(-n2c3ccccc3c3ccc(-c4ccc5c(c4)c4ccccc4n5-c4ncc(-c5ccc(-c6ccc([Si](c7ccccc7)(c7ccccc7)c7ccccc7)cc6)cc5)cn4)cc32)cc1 ; c1ccc(-c2cccc(-c3ccnc(-n4c5ccccc5c5cc(-c6ccc7c8cc(-n9c%10ccccc%10c%10ccccc%109)ccc8n(-c8ccccc8)c7c6)ccc54)n3)c2)cc1]

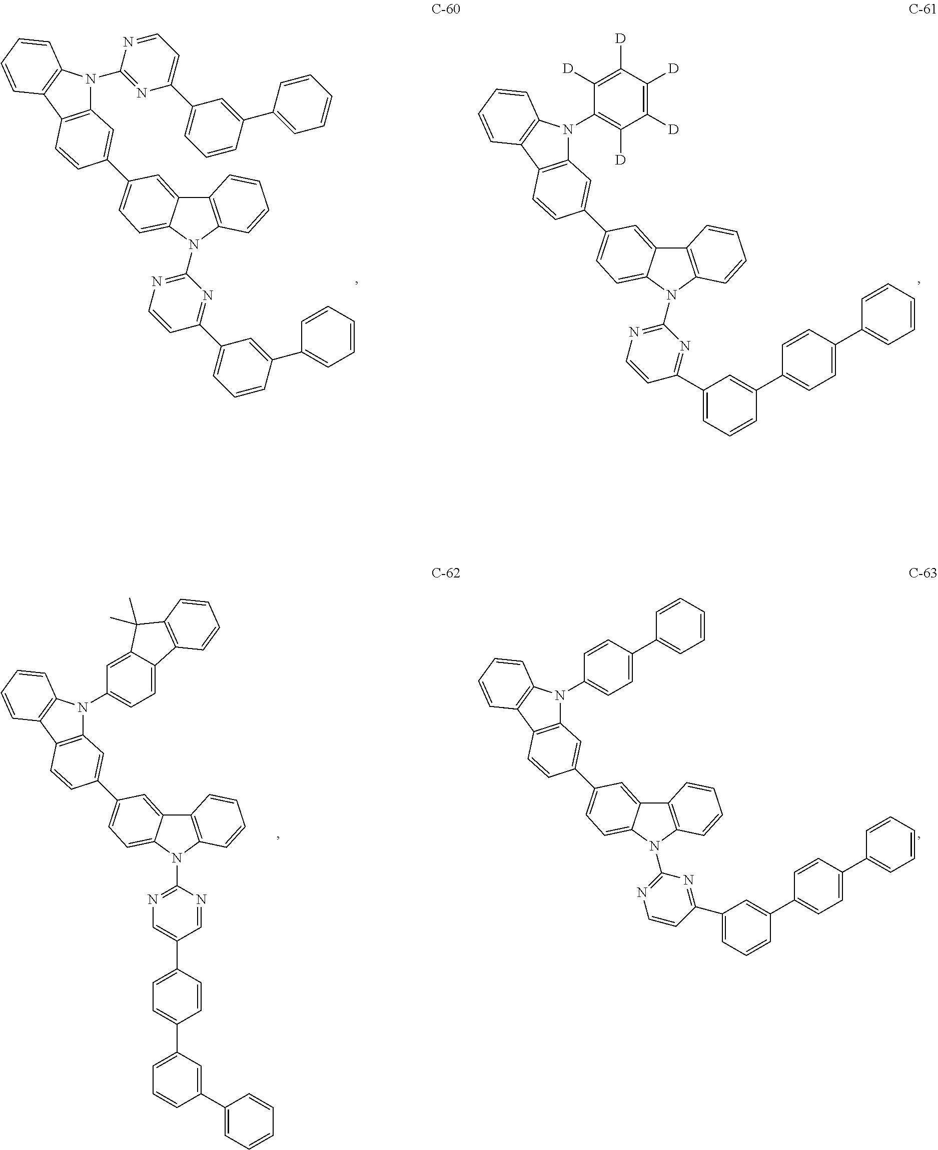 [SMILES: c1ccc(-c2cccc(-c3ccnc(-n4c5ccccc5c5cc(-c6ccc7c8ccccc8n(-c8nccc(-c9cccc(-c%10ccccc%10)c9)n8)c7c6)ccc54)n3)c2)cc1 ; [2H]c1c([2H])c([2H])c(-n2c3ccccc3c3ccc(-c4ccc5c(c4)c4ccccc4n5-c4nccc(-c5cccc(-c6ccc(-c7ccccc7)cc6)c5)n4)cc32)c([2H])c1[2H] ; CC1(C)c2ccccc2-c2ccc(-n3c4ccccc4c4ccc(-c5ccc6c(c5)c5ccccc5n6-c5ncc(-c6ccc(-c7cccc(-c8ccccc8)c7)cc6)cn5)cc43)cc21 ; c1ccc(-c2ccc(-c3cccc(-c4ccnc(-n5c6ccccc6c6cc(-c7ccc8c9ccccc9n(-c9ccc(-c%10ccccc%10)cc9)c8c7)ccc65)n4)c3)cc2)cc1]

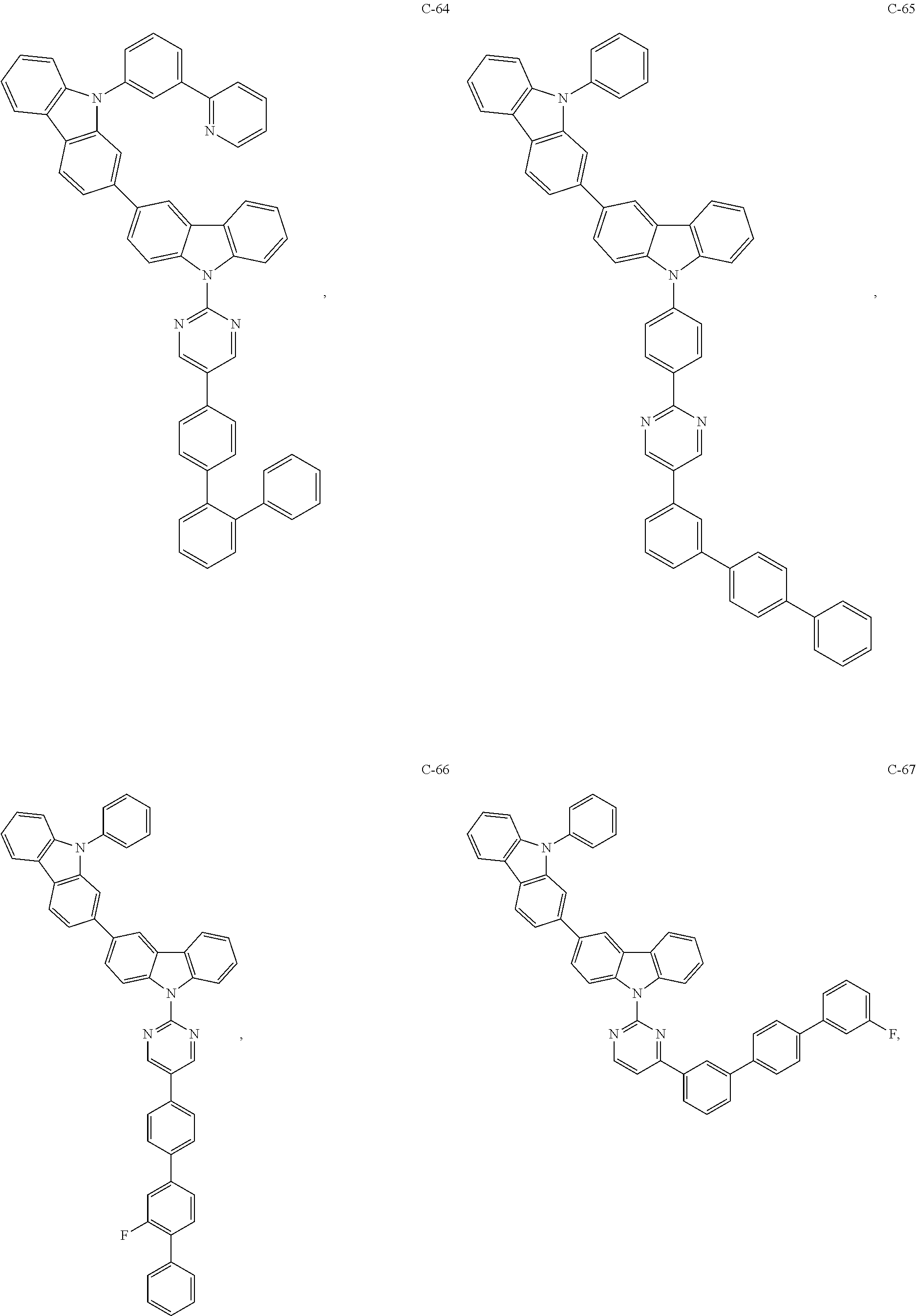 [SMILES: c1ccc(-c2ccccc2-c2ccc(-c3cnc(-n4c5ccccc5c5cc(-c6ccc7c8ccccc8n(-c8cccc(-c9ccccn9)c8)c7c6)ccc54)nc3)cc2)cc1 ; c1ccc(-c2ccc(-c3cccc(-c4cnc(-c5ccc(-n6c7ccccc7c7cc(-c8ccc9c%10ccccc%10n(-c%10ccccc%10)c9c8)ccc76)cc5)nc4)c3)cc2)cc1 ; Fc1cc(-c2ccc(-c3cnc(-n4c5ccccc5c5cc(-c6ccc7c8ccccc8n(-c8ccccc8)c7c6)ccc54)nc3)cc2)ccc1-c1ccccc1 ; Fc1cccc(-c2ccc(-c3cccc(-c4ccnc(-n5c6ccccc6c6cc(-c7ccc8c9ccccc9n(-c9ccccc9)c8c7)ccc65)n4)c3)cc2)c1]

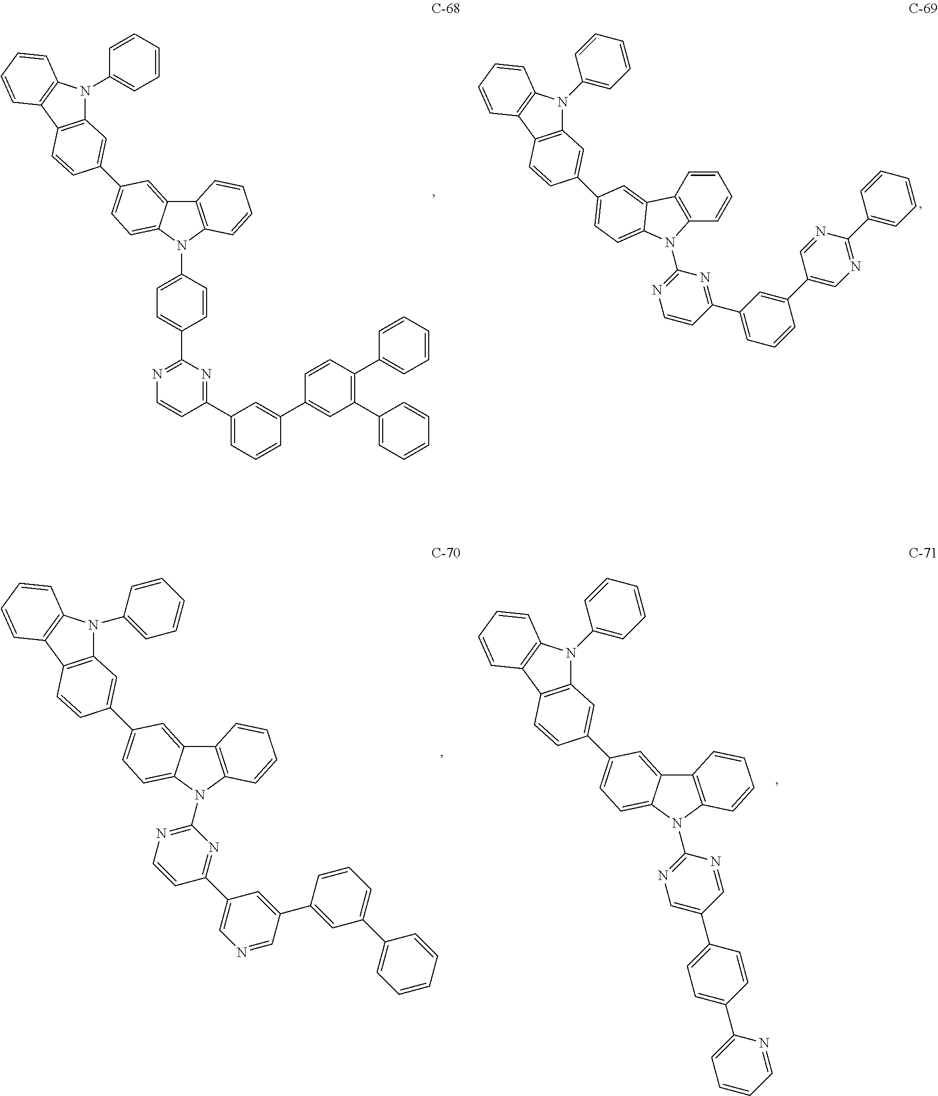 [SMILES: c1ccc(-c2ccc(-c3cccc(-c4ccnc(-c5ccc(-n6c7ccccc7c7cc(-c8ccc9c%10ccccc%10n(-c%10ccccc%10)c9c8)ccc76)cc5)n4)c3)cc2-c2ccccc2)cc1 ; c1ccc(-c2ncc(-c3cccc(-c4ccnc(-n5c6ccccc6c6cc(-c7ccc8c9ccccc9n(-c9ccccc9)c8c7)ccc65)n4)c3)cn2)cc1 ; c1ccc(-c2cccc(-c3cncc(-c4ccnc(-n5c6ccccc6c6cc(-c7ccc8c9ccccc9n(-c9ccccc9)c8c7)ccc65)n4)c3)c2)cc1 ; c1ccc(-n2c3ccccc3c3ccc(-c4ccc5c(c4)c4ccccc4n5-c4ncc(-c5ccc(-c6ccccn6)cc5)cn4)cc32)cc1]

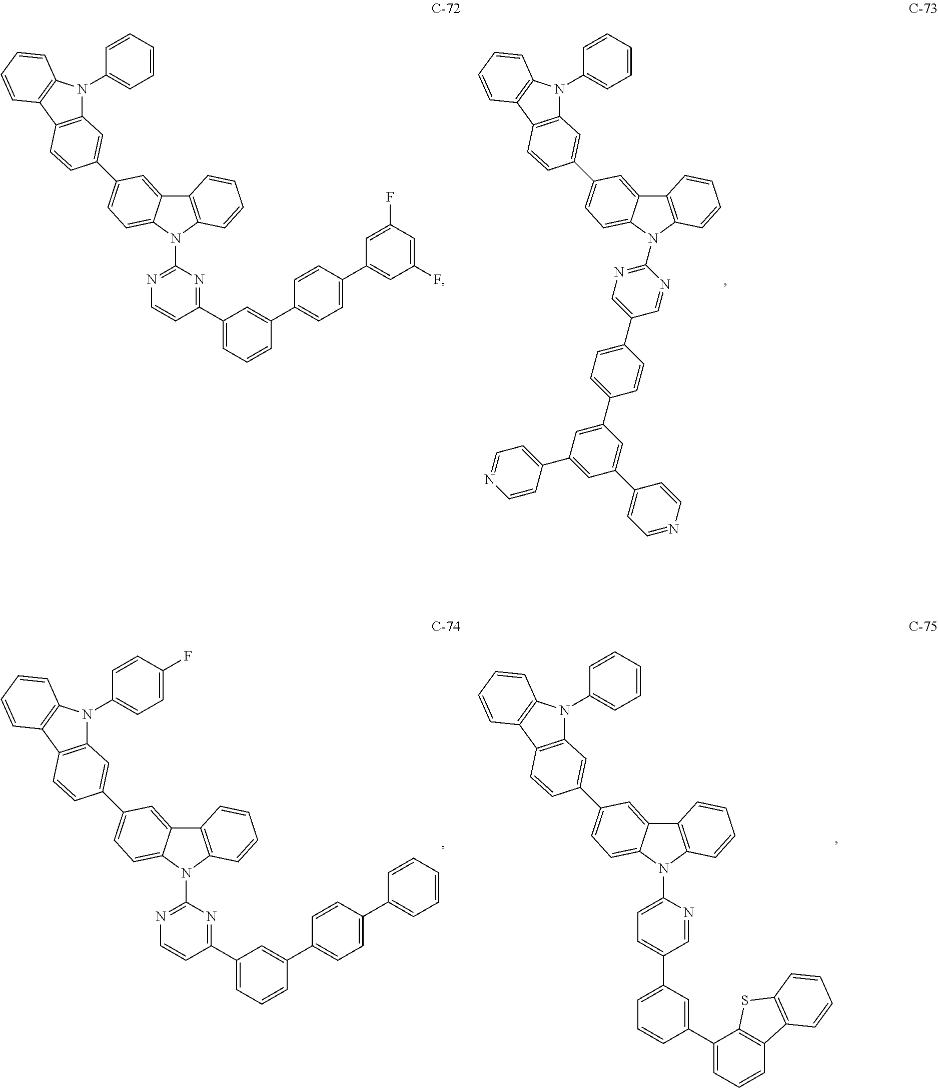 [SMILES: Fc1cc(F)cc(-c2ccc(-c3cccc(-c4ccnc(-n5c6ccccc6c6cc(-c7ccc8c9ccccc9n(-c9ccccc9)c8c7)ccc65)n4)c3)cc2)c1 ; c1ccc(-n2c3ccccc3c3ccc(-c4ccc5c(c4)c4ccccc4n5-c4ncc(-c5ccc(-c6cc(-c7ccncc7)cc(-c7ccncc7)c6)cc5)cn4)cc32)cc1 ; Fc1ccc(-n2c3ccccc3c3ccc(-c4ccc5c(c4)c4ccccc4n5-c4nccc(-c5cccc(-c6ccc(-c7ccccc7)cc6)c5)n4)cc32)cc1 ; c1ccc(-n2c3ccccc3c3ccc(-c4ccc5c(c4)c4ccccc4n5-c4ccc(-c5cccc(-c6cccc7c6sc6ccccc67)c5)cn4)cc32)cc1]

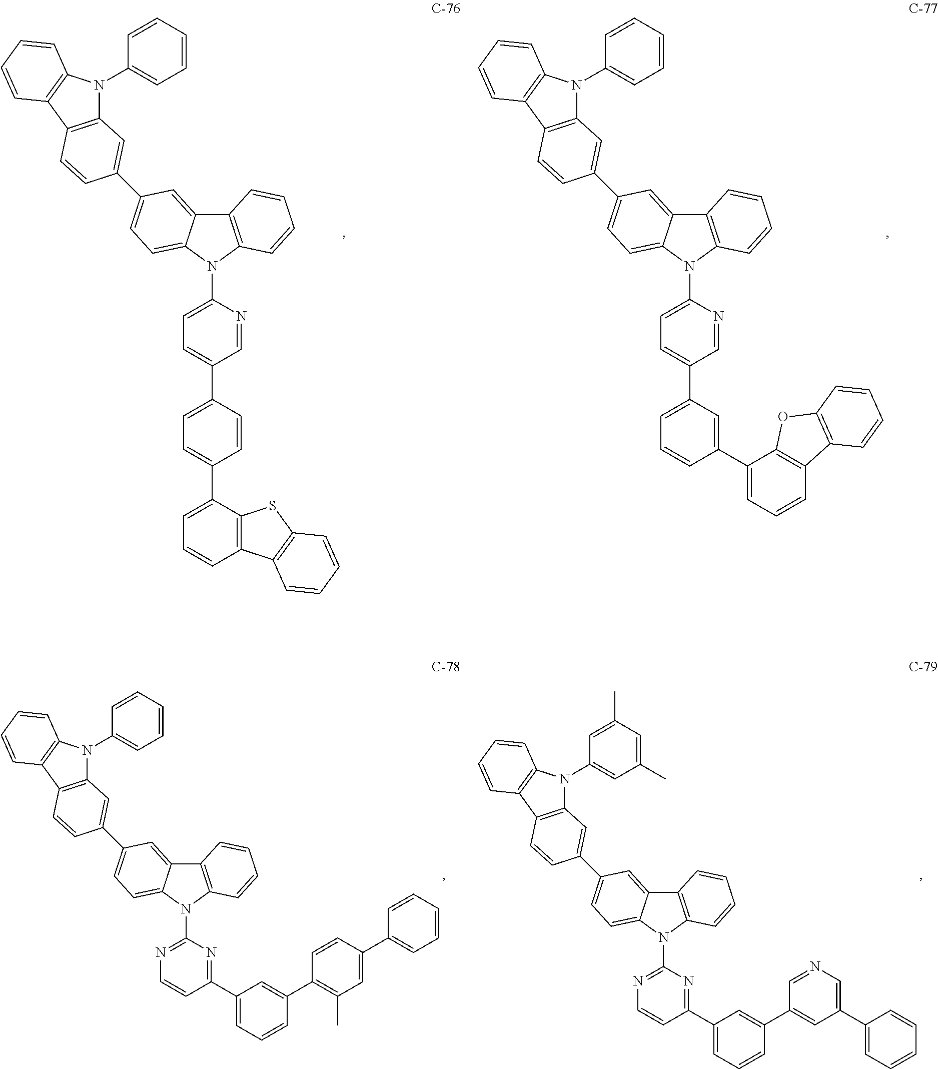 [SMILES: c1ccc(-n2c3ccccc3c3ccc(-c4ccc5c(c4)c4ccccc4n5-c4ccc(-c5ccc(-c6cccc7c6sc6ccccc67)cc5)cn4)cc32)cc1 ; c1ccc(-n2c3ccccc3c3ccc(-c4ccc5c(c4)c4ccccc4n5-c4ccc(-c5cccc(-c6cccc7c6oc6ccccc67)c5)cn4)cc32)cc1 ; Cc1cc(-c2ccccc2)ccc1-c1cccc(-c2ccnc(-n3c4ccccc4c4cc(-c5ccc6c7ccccc7n(-c7ccccc7)c6c5)ccc43)n2)c1 ; Cc1cc(C)cc(-n2c3ccccc3c3ccc(-c4ccc5c(c4)c4ccccc4n5-c4nccc(-c5cccc(-c6cncc(-c7ccccc7)c6)c5)n4)cc32)c1]

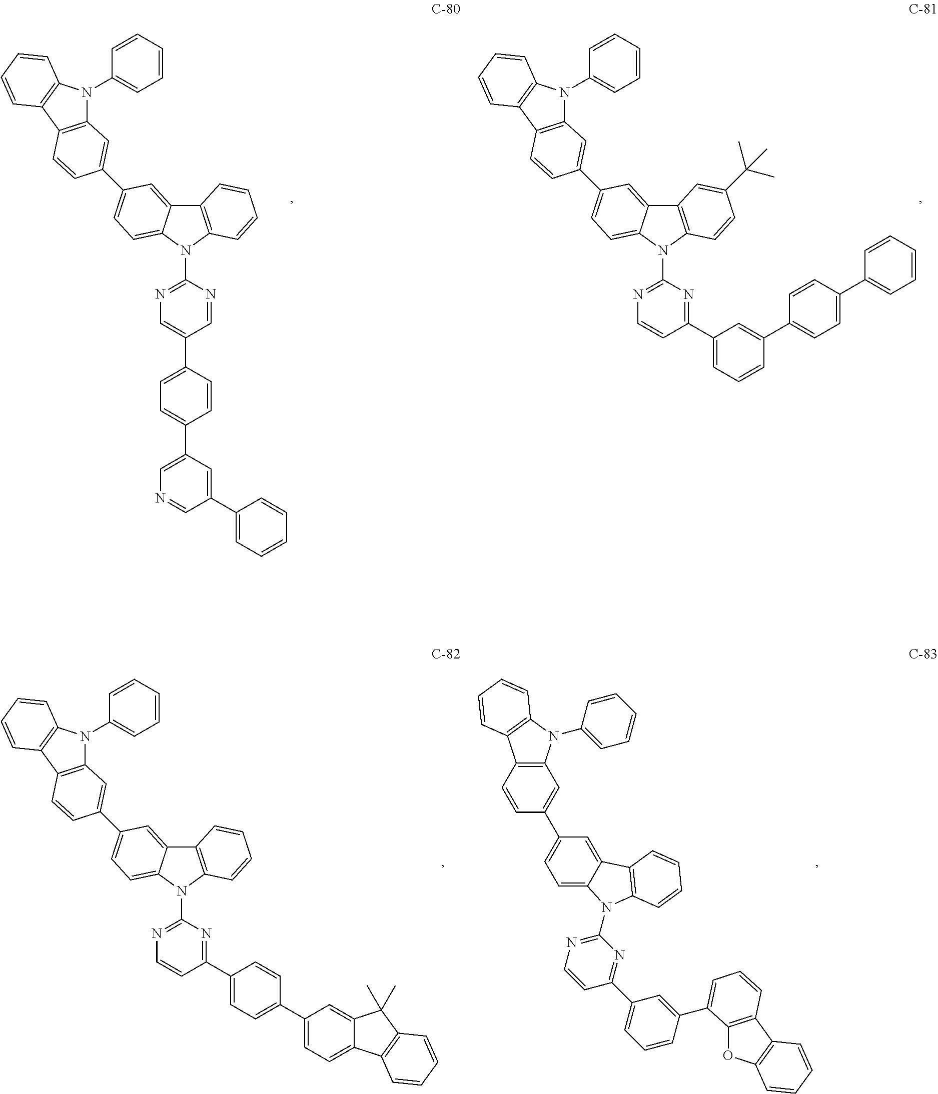 [SMILES: c1ccc(-c2cncc(-c3ccc(-c4cnc(-n5c6ccccc6c6cc(-c7ccc8c9ccccc9n(-c9ccccc9)c8c7)ccc65)nc4)cc3)c2)cc1 ; CC(C)(C)c1ccc2c(c1)c1cc(-c3ccc4c5ccccc5n(-c5ccccc5)c4c3)ccc1n2-c1nccc(-c2cccc(-c3ccc(-c4ccccc4)cc3)c2)n1 ; CC1(C)c2ccccc2-c2ccc(-c3ccc(-c4ccnc(-n5c6ccccc6c6cc(-c7ccc8c9ccccc9n(-c9ccccc9)c8c7)ccc65)n4)cc3)cc21 ; c1ccc(-n2c3ccccc3c3ccc(-c4ccc5c(c4)c4ccccc4n5-c4nccc(-c5cccc(-c6cccc7c6oc6ccccc67)c5)n4)cc32)cc1]

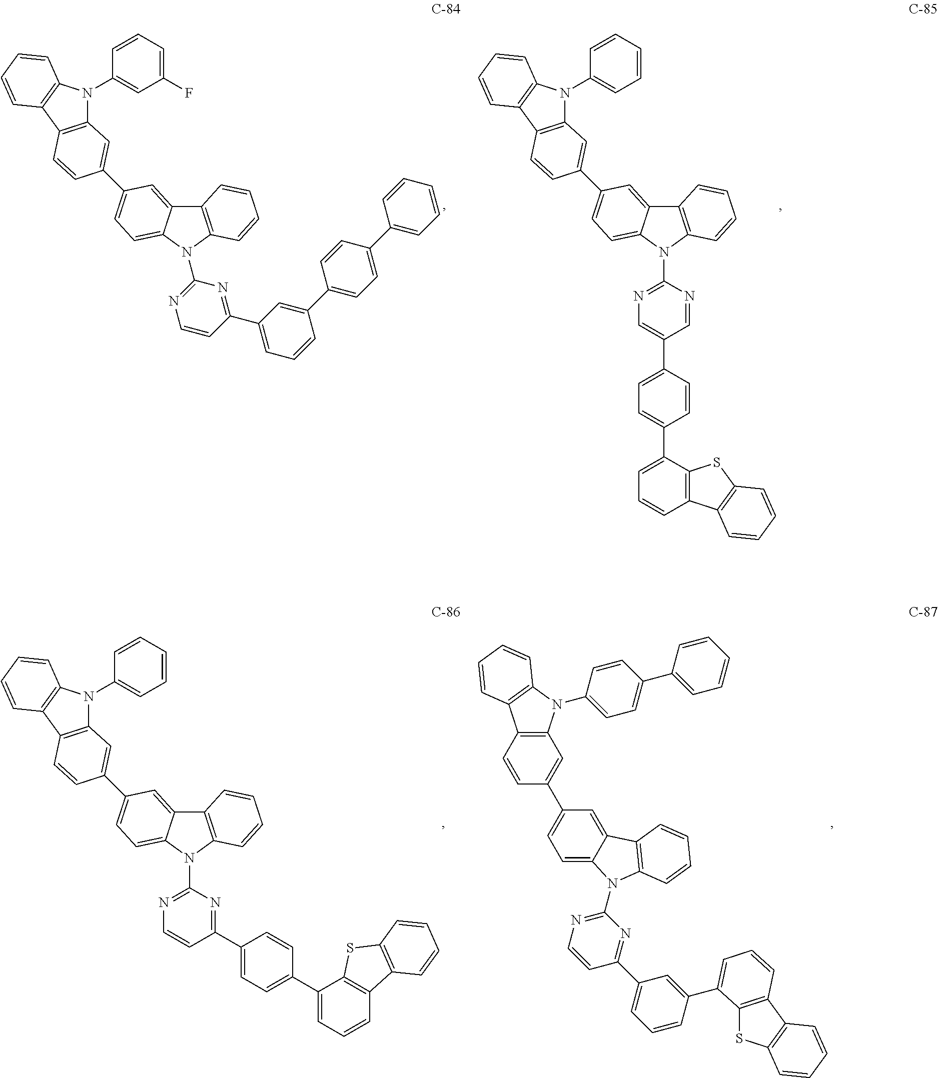 [SMILES: Fc1cccc(-n2c3ccccc3c3ccc(-c4ccc5c(c4)c4ccccc4n5-c4nccc(-c5cccc(-c6ccc(-c7ccccc7)cc6)c5)n4)cc32)c1 ; c1ccc(-n2c3ccccc3c3ccc(-c4ccc5c(c4)c4ccccc4n5-c4ncc(-c5ccc(-c6cccc7c6sc6ccccc67)cc5)cn4)cc32)cc1 ; c1ccc(-n2c3ccccc3c3ccc(-c4ccc5c(c4)c4ccccc4n5-c4nccc(-c5ccc(-c6cccc7c6sc6ccccc67)cc5)n4)cc32)cc1 ; c1ccc(-c2ccc(-n3c4ccccc4c4ccc(-c5ccc6c(c5)c5ccccc5n6-c5nccc(-c6cccc(-c7cccc8c7sc7ccccc78)c6)n5)cc43)cc2)cc1]

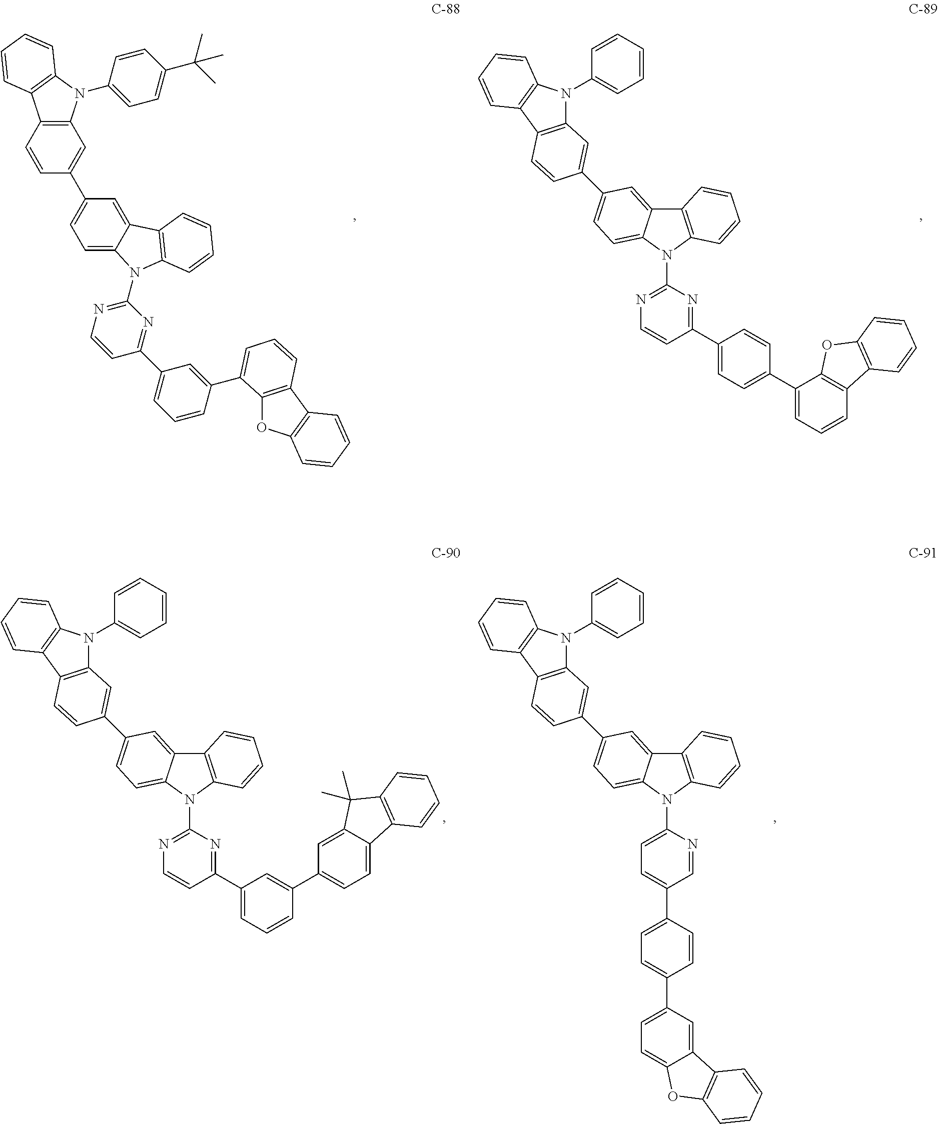 [SMILES: CC(C)(C)c1ccc(-n2c3ccccc3c3ccc(-c4ccc5c(c4)c4ccccc4n5-c4nccc(-c5cccc(-c6cccc7c6oc6ccccc67)c5)n4)cc32)cc1 ; c1ccc(-n2c3ccccc3c3ccc(-c4ccc5c(c4)c4ccccc4n5-c4nccc(-c5ccc(-c6cccc7c6oc6ccccc67)cc5)n4)cc32)cc1 ; CC1(C)c2ccccc2-c2ccc(-c3cccc(-c4ccnc(-n5c6ccccc6c6cc(-c7ccc8c9ccccc9n(-c9ccccc9)c8c7)ccc65)n4)c3)cc21 ; c1ccc(-n2c3ccccc3c3ccc(-c4ccc5c(c4)c4ccccc4n5-c4ccc(-c5ccc(-c6ccc7oc8ccccc8c7c6)cc5)cn4)cc32)cc1]

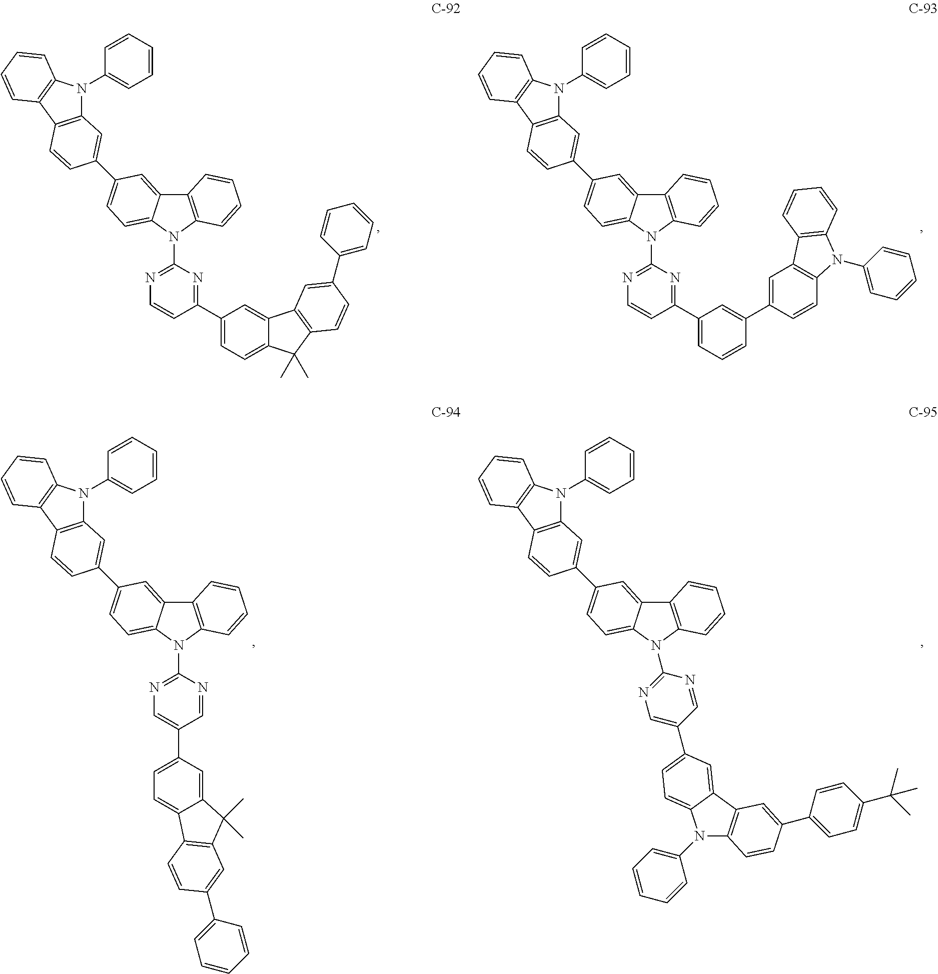 [SMILES: CC1(C)c2ccc(-c3ccccc3)cc2-c2cc(-c3ccnc(-n4c5ccccc5c5cc(-c6ccc7c8ccccc8n(-c8ccccc8)c7c6)ccc54)n3)ccc21 ; c1ccc(-n2c3ccccc3c3cc(-c4cccc(-c5ccnc(-n6c7ccccc7c7cc(-c8ccc9c%10ccccc%10n(-c%10ccccc%10)c9c8)ccc76)n5)c4)ccc32)cc1 ; CC1(C)c2cc(-c3ccccc3)ccc2-c2ccc(-c3cnc(-n4c5ccccc5c5cc(-c6ccc7c8ccccc8n(-c8ccccc8)c7c6)ccc54)nc3)cc21 ; CC(C)(C)c1ccc(-c2ccc3c(c2)c2cc(-c4cnc(-n5c6ccccc6c6cc(-c7ccc8c9ccccc9n(-c9ccccc9)c8c7)ccc65)nc4)ccc2n3-c2ccccc2)cc1]

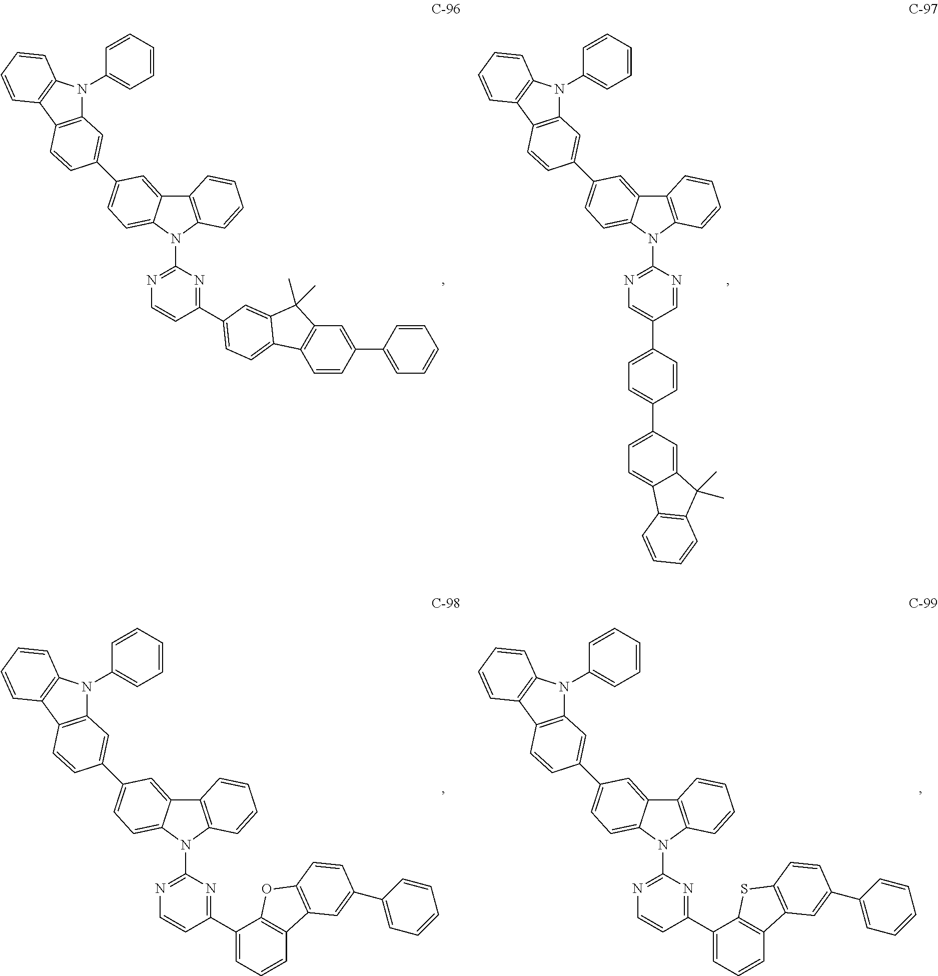 [SMILES: CC1(C)c2cc(-c3ccccc3)ccc2-c2ccc(-c3ccnc(-n4c5ccccc5c5cc(-c6ccc7c8ccccc8n(-c8ccccc8)c7c6)ccc54)n3)cc21 ; CC1(C)c2ccccc2-c2ccc(-c3ccc(-c4cnc(-n5c6ccccc6c6cc(-c7ccc8c9ccccc9n(-c9ccccc9)c8c7)ccc65)nc4)cc3)cc21 ; c1ccc(-c2ccc3oc4c(-c5ccnc(-n6c7ccccc7c7cc(-c8ccc9c%10ccccc%10n(-c%10ccccc%10)c9c8)ccc76)n5)cccc4c3c2)cc1 ; c1ccc(-c2ccc3sc4c(-c5ccnc(-n6c7ccccc7c7cc(-c8ccc9c%10ccccc%10n(-c%10ccccc%10)c9c8)ccc76)n5)cccc4c3c2)cc1]

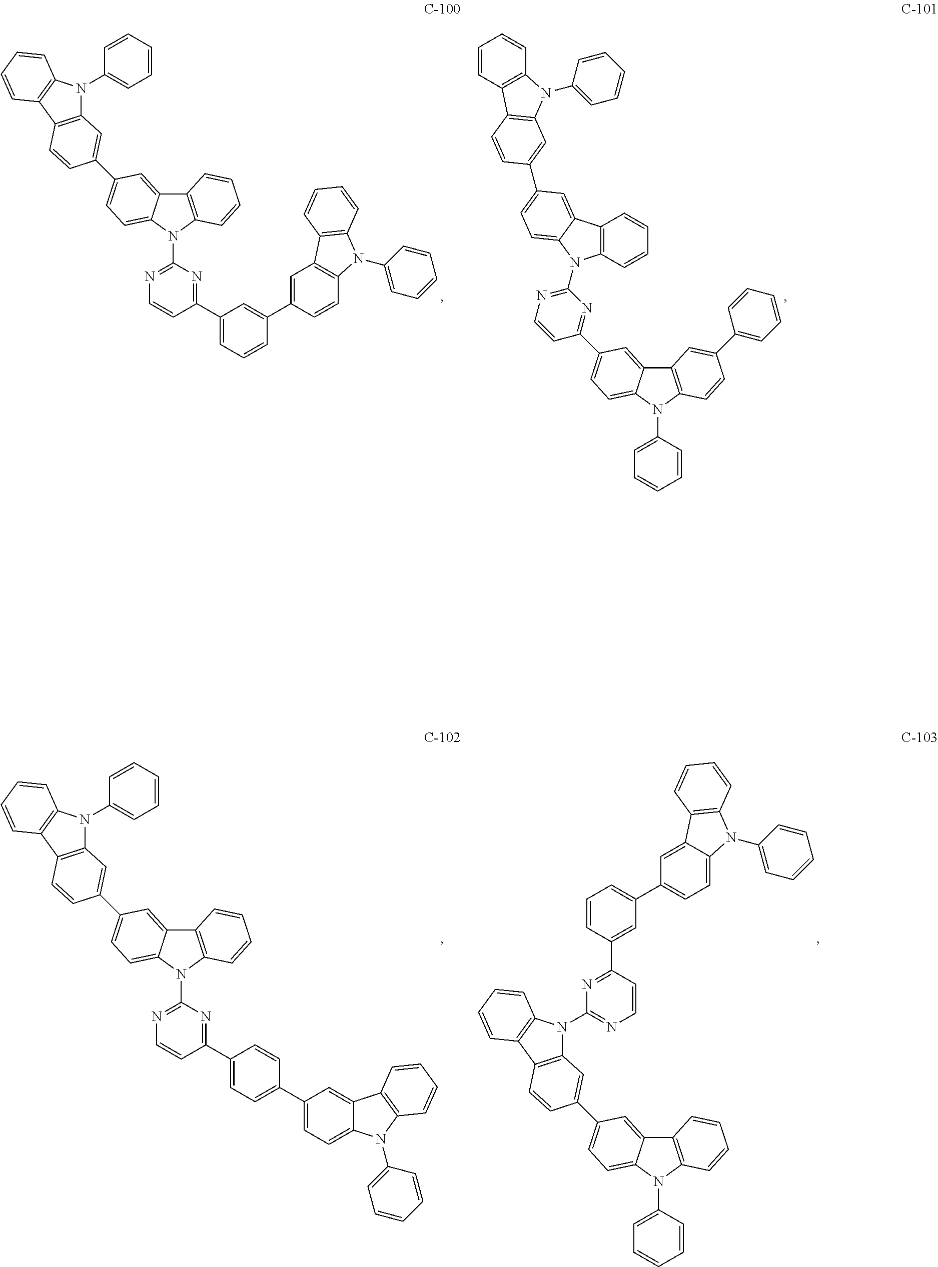 [SMILES: c1ccc(-n2c3ccccc3c3cc(-c4cccc(-c5ccnc(-n6c7ccccc7c7cc(-c8ccc9c%10ccccc%10n(-c%10ccccc%10)c9c8)ccc76)n5)c4)ccc32)cc1 ; c1ccc(-c2ccc3c(c2)c2cc(-c4ccnc(-n5c6ccccc6c6cc(-c7ccc8c9ccccc9n(-c9ccccc9)c8c7)ccc65)n4)ccc2n3-c2ccccc2)cc1 ; c1ccc(-n2c3ccccc3c3cc(-c4ccc(-c5ccnc(-n6c7ccccc7c7cc(-c8ccc9c%10ccccc%10n(-c%10ccccc%10)c9c8)ccc76)n5)cc4)ccc32)cc1 ; c1ccc(-n2c3ccccc3c3cc(-c4cccc(-c5ccnc(-n6c7ccccc7c7ccc(-c8ccc9c(c8)c8ccccc8n9-c8ccccc8)cc76)n5)c4)ccc32)cc1]

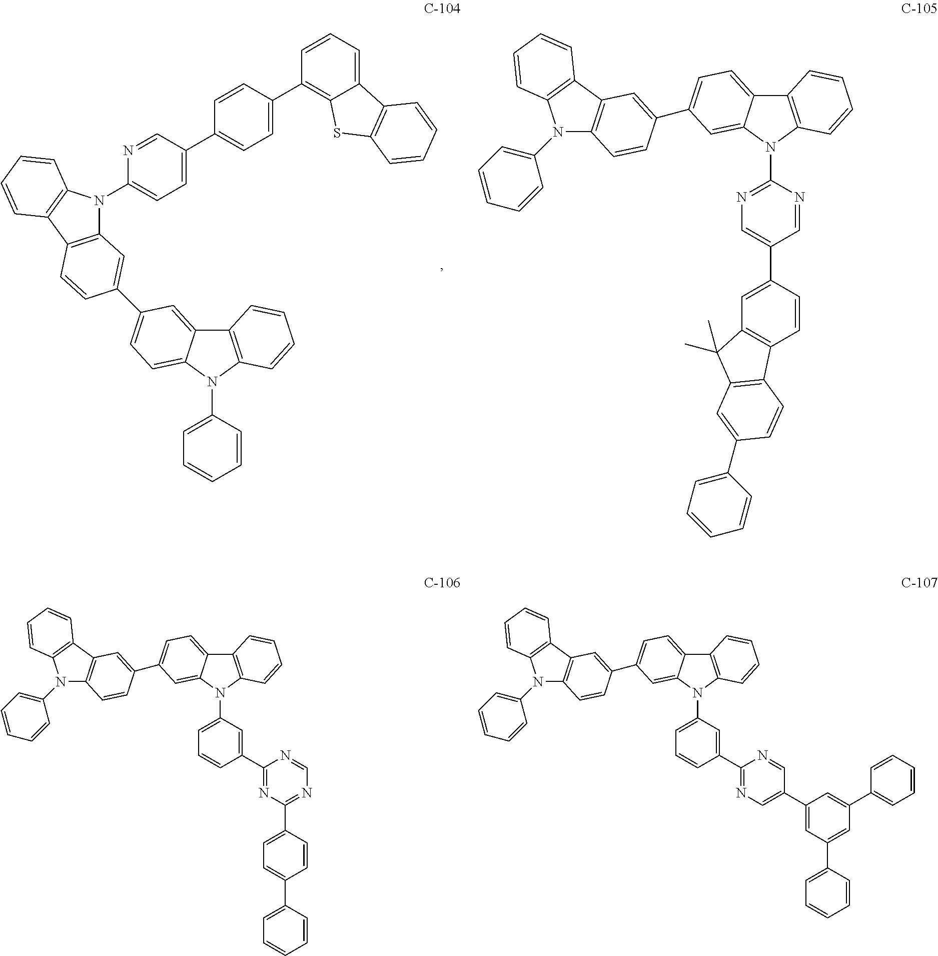 [SMILES: c1ccc(-n2c3ccccc3c3cc(-c4ccc5c6ccccc6n(-c6ccc(-c7ccc(-c8cccc9c8sc8ccccc89)cc7)cn6)c5c4)ccc32)cc1 ; CC1(C)c2cc(-c3ccccc3)ccc2-c2ccc(-c3cnc(-n4c5ccccc5c5ccc(-c6ccc7c(c6)c6ccccc6n7-c6ccccc6)cc54)nc3)cc21 ; c1ccc(-c2ccc(-c3ncnc(-c4cccc(-n5c6ccccc6c6ccc(-c7ccc8c(c7)c7ccccc7n8-c7ccccc7)cc65)c4)n3)cc2)cc1 ; c1ccc(-c2cc(-c3ccccc3)cc(-c3cnc(-c4cccc(-n5c6ccccc6c6ccc(-c7ccc8c(c7)c7ccccc7n8-c7ccccc7)cc65)c4)nc3)c2)cc1]

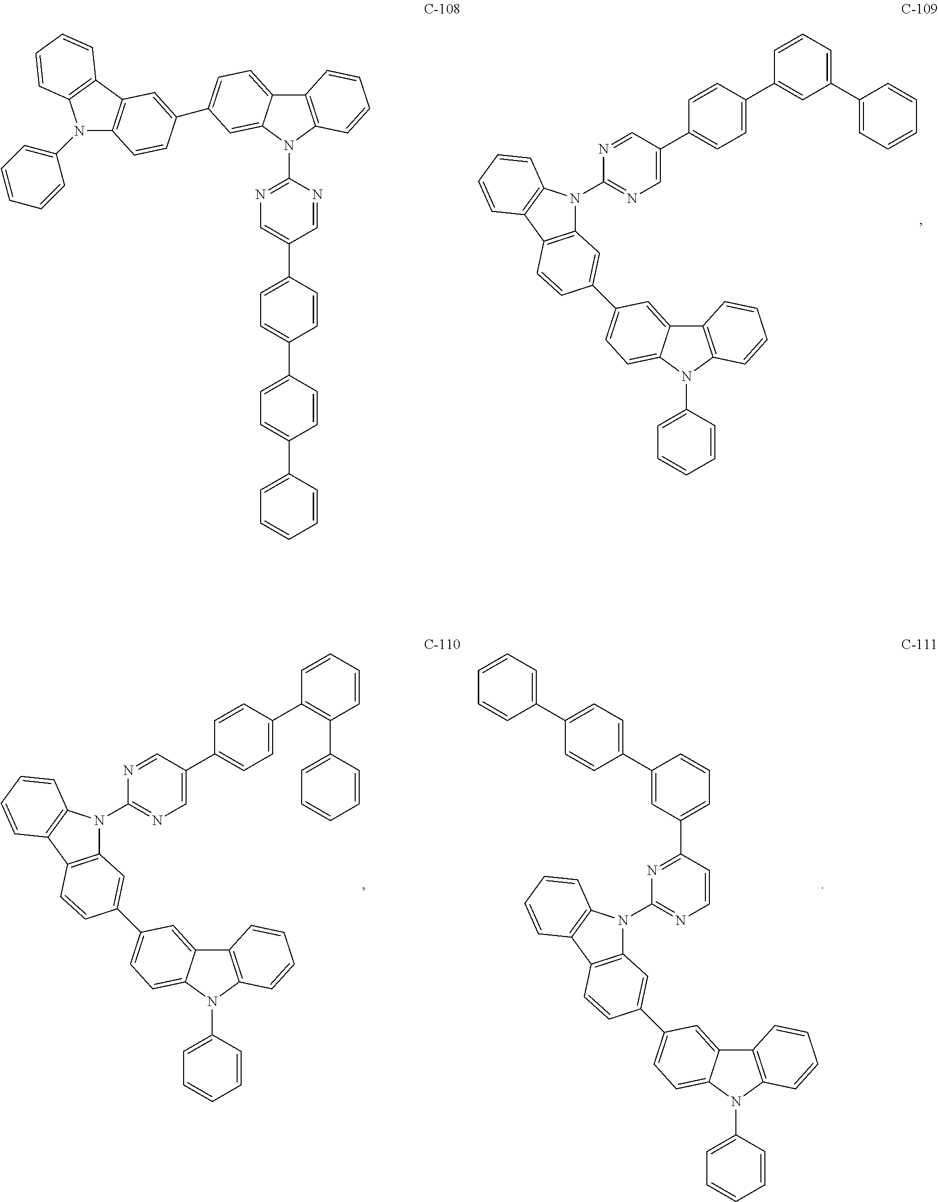 [SMILES: c1ccc(-c2ccc(-c3ccc(-c4cnc(-n5c6ccccc6c6ccc(-c7ccc8c(c7)c7ccccc7n8-c7ccccc7)cc65)nc4)cc3)cc2)cc1 ; c1ccc(-c2cccc(-c3ccc(-c4cnc(-n5c6ccccc6c6ccc(-c7ccc8c(c7)c7ccccc7n8-c7ccccc7)cc65)nc4)cc3)c2)cc1 ; c1ccc(-c2ccccc2-c2ccc(-c3cnc(-n4c5ccccc5c5ccc(-c6ccc7c(c6)c6ccccc6n7-c6ccccc6)cc54)nc3)cc2)cc1 ; c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1]

9. The organic electroluminescent compound according to claim 7, wherein the compound is selected from the group consisting of:

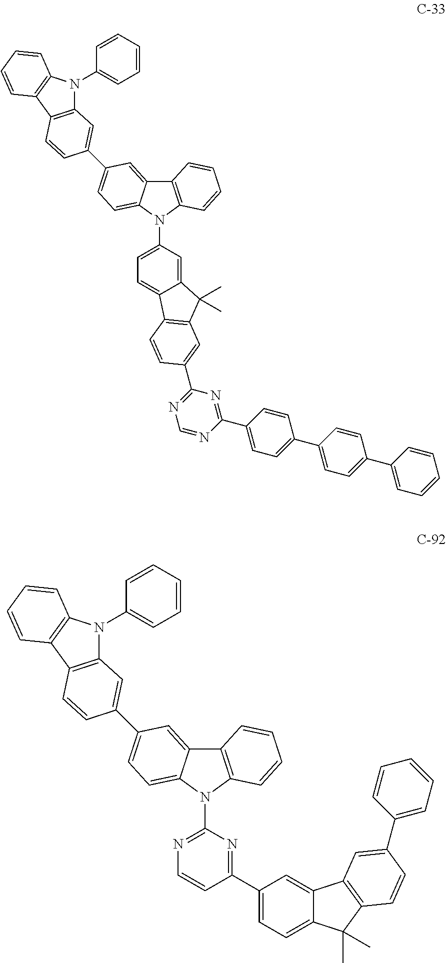 [SMILES: CC1(C)c2cc(-c3ncnc(-c4ccc(-c5ccc(-c6ccccc6)cc5)cc4)n3)ccc2-c2ccc(-n3c4ccccc4c4cc(-c5ccc6c7ccccc7n(-c7ccccc7)c6c5)ccc43)cc21 ; CC1(C)c2ccc(-c3ccccc3)cc2-c2cc(-c3ccnc(-n4c5ccccc5c5cc(-c6ccc7c8ccccc8n(-c8ccccc8)c7c6)ccc54)n3)ccc21]

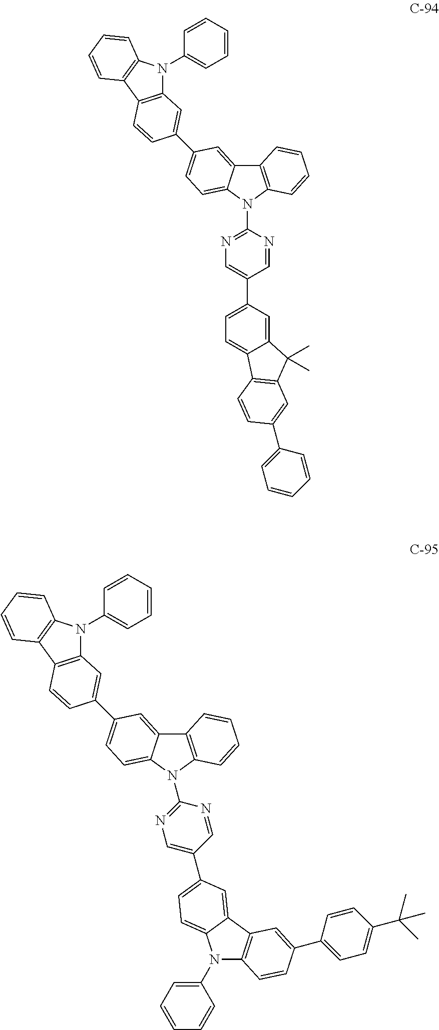 [SMILES: CC1(C)c2cc(-c3ccccc3)ccc2-c2ccc(-c3cnc(-n4c5ccccc5c5cc(-c6ccc7c8ccccc8n(-c8ccccc8)c7c6)ccc54)nc3)cc21 ; CC(C)(C)c1ccc(-c2ccc3c(c2)c2cc(-c4cnc(-n5c6ccccc6c6cc(-c7ccc8c9ccccc9n(-c9ccccc9)c8c7)ccc65)nc4)ccc2n3-c2ccccc2)cc1]

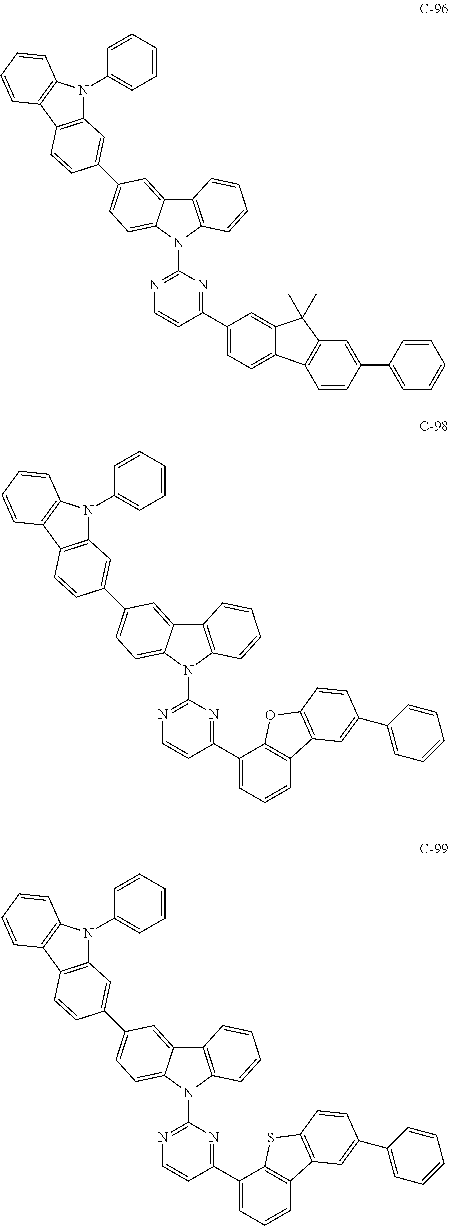 [SMILES: CC1(C)c2cc(-c3ccccc3)ccc2-c2ccc(-c3ccnc(-n4c5ccccc5c5cc(-c6ccc7c8ccccc8n(-c8ccccc8)c7c6)ccc54)n3)cc21 ; c1ccc(-c2ccc3oc4c(-c5ccnc(-n6c7ccccc7c7cc(-c8ccc9c%10ccccc%10n(-c%10ccccc%10)c9c8)ccc76)n5)cccc4c3c2)cc1 ; c1ccc(-c2ccc3sc4c(-c5ccnc(-n6c7ccccc7c7cc(-c8ccc9c%10ccccc%10n(-c%10ccccc%10)c9c8)ccc76)n5)cccc4c3c2)cc1]

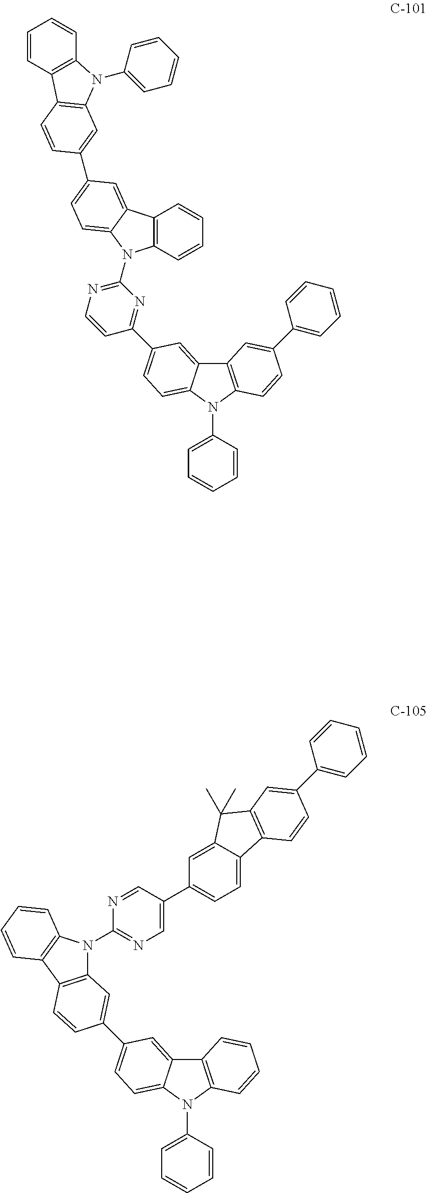 [SMILES: c1ccc(-c2ccc3c(c2)c2cc(-c4ccnc(-n5c6ccccc6c6cc(-c7ccc8c9ccccc9n(-c9ccccc9)c8c7)ccc65)n4)ccc2n3-c2ccccc2)cc1 ; CC1(C)c2cc(-c3ccccc3)ccc2-c2ccc(-c3cnc(-n4c5ccccc5c5ccc(-c6ccc7c(c6)c6ccccc6n7-c6ccccc6)cc54)nc3)cc21]

10. An organic electroluminescent device comprising the organic electroluminescent compound according to claim 1.
